(19) United States
(12) Patent Application Publication
(10) Pub. No.: US 2024/0152047 A1
(43) Pub. Date: May 9, 2024

(54) HIGH REFRACTIVE INDEX MATERIALS

(71) Applicant: Rohm and Haas Electronic Materials LLC, Marlborough, MA (US)

(72) Inventors: ANASTASIA LILY PATTERSON, Philadelphia, PA (US); RACHEL SNYDER, Marlborough, MA (US); Greg Alan Hostetler, Newark, DE (US); Charles Roger Kinzie, Natick, MA (US); Bethany Seckman, Worcester, MA (US); Deyan Wang, Hudson, MA (US); Hee Jae Yoon, Hwaseong-si (KR); Su Min Lee, Hwaseong-si (KR); Heelim Lee, Hwaseong-si (KR)

(21) Appl. No.: 18/482,295

(22) Filed: Oct. 6, 2023

Related U.S. Application Data
(60) Provisional application No. 63/379,212, filed on Oct. 12, 2022.

(51) Int. Cl. G03F 7/00; C08F 220/06

(52) U.S. Cl. CPC G03F 7/0005; C08F 220/06

(57) ABSTRACT

Disclosed is a formulation comprising a copolymer comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B), and one or more solvents. The formulation may optionally contain additional components. Further disclosed are methods for forming optical thin films from the formulation and optical devices containing the optical thin films.

### BACKGROUND OF THE INVENTION

### Field of the Disclosed and Claimed Inventive Concepts

The presently disclosed process(es), procedure(s), method(s), product(s), result(s), and/or concept(s) (collectively referred to hereinafter as the “present disclosure”) relate generally to copolymer compositions, formulations, and methods to prepare optical thin films and materials therefrom. In particular, the films are found to exhibit optical and other properties that make them useful in a variety of optical and electronics applications.

### Background and Applicable Aspects of the Presently Disclosed and Claimed Inventive Concept(s)

Materials for use in electronics and displays applications often have strict requirements in terms of their structural, optical, thermal, electronic, and other properties. As the number of commercial electronics and displays applications continues to grow, the breadth and specificity of requisite properties demand the innovation of materials with new and/or improved properties. Polymeric materials are increasingly finding use in such applications as a result of their widely-variable properties and processability advantages over more-conventional incumbent materials.

Polymers can often be made to exhibit an effective combination of good chemical and thermal resistance, tunable glass transition temperatures (T_{g}), and thermomechanical properties that are required in many electronics and displays applications. Further, their molecular weight and solution concentration may be adjusted to enable precise and convenient deposition by spin coating, slot-die coating, or ink-jet printing—all of which are universally important industrial processing methods. Also, the synthetic flexibility that is afforded by heteroatom inclusion, copolymer formation, and the like makes available families of materials that can be prepared for highly specific applications in-use.

Polymeric materials can exhibit optical properties that make them particularly well-suited to address the technical challenges associated with optical elements and devices of increasing complexity. Many such devices can exhibit significant losses in efficiency because of the way that light moves within and through their structural elements. Display devices like light-emitting diodes (LEDs) and organic light-emitting diodes (OLEDs) often suffer from lower luminance because a significant percentage of the generated light is lost via internal reflection and waveguiding as it passes between elements or layers of different refractive indices. To counter these losses, the display unit must be run at a higher internal brightness, leading to higher energy consumption. Many of these display-device inefficiencies are addressable through more-precise management of the refractive indices, and the relative refractive indices, of adjacent optical elements. The introduction of a relatively high-refractive-index light-extraction layer between an OLED encapsulant layer and polarizer element, for example, can greatly increase the number of photons emitted from a display device, enabling improved display brightness, lower power consumption, and/or longer emitter lifetimes.

Improved display performance continues to be essential as the display serves as the user-interface in devices that span a range of applications in the television, computer, mobile phone, and auto industries and the like. This desired performance often relies on increased brightness for high visibility in a variety of environments, which can only be partially satisfied by improvements in the efficiency of emission materials and/or increases in driving currents.

Furthermore, as power demands on these devices increase due to ever-increasing computing and communication functions, there is a need to reduce power consumption of the display component, which often consists of a significant fraction of available power in battery-operated mobile applications. To enable displays to achieve improved performance as compared to their forebears, improved light extraction is demanded.

Display designs include variable components, but the essential function is the same. As light leaves an emitter such as an OLED or LED, it travels through a number of layers that may include (in some order): (1) a transparent electrode that serves as half of the voltaic cell, (2) an encapsulant designed to protect the emission source from decomposition; (3) a planarization layer; (4) a polarizer; and (5) a series of layers that may include an organic or inorganic color filter layer, a backplane containing pixel-controlling thin-film transistors, conductors to enable touch-screen capabilities, cover windows, and the like to impart functionalities specific to intended the device application or design.

Similar considerations can apply to optical devices wherein the light in question is incident-versus-emitted. Image sensors based on complementary metal oxide-semiconductor (CMOS) technology (CIS) can suffer reduced sensitivities from reflections by a refractive index mismatch between the external environment and the color filter surface or from light falling on non-photosensitive areas between pixels. This can be overcome by introducing a high-surface-area microlens on top of the color filter, and the light can be recovered for detection by reducing reflections or altering the angle of incidence via refraction.

Judicious use of optical materials in other types of devices can similarly be used to drive efficiency improvements, although sometimes the refractive index of a material is manipulated to increase internal reflection. Core/clad waveguides, for example, operate most efficiently when transmitted light passes longitudinally through the core. In practice, however, a portion of the transmitted light travels off-axis and escapes the core. This situation can be remedied via the addition of a cladding around the core where the cladding has a higher refractive index than the core.

Applications such as displays, image sensors, and other optical applications, continue to place demanding performance requirements on device materials. For example, non-filled high refractive index materials that can be photopatterned using ultraviolet (UV) or broad-band light and aqueous-based developers are an unmet need for fabricating displays with higher brightness and low power consumption. New materials are being sought that can demonstrate high refractive indices while meeting stringent processing requirements. The materials disclosed herein offer the potential to meet such demands, and they can find advantages-in-use not only because of their inherent processability, but also because specific optical properties can be tuned to meet specific parametric demands of increasingly complicated optical devices. Because of these ever-changing demands, there is an ongoing need for the development of such materials in this context. Not only will the current-device performance and efficiency be improved, but components with superior light management will facilitate the drive towards new devices with smaller optical elements for use in an expanding number of commercial applications.

### DETAILED DESCRIPTION

Before explaining at least one embodiment of the present disclosure in detail, it is to be understood that the present disclosure is not limited in its application to the details of construction and the arrangement of the components or steps or methodologies set forth in the following description. The present disclosure is capable of other embodiments or of being practiced or carried out in various ways. Also, it is to be understood that the phraseology and terminology employed herein is for the purpose of description and should not be regarded as limiting.

Unless otherwise defined herein, technical terms used in connection with the present disclosure shall have the meanings that are commonly understood by those of ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the present disclosure pertains. All patents, published patent applications, and non-patent publications referenced in any portion of this application are herein expressly incorporated by reference in their entirety to the same extent as if each individual patent or publication was specifically and individually indicated to be incorporated by reference.

All of the articles and/or methods disclosed herein can be made and executed without undue experimentation in light of the present disclosure. While the articles and methods of the present disclosure have been described in terms of preferred embodiments, it will be apparent to those of ordinary skill in the art that variations may be applied to the articles and/or methods and in the steps or in the sequence of steps of the method(s) described herein without departing from the concept, spirit, and scope of the present disclosure. All such similar substitutes and modifications apparent to those skilled in the art are deemed to be within the spirit, scope, and concept of the present disclosure.

As utilized in accordance with the present disclosure, the following terms, unless otherwise indicated, shall be understood to have the following meanings.

The use of the word “a” or “an” when used in conjunction with the term “comprising” may mean “one,” but it is also consistent with the meaning of “one or more,” “at least one,” and “one or more than one.” The use of the term “or” is used to mean “and/or” unless explicitly indicated to refer to alternatives only if the alternatives are mutually exclusive, although the disclosure supports a definition that refers to only alternatives and “and/or.” Throughout this application, the term “about” is used to indicate that a value includes the inherent variation of error for the quantifying device, the method(s) being employed to determine the value, or the variation that exists among the study subjects. For example, but not by way of limitation, when the term “about” is utilized, the designated value may vary by plus or minus twelve percent, or eleven percent, or ten percent, or nine percent, or eight percent, or seven percent, or six percent, or five percent, or four percent, or three percent, or two percent, or one percent. The use of the term “at least one” will be understood to include one as well as any quantity more than one, including but not limited to, 1, 2, 3, 4, 5, 10, 15, 20, 30, 40, 50, 100, etc. The term “at least one” may extend up to 100 or 1000 or more depending on the term to which it is attached. In addition, the quantities of 100/1000 are not to be considered limiting as lower or higher limits may also produce satisfactory results. In addition, the use of the term “at least one of X, Y, and Z” will be understood to include X alone, Y alone, and Z alone, as well as any combination of X, Y, and/or Z. The use of ordinal number terminology (i.e., “first”, “second”, “third”, “fourth”, etc.) is solely for the purpose of differentiating between two or more items and, unless otherwise stated, is not meant to imply any sequence or order or importance to one item over another or any order of addition.

As used herein, the words “comprising” (and any form of comprising, such as “comprise” and “comprises”). “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. The terms “or combinations thereof” and “and/or combinations thereof” as used herein refer to all permutations and combinations of the listed items preceding the term. For example, “A, B, C, or combinations thereof” is intended to include at least one of: A, B, C, AB, AC, BC, or ABC and, if order is important in a particular context, also BA, CA. CB, CBA, BCA, ACB, BAC, or CAB. Continuing with this example, expressly included are combinations that contain repeats of one or more items or terms, such as BB, AAA, AAB, BBC, AAABCCCC, CBBAAA, CABABB, and so forth. The skilled artisan will understand that typically there is no limit on the number of items or terms in any combination, unless otherwise apparent from the context.

As used herein, the term “substantially” means that the subsequently described circumstance completely occurs or that the subsequently described circumstance occurs to a great extent or degree.

For purposes of the following detailed description, other than in any operating examples, or where otherwise indicated, numbers that express, for example, quantities of ingredients used in the specification and claims are to be understood as being modified in all instances by the term “about.” The numerical parameters set forth in the specification and attached claims are approximations that may vary depending upon the desired properties to be obtained in carrying out the invention.

The term “alicyclic” refers to a cyclic group that is not aromatic. The group can be saturated or unsaturated, but it does not exhibit aromatic character.

The term “alkyl” refers to a saturated linear or branched hydrocarbon group of 1 to 50 carbons. It further includes both substituted and unsubstituted hydrocarbon groups. The term is further intended to include heteroalkyl groups.

The term “aprotic” refers to a class of solvents that lack an acidic hydrogen atom and are therefore incapable of acting as hydrogen donors. Common aprotic solvents include alkanes, carbon tetrachloride (CCl₄), benzene, dimethyl formamide (DMF), N-methyl-2-pyrrolidone (NMP), dimethylacetamide (DMAc), propylene glycol methyl ether acetate (PGMEA), anisole, cyclohexanone, benzyl benzoate, cyclopentanone, methyl ethyl ketone, and many others.

The term “aromatic compound” refers to an organic compound comprising at least one unsaturated cyclic group having 4n+μ delocalized pi electrons. The term is intended to encompass both aromatic compounds having only carbon and hydrogen atoms, and heteroaromatic compounds wherein one or more of the carbon atoms within the cyclic group has been replaced by another atom, such as nitrogen, oxygen, sulfur, or the like.

The term “aryl” or “aryl group” refers to a moiety formed by removal of one or more hydrogen (“H”) or deuterium (“D”) from an aromatic compound. The aryl group may be a single ring (monocyclic) or have multiple rings (bicyclic, or more) fused together or linked covalently. A “carbocyclic aryl” has only carbon atoms in the aromatic ring(s). A “heteroaryl” has one or more heteroatoms in at least one aromatic ring.

The term “alkoxy” refers to the group —OR, where R is alkyl.

The term “aryloxy” refers to the group —OR, where R is aryl.

Unless otherwise indicated, all groups can be substituted or unsubstituted. An optionally substituted group, such as, but not limited to, alkyl or aryl, may be substituted with one or more substituents which may be the same or different. Suitable substituents include alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be cross-linking groups.

The term “amine” refers to a compound that contains a basic nitrogen atom with a lone pair. The term “amino” refers to the functional group —NH₂, —NHR, or —NR₂, where R is the same or different at each occurrence and can be an alkyl group or an aryl group. The term “diamine” refers to a compound that contains two basic nitrogen atoms with associated lone pairs. The term “aromatic diamine” refers to an aromatic compound having two amino groups. The term “aromatic diamine residue” refers to the moiety bonded to the two amino

groups in an aromatic diamine. This is further illustrated below.

| Diamine | Residue |
|---|---|
| 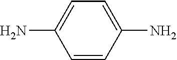 | 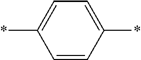 [SMILES: *c1ccc(*)cc1] |
| 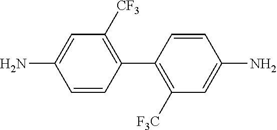 [SMILES: Nc1ccc(-c2ccc(N)cc2C(F)(F)F)c(C(F)(F)F)c1] | 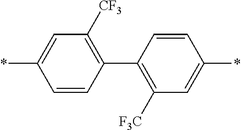 [SMILES: *c1ccc(-c2ccc(*)cc2C(F)(F)F)c(C(F)(F)F)c1] |

The term “bifunctional” describes a molecule containing two functional groups of the same composition.

The term “CMOS image sensor,” or “CIS”, refers to a type of digital image sensor that is an integrated circuit used for measuring light intensity. Image sensors have generally become quite common; finding utility in phones, computers, digital cameras, and automobiles.

The term “coating” refers to a covering that is applied to the surface of an object that is usually referred to as the “substrate.” Coatings may have various thicknesses and other properties, depending on the end-use appropriate for a given situation. In some non-limiting embodiments, the coating/substrate combination is used as a single unit, while in some embodiments, the coating is removed from the substrate for stand-alone use. In some non-limiting embodiments, the coating is referred to as a film, a thin film, an optical thin film, or the like.

The term “copolymer” refers to a polymer that is derived from more than one species of monomer. Copolymers derived from three species of monomers are sometimes referred to as “terpolymers.”

The term “cross-linker” or “cross-linking reagent” refers to a molecule that contains two or more reactive ends capable of chemically attaching to specific functional groups on molecules or polymers. The cross-linked molecules or polymers are chemically joined together by one or more covalent bonds.

The term “curing” refers to a process during which a chemical reaction or physical action takes place; resulting in a harder, tougher, or more stable linkage or substance. In polymer chemistry, “curing” specifically refers to the toughening or hardening of a polymer via cross-linking of polymer chains. Curing processes may be brought about by electron beams, heat, light, and/or chemical additives.

The term “developable in aqueous media” or “capable of being reacted to become developable in aqueous media” refers to any number of water-based processes related to photolithography wherein a thin film is exposed to a pattern of light of a given energy and intensity which causes a chemical change that allows some of the material to be removed by a developer solution and some of the material to remain in the film. Positive photoresists become soluble in the developer solution upon exposure, while negative photoresists are characterized in that unexposed regions are soluble in the developer.

The term “linear coefficient of thermal expansion (CTE or α)” refers to the parameter that defines the amount by which a material expands or contracts as a function of temperature. It is expressed as the normalized change in length per degree Celsius and is generally expressed in units of μm/m/° C. or ppm/° C.

α=(ΔL/L₀)/ΔT

CTE values may be measured via known methods during the first or second heating scan. The understanding of the relative expansion/contraction characteristics of materials can be an important consideration in the fabrication and/or reliability of electronic and display devices.

The term “electroactive” as it refers to a layer or a material, which electronically facilitates the operation of a device. Examples of electroactive materials include, but are not limited to, materials which conduct, inject, transport, or block a charge, where the charge can be either an electron or a hole, or materials which emit radiation or exhibit a change in concentration of electron-hole pairs when receiving radiation.

The term “fused,” when applied to aromatic or alicyclic rings, refers to an aromatic or alicyclic species that contains two or more joined rings that may share a single atom, two adjacent atoms, or 3 or more atoms.

The term “glass transition temperature (or T_{g})” refers to the temperature at which a reversible change occurs in an amorphous polymer or in amorphous regions of a semi-crystalline polymer where the material changes suddenly from a hard, glassy, or brittle state to one that is flexible or elastomeric. Microscopically, the glass transition occurs when normally-coiled, motionless polymer chains become free to rotate and can move past each other. T_{g} values may be measured using differential scanning calorimetry (DSC), thermo-mechanical analysis (TMA), dynamic-mechanical analysis (DMA), or other methods.

The term “haloalkyl” refers to an alkyl group having one or more hydrogen atoms replaced by a halogen atom.

The term “haloalkoxy” refers to an alkoxy group having one or more hydrogen atoms replaced by a halogen atom.

The prefix “hetero” refers to a situation where one or more carbon atoms have been replaced with a different atom. In some embodiments, the heteroatom is O, N, S, Se, or combinations thereof.

The term “high-boiling” refers to a boiling point greater than 130° C.

The term “hindered amine light stabilizer” refers to a class of radical scavengers used for light protection and long-term heat protection of polymers. Hindered amine light stabilizers are compounds that contain a sterically hindered amine functional group, which is designed to react with free radicals and resist other side reactions.

The term “imide” refers to a functional group containing two acyl groups bound to a central nitrogen, i.e., RCO—NR'—COR. The term “bis-imide” refers to the presence of two identical, but separated, imide groups in a single molecule, polymer, or other species.

The term “matrix” refers to a foundation on which one or more layers is deposited in the formation of, for example, an electronic device. Non-limiting examples include glass, silicon, and others.

The term “monomer” refers to a small molecule that chemically bonds during polymerization to one or more monomers of the same or different kind to form a polymer.

The term “nonpolar” refers to a molecule, solvent, or other species in which the distribution of electrons between covalently-bonded atoms is even and there is thus no net electrical charge or strong permanent dipole across them. In some embodiments; nonpolar molecules, solvents, or other species are formed when constituent atoms have the same or similar electronegativities.

The term “optical thin film” refers to a polymeric film whose optical properties make it well-suited to provide specific function in optical devices such as those disclosed herein. Optical thin films may be prepared by any number of methods that are well known to those skilled in the art. The term “optical material” or “optical polymer” are sometimes used interchangeably by those with skill in the art, particularly when the application does not involve the polymer being directly prepared as a thin film.

The term “organic electronic device” or sometimes “electronic device” refers to a device including one or more organic semiconductor layers or organic materials.

The term “oxygen scavenger” refers to compounds that are added to solutions or formulations that assist in the reduction or removal of oxygen from the solutions or formulations or films made therefrom.

The term “photoacid” refers to molecules which become more acidic upon absorption

of light. This is due either to the formation of strong acids upon photodissociation, or to the dissociation of protons upon photo-association (e.g., ring-closing). The term “photoacid generator” refers to a molecule that releases protons upon illumination.

The term “photoinitiator” refers to a molecule that creates one or more reactive species (free radicals, cations or anions) when exposed to UV or visible radiation. Synthetic photoinitiators are sometimes key components in photopolymers like photo-curable coatings, adhesives, and dental materials.

The term “photopatternable” or “reactive groups capable of being photopatterned” refers to reactive species that permit the production of a pattern in the target material by affording a change in solubility after light exposure and photochemical reaction to reveal a pattern after dissolution in appropriate solvent.

The term “polar” refers to a molecule, solvent, or other species in which the distribution of electrons between covalently-bonded atoms is not even. Such species therefore exhibit a large dipole moment which may result from bonds between atoms characterized by significantly different electronegativities.

The term “polyimide” refers to condensation polymers resulting from the reaction of one or more bifunctional carboxylic acid components with one or more primary diamines or diisocyanates. Polyimides contain the imide structure —CO—NR—CO— as a linear or heterocyclic unit along the main chain of the polymer backbone.

The term “polyester-acid” refers to step-growth polymers resulting from the reaction of one or more bifunctional tetracarboxylic acid components with one or more primary or secondary alcohols. Polyester-acids contain the ester structure —CO—O— as a linear or heterocyclic unit along the main chain of the polymer backbone and the structure —CO—OH adjacent to the ester structure.

The term “polymer” refers to a large molecule comprising one or more types of monomer residues (repeating units) connected by covalent chemical bonds. By this definition, a polymer encompasses compounds wherein the number of monomer units may range from very few, which more commonly may be called as oligomers, to very many. Non-limiting examples of polymers include homopolymers and non-homopolymers such as copolymers, terpolymers, tetrapolymers and the higher analogues.

The term “polyarylene” refers to a class of polymers that contain benzenoid aromatic components directly joined to one another by carbon-carbon bonds along the main chain of the polymer backbone.

The term “protic” refers to a class of solvents that contain an acidic hydrogen atom and are therefore capable of acting as hydrogen donors. Common protic solvents include formic acid, n-butanol, isopropanol, ethanol, methanol, acetic acid, water, propylene glycol methyl ether (PGME), and others. Protic solvents can be used individually or in various combinations.

The term “reactive,” when used in the context of a chemical species or group refers to the propensity of the chemical species or group to undergo a chemical reaction when subject to the appropriate conditions of temperature, pressure, light, co-reactants, and the like. The chemical species or group can include any number of materials or classes of materials that are known to those with skill in the art.

The term “refractive index” or “index of refraction” is a measure of the bending of a ray of light when it passes from one medium into another. If i is the angle of incidence of a ray in a vacuum (angle between the incoming ray and the perpendicular to the surface of a medium, called the normal) and r is the angle of refraction (angle between the ray in the medium and the normal), the refractive index n is defined as the ratio of the sine of the angle of incidence to the sine of the angle of refraction; i.e., n=sin i/sin r. Refractive index is also equal to the velocity of light c of a given wavelength in empty space divided by its velocity v in a substance, or n=c/v. The refractive index is generally wavelength dependent. The refractive index of a given compound or material may generally be viewed as “low,” “intermediate,” or “high;” as would be understood by one having skill in the art to which these relative terms may be applied.

The term “satisfactory,” when regarding a materials property or characteristic, is intended to mean that the property or characteristic fulfills all requirements/demands for the material in-use.

The term “solubility” refers to the amount of solute that can be dissolved in a

solvent at a given temperature. In some embodiments, solubility may be measured or assessed by any number of qualitative or quantitative methods.

The term “substrate” refers to a base material that can be either rigid or flexible and may include one or more layers of one or more materials, which can include, but are not limited to, glass, polymer, metal, or ceramic materials or combinations thereof. The substrate may or may not include electronic components, circuits, or conductive members.

The term “surface leveling agent” refers to a formulation additive that reduces the surface tension of a coating being applied to a substrate; wherein surface wetting is improved, and defects are eliminated that can result from a mismatch in surface tensions of the coating and substrate onto which it is applied.

The term “tetracarboxylic acid component” refers to any one or more of the following: a tetracarboxylic acid, a tetracarboxylic acid monoanhydride, a tetracarboxylic acid dianhydride, a tetracarboxylic acid monoester, a tetracarboxylic acid diester, a tetracarboxylic acid tri-ester, and a tetracarboxylic acid tetra-ester.

The term “thermal acid generator” refers to a compound or compounds that, when heated, are capable of producing a strong acid or acids having a pKa of 2.0 or less. In one non-limiting embodiment, the thermal acid generator comprises a salt wherein a volatile base (e.g., pyridine) buffers a superacid (e.g., a sulfonate), and the mixture is heated above the heat of decomposition of the salt and the boiling point of the buffering base to remove the buffer and yield the strong acid. In another non-limiting embodiment, a thermal acid generator comprises a thermally-unstable buffer that breaks down upon heating to produce a strong acid. The use of thermal acid generators in electronics and displays applications described is described, for example, in U.S. 2014-0120469 A1. A variety of thermal acid generators are commercially available.

The term “transmittance” or “percent transmittance” refers to the percentage of light of a given wavelength impinging on a film that passes through the film so as to be detectable on the other side. Light transmittance measurements in the visible region (380 nm to 800 nm) are particularly useful for characterizing film-color characteristics that are most important for understanding the properties-in-use of the optical thin films disclosed herein.

The term “UV blocker” refers to a compound that mitigates the harmful effects of UV radiation on materials prepared from compositions that contain them.

In a structure where a substituent bond passes through one or more rings as shown below,

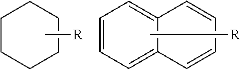

it is meant that the substituent R may be bonded at any available position on the one or more rings.

The phrase “adjacent to,” when used to refer to layers in a device, does not necessarily mean that one layer is immediately next to another layer. On the other hand, the phrase “adjacent R groups,” is used to refer to R groups that are next to each other in a chemical formula (i.e., R groups that are on atoms joined by a bond). Exemplary adjacent R groups are shown below:

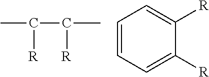

All percentages, ratios, and proportions used herein are based on weight unless otherwise specified.

The present disclosure is directed to a copolymer composition comprising: (a) one or more bifunctional high refractive index first monomers comprising a high refractive index core comprising one or more aromatic groups and further comprising one or more UV- or thermally-reactive groups (A); (b) one or more second monomers comprising a high refractive index core comprising one or more aromatic groups and further comprising one or more groups capable of reacting to increase the solubility of the copolymer in aqueous media (B); and (c) one or more solvents.

The present disclosure is further directed to a copolymer composition comprising: (a) one or more bifunctional high refractive index first monomers comprising a high refractive index core comprising one or more aromatic groups and further comprising one or more UV-or thermally-reactive groups (A); (b) one or more second monomers comprising a high refractive index core comprising one or more aromatic groups and further comprising one or more groups capable of reacting to increase the solubility of the copolymer in aqueous media (B); and (c) one or more solvents; and (d) one or more additional monomers comprising a high refractive index core and two or more nucleophilic reactive groups (A′).

The present disclosure is further directed to a copolymer composition comprising: (a) one or more bifunctional high refractive index first monomers comprising a high refractive index core comprising one or more aromatic groups and further comprising one or more UV-or thermally-reactive groups (A); (b) one or more second monomers comprising a high refractive index core comprising one or more aromatic groups and further comprising one or more groups capable of reacting to increase the solubility of the copolymer in aqueous media (B); (c) one or more solvents; (d) one or more additional monomers comprising a high refractive index core and two or more nucleophilic reactive groups (A′); and (e) one or more monofunctional monomers (M).

The present disclosure is further directed to a formulation comprising the copolymer composition disclosed herein and additionally comprising one or more selected from: (f) one or more additional polymers or copolymers; (g) one or more photo-initiators and/or thermal initiators; (h) one or more cross-linking agents; (i) one or more antioxidants; (j) one or more surface leveling agents; and (k) one or more solvents.

The present disclosure is further directed to a film prepared from any one or more of the copolymer compositions or formulations disclosed herein such that the film exhibits: (1) a refractive index >1.620 at a wavelength of 550 nm; (2) a % T >80% at wavelengths ≥410 nm for a 2 μm film; and (3) photopatternability afforded by a light-induced reaction that imparts partial solubility in developing solutions used in the electronics industry such as aqueous tetramethy ammonium hydroxide solutions or the like.

In some non-limiting embodiments, the one or more bifunctional high refractive index first monomers comprising a core structure comprising one or more aryl or heteroaryl groups and further comprising one or more UV- or thermally reactive groups (A) has a refractive index measured at 550 nm that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more bifunctional high refractive index first monomers comprising a core structure comprising one or more aryl or heteroaryl groups and further comprising one or more UV- or thermally reactive groups (A) has a refractive index measured at a wavelength in the visible spectrum. In some non-limiting embodiments, the refractive index is measured between 380 nm and 780 nm. In some non-limiting embodiments, between 400 nm and 700 nm. In some non-limiting embodiments, between 450 nm and 650 nm. In some non-limiting embodiments, between 500 nm and 600 nm.

In some non-limiting embodiments, the polymer comprising the one or more bifunctional high refractive index first monomers comprising a core structure comprising one or more aryl or heteroaryl groups and further comprising one or more UV- or thermally reactive groups (A) has a refractive index as measured at a wavelength in the visible spectrum that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more bifunctional high refractive index first monomers comprising a core structure comprising one or more aryl or heteroaryl groups and further comprising one or more UV- or thermally reactive groups (A) is given by Formula (I):

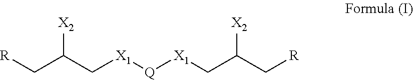

wherein Q is a high refractive index core structure comprising one or more aryl or heteroaryl groups; X1 are B(R′), B(R′)(R″), N(R′), O, P(R′), P(O)(O), Si(R′)(R″), S, and Se; X2 are B(R′), B(R′)(R″), O(H), P(R′), P(O)(O), Si(R′)(R″), S(H), and Se(H); and R is a UV- or thermally-active functional group. In some non-limiting embodiments, Q comprises two or more aryl or heteroaryl groups which are covalently linked by an alkyl, cycloalkyl, alkenyl, alkynyl, aryl, heteroaryl, aryloxy, arylthioxy, arylselenoxy, amino N(R′)(R″), arylcarbonyl, ketoxy, perfluoroalkyl, arylalkyl, silyl, siloxy, siloxane, sulfonyl, sulfonoaryl, or sulfonoheteroaryl or is linked by a phosphate, phosphine, urea, amide, imide, triazole, thioether, vinyl thioether, carbonate, thiocarbonate, or dithiocarbonate group or the like. In some non-limiting embodiments, carbon atom(s) in the described covalent-linking group may be replaced with at least one heteroatom selected from N, O, S, and Se. In some non-limiting embodiments, Q comprises one or more aryl, heteroaryl, and aromatic groups comprising substituted or unsubstituted (C₃-C₆₀) mono- or polycyclic rings that may or may not contain deuterium and whose carbon atom(s) may be replaced with at least one heteroatom selected from N, O, S., and Se. In some non-limiting embodiments, Q additionally comprises one or more (C₃-C₃₀) alicyclic rings whose carbon atom(s) may be replaced with at least one hetero atom selected from N, O. S. and Se. Q may be further substituted with one or more alkyl, cycloalkyl, aryl, nitro, cyano, amino, halo, hydroxy, thioxy, selenoxy, carboxy, thiocarboxy, dithiocarboxy, alkenyl, alkynyl, cycloalkyl, heteroaryl, alkoxy, aryloxy, heteroaryloxy, alkoxycarbonyl, thioalkoxy, selenoalkoxy, ketoxy, perfluoroalkyl, perfluoroalkoxy, arylalkyl, silyl, siloxy, siloxane, sulfonyl, amido, amino, arylamido, arylamino, sulfonoaryl, sulfonoheteroaryl or may be substituted with a phosphate, phosphine, urea, amide, imide, triazole, thioether, vinyl thioether, carbonate, thiocarbonate, or dithiocarbonate group. In some non-limiting embodiments, substitutents comprising N or Si atoms may comprise additional groups R′ and R″, where each R′ and R″ is independently an optionally substituted alkyl, cycloalkyl, aryl, or heteroaryl group. R′ and R″, together with the nitrogen or silicon atom to which they are bound, can form a ring system in certain embodiments. Substituents on Q may also be cross-linking substituents such as acrylate, methacrylate, alkene, alkyne, oxirane, thiirane, azide, carboxylic acid, alcohol, thiol, selenol, benzocyclobutene, and furan groups or the like.

In some non-limiting embodiments, X1 is the same or different at each occurrence and is selected from the group consisting of B(R′), B(R′)(R″), N(R′), O, P(R′), Si(R′)(R″), S, and Se. In some non-limiting embodiments, X2 is the same or different at each occurrence and is selected from the group consisting of B(R′), B(R′)(R″), O(H), P(R′), Si(R′)(R″), S(H), and Se(H). UV- or thermally active functional groups R are the same or different at each occurrence and comprise one or more linking groups and one or more UV- or thermally-active groups. The linking groups are the same or different at each occurrence and are selected from the group consisting of ether, thioether, selenoether, amine, ester, thioester, dithioester, amide, urea, carbamate, triazole, thioether, vinyl thioether, carbonate, thiocarbonate, dithiocarbonate, trithiocarbonate, silane, siloxane, phosphate, and phosphine. The UV- or thermally-active functional groups of R are the same or different at each occurrence and are selected from the group consisting of acrylate, methacrylate, alkene, vinyl ether, styrene, phenyl acrylate, napthyl acrylate, aryl acrylate, heteroarylacrylate, alkyne, diphenylacetylene, benzocyclobutene, diene, furan, thiol, carboxylic acid, amide, ester, thioester, dithioester, carbonate, carbamate, thiocarbonate, dithiocarbonate, trithiocarbonate, acetal, aminal, thioacetal, oxirane, aziridine, dioxolane, oxetane, and nitrile groups. Some non-limiting examples of R are:

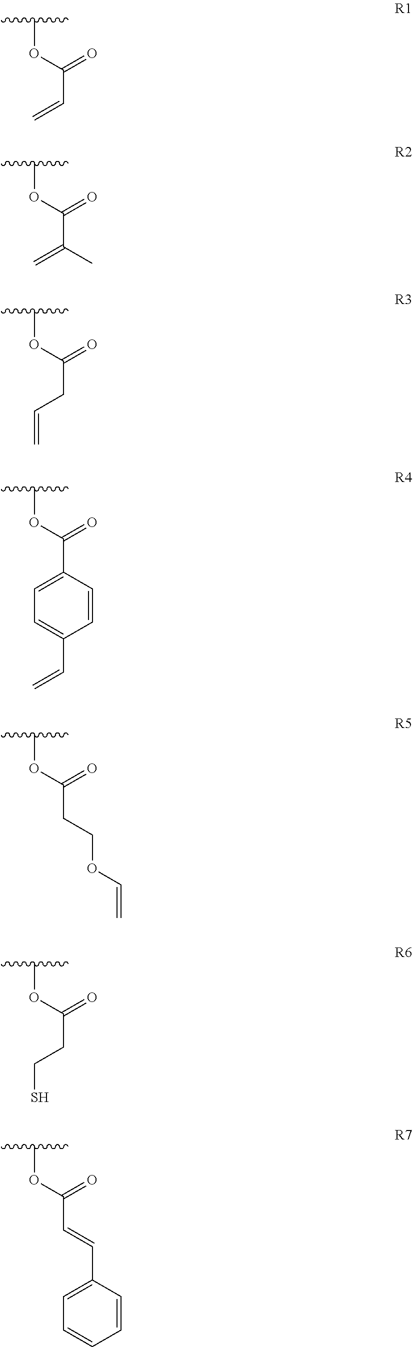

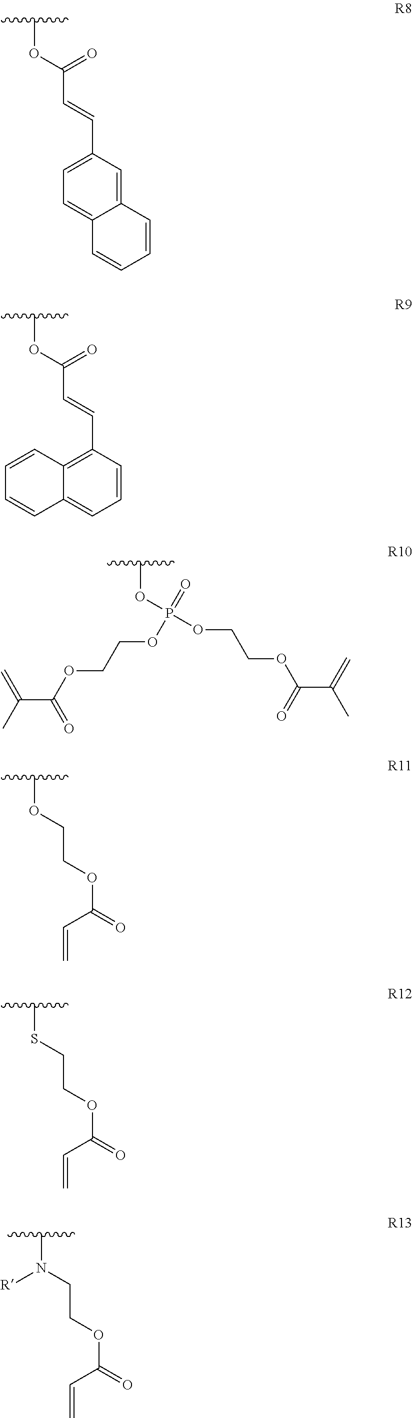

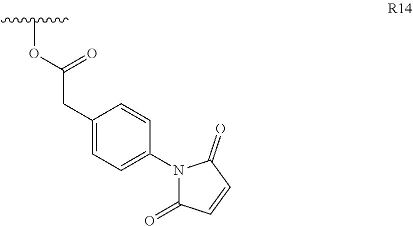

wherein [symbol] denotes the position of attachment to the aliphatic carbon atom of Formula (I) and R′ is an optionally substituted alkyl, cycloalkyl, aryl, or heteroaryl group.

Some non-limiting examples of the compound having Formula (I) are:

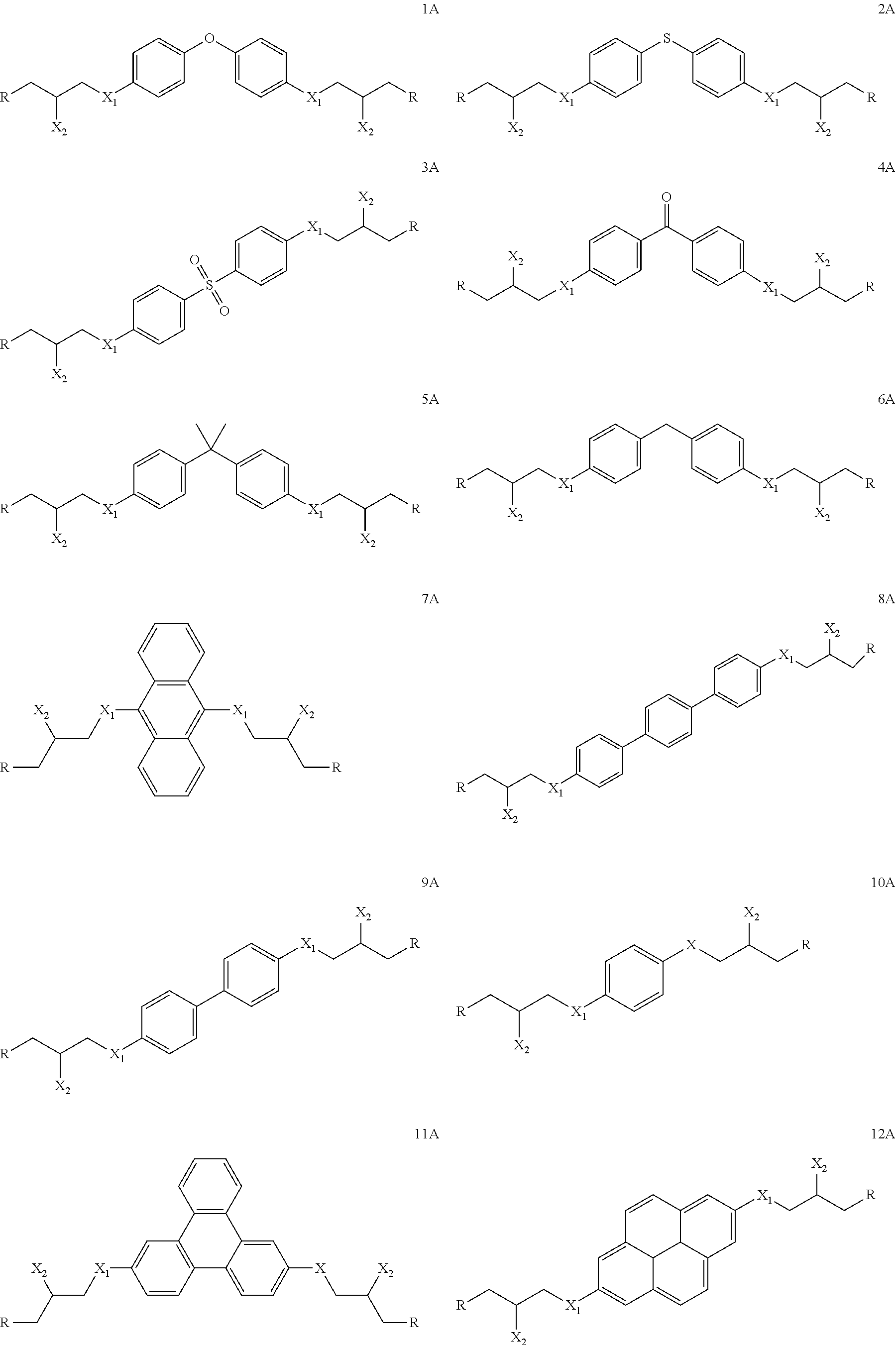

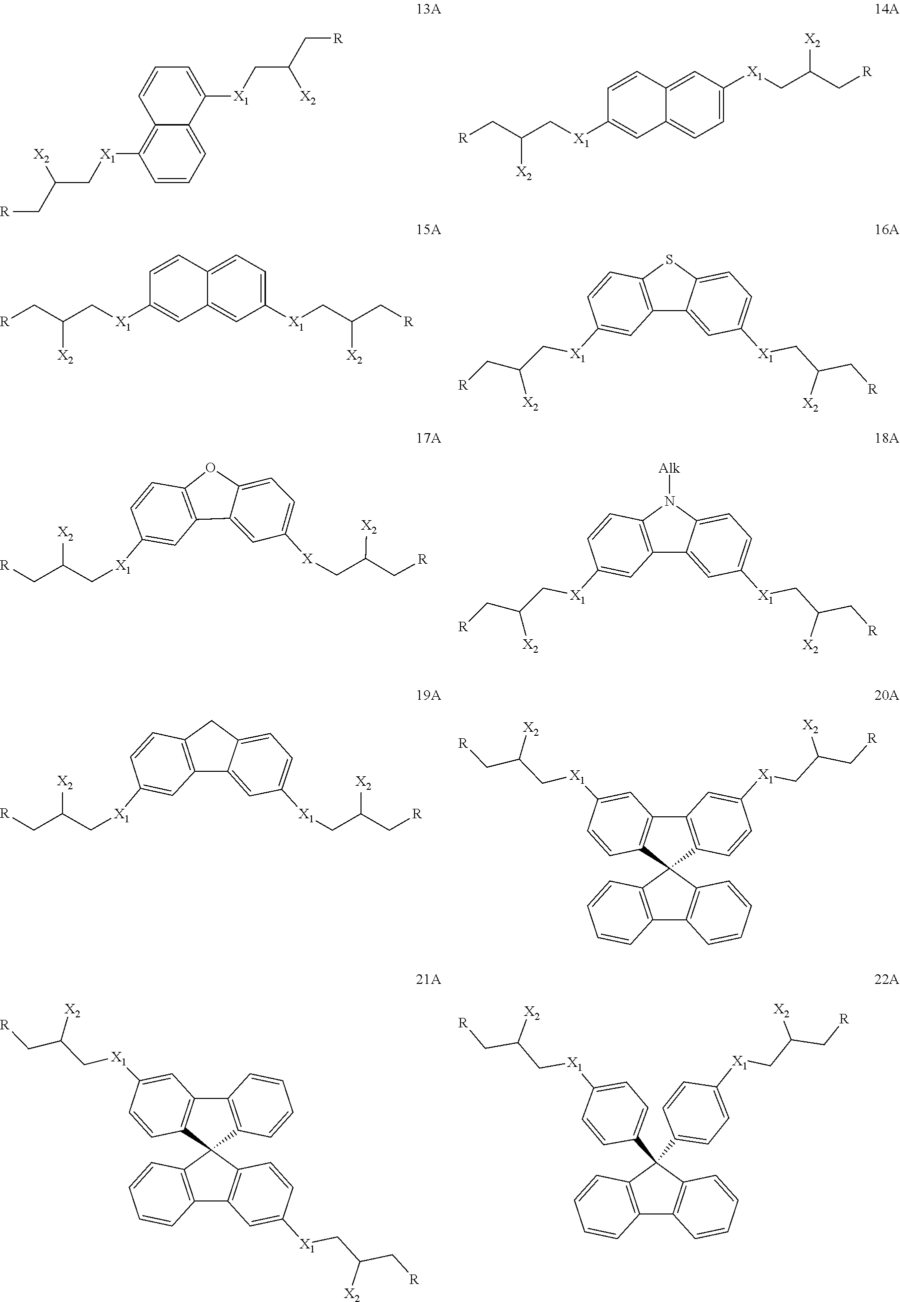

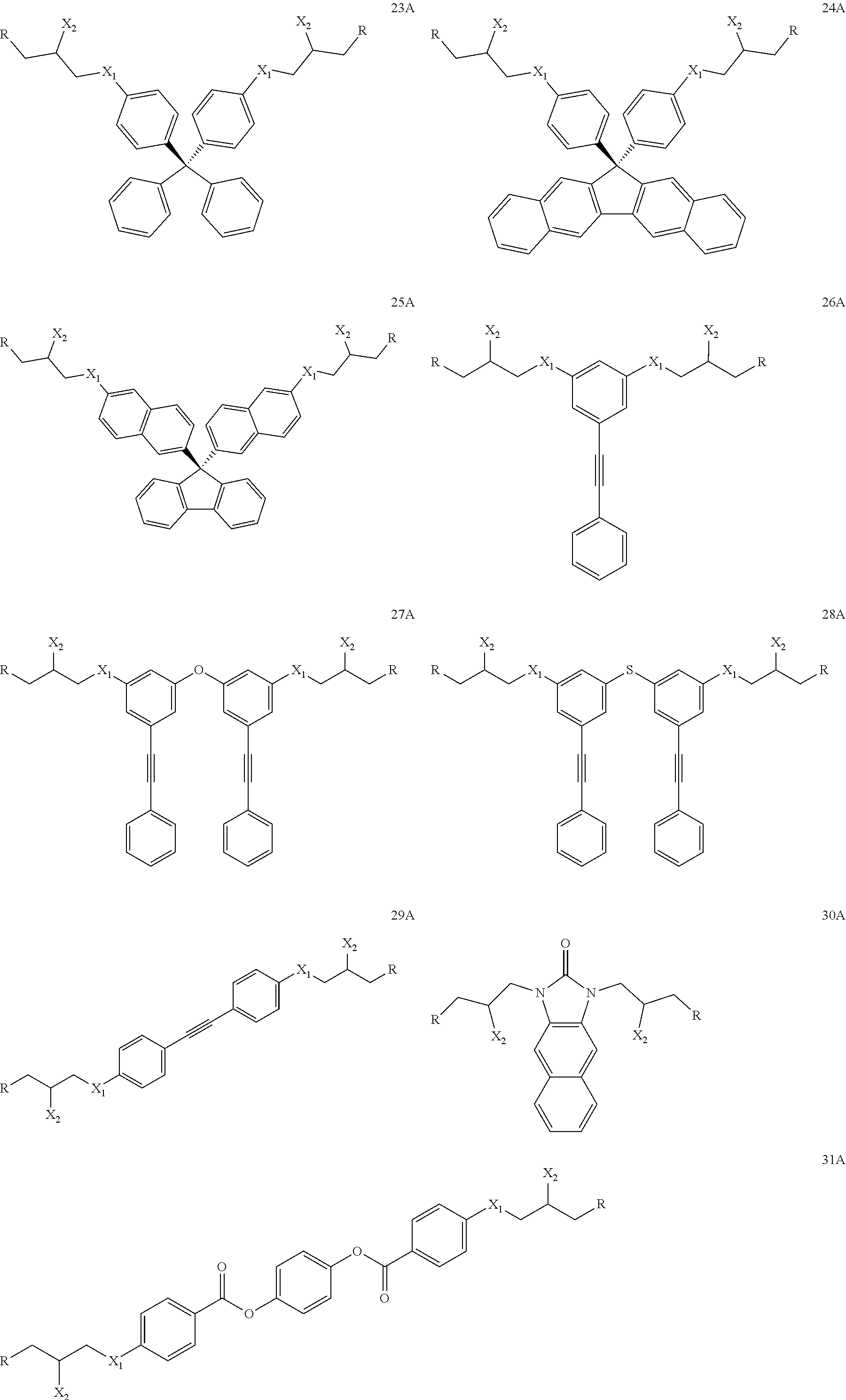

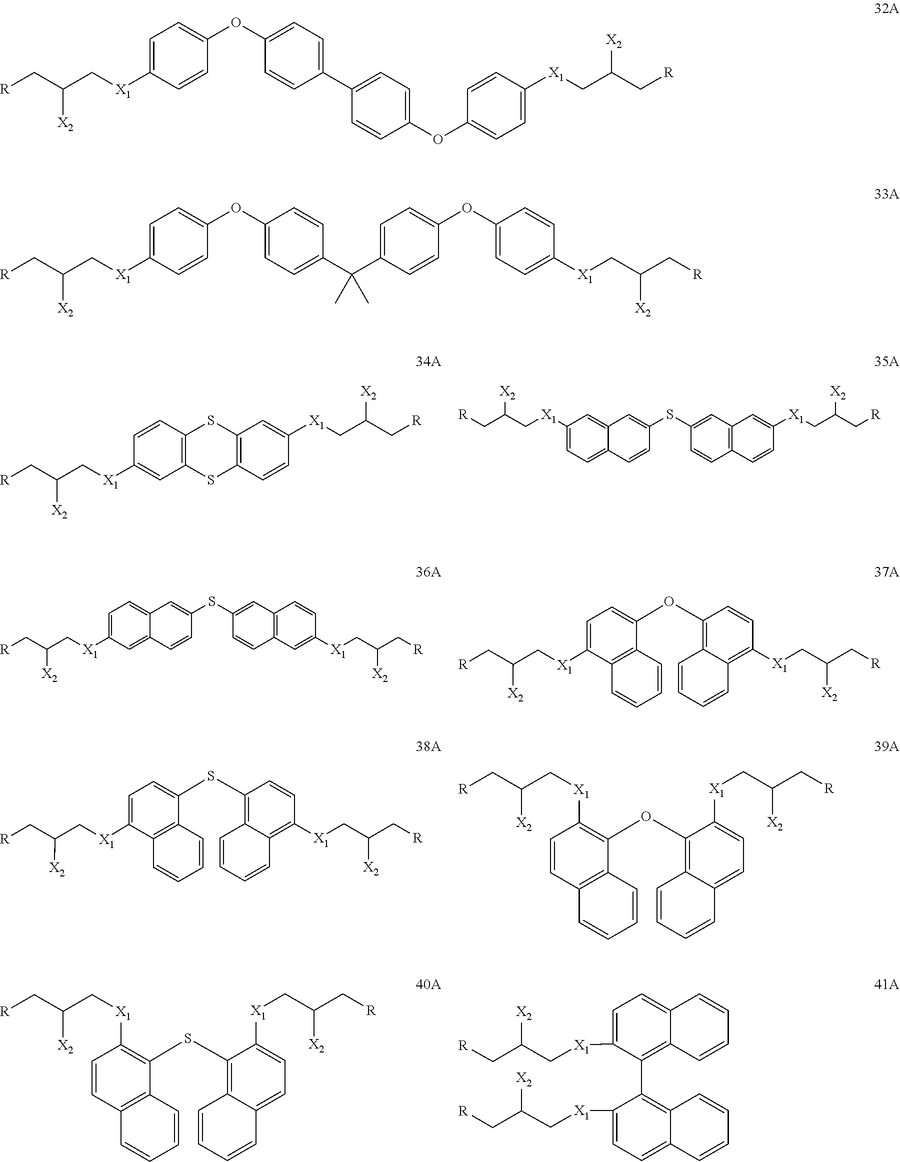

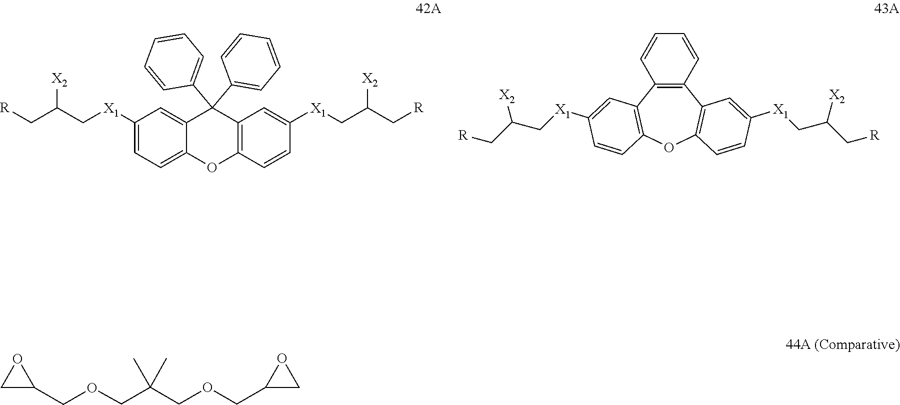

wherein R, X₁, and X₂ are as defined above.

In some non-limiting embodiments, the first monomer having Formula (I) is selected from the group consisting of structures where Q is selected from the groups diphenylether; diphenylsulfane; diphenylsulfone; diphenylmethane; benzophenone; propane-22-diyldibenzene; phenylene; napthylene; anthracene; biphenylene; terphenylene; triphenylene; pyrene; carbazole; thiocarbazole; dibenzofuran; fluorene; spirobis(fluorene); 9,9′-diphenylfluorene; tetraphenylmethane; 12,12-diphenyldibenzofluorene; spiro[dibenzofluorene-12,9′-fluorene]; 9,9-di(naphthalene-2-yl)-fluorene; diphenylacetylene; 3,3′-oxybis(diphenylacetylene); 3,3′-thiobis(diphenylacetylene); 1,4-phenylene dibenzoate; 4,4′-diphenoxy-1,1′-biphenyl; 4,4′-(propane-2,2-diyl)bis(phenoxybenzene); tribenzooxepine; 9,9′-diphenylxanthene; bisnapthalene; 1,1′-oxydinapthalene; 1,1′-thiodinapthalene; napthylbenzimidazolone; di(naphthalene-2-yl)sulfane; thianthrene; phenothiazine; and phenazine.

In some non-limiting embodiments, the one or more second monomers comprising a high refractive index core and further comprising one or more groups capable of reacting to increase the solubility of the copolymer in aqueous media (B) has a refractive index measured at 550 nm that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more second monomers comprising a high refractive index core and further comprising one or more groups capable of reacting to increase the solubility of the copolymer in aqueous media (B) has a refractive index measured at other wavelengths of the visible spectrum. In some non-limiting embodiments, the refractive index is measured between 380 nm and 780 nm. In some non-limiting embodiments, between 400 nm and 700 nm. In some non-limiting embodiments, between 450 nm and 650 nm. In some non-limiting embodiments, between 500 nm and 600 nm.

In some non-limiting embodiments, the one or more second monomers comprising a high refractive index core and further comprising one or more groups capable of reacting to increase the solubility of the copolymer in aqueous media (B) has a refractive index measured at these other wavelengths of the visible spectrum that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more second monomers comprising a high refractive index core and further comprising one or more groups capable of reacting to increase the solubility of the copolymer in aqueous media (B) is given by Formula (II):

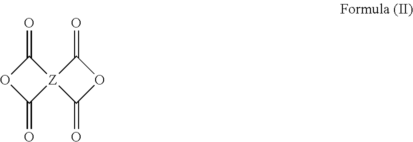

wherein Z is a tetravalent high refractive index core comprising one or more aryl or heteroaryl groups. In some non-limiting embodiments, Z comprises two or more aryl or heteroaryl groups which are covalently linked by an alkyl, cycloalkyl, alkenyl, alkynyl, aryl, heteroaryl, aryloxy, arylthioxy, arylselenoxy, amino N(R′)(R″), arylcarbonyl, ketoxy, perfluoroalkyl, arylalkyl, silyl, siloxy, siloxane, sulfonyl, sulfonoaryl, or sulfonoheteroaryl or is linked by a phosphate, phosphine, urea, amide, imide, triazole, thioether, vinyl thioether, carbonate, thiocarbonate, or dithiocarbonate group or the like. In some non-limiting embodiments, carbon atom(s) in the described covalent-linking group may be replaced with at least one heteroatom selected from N, O, S, and Se. In some non-limiting embodiments, Z comprises one or more aryl, heteroaryl, and aromatic groups comprising substituted or unsubstituted (C₃-C₆₀) mono- or polycyclic rings that may or may not contain deuterium and whose carbon atom(s) may be replaced with at least one heteroatom selected from N, O, S, and Se. In some non-limiting embodiments, Z additionally comprises one or more (C₃-C₃₀) alicyclic rings whose carbon atom(s) may be replaced with at least one hetero atom selected from N, O, S, and Se. Z may be further substituted with one or more alkyl, cycloalkyl, aryl, nitro, cyano, amino, halo, hydroxy, thioxy, selenoxy, carboxy, thiocarboxy, dithiocarboxy, alkenyl, alkynyl, cycloalkyl, heteroaryl, alkoxy, aryloxy, heteroaryloxy, alkoxycarbonyl, thioalkoxy, selenoalkoxy, ketoxy, perfluoroalkyl, perfluoroalkoxy, arylalkyl, silyl, siloxy, siloxane, sulfonyl, amido, amino, arylamido, arylamino, sulfonoaryl, sulfonoheteroaryl or may be substituted with a phosphate, phosphine, urea, amide, imide, triazole, thioether, vinyl thioether, carbonate, thiocarbonate, or dithiocarbonate group. In some non-limiting embodiments, substitutents comprising N or Si atoms may comprise additional groups R′ and R″, where each R′ and R″ is independently an optionally substituted alkyl, cycloalkyl, aryl, or heteroaryl group. R′ and R″, together with the nitrogen or silicon atom to which they are bound, can form a ring system in certain embodiments. Substituents on Z may also be cross-linking substituents such as acrylate, methacrylate, alkene, alkyne, oxirane, thiirane, azide, carboxylic acid, alcohol, thiol, selenol, benzocyclobutene, and furan groups or the like. Some non-limiting examples of the compound having Formula (II) are:

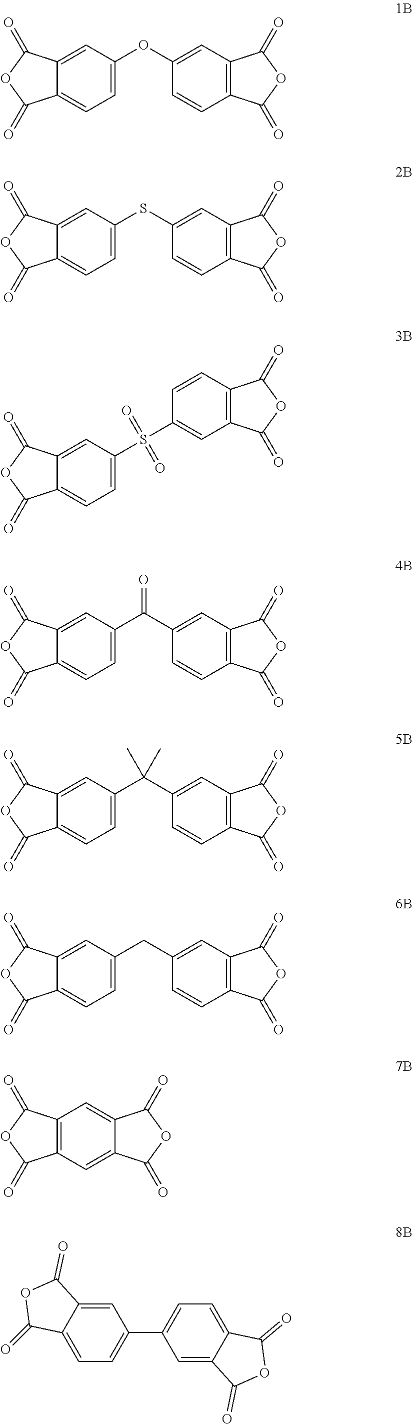

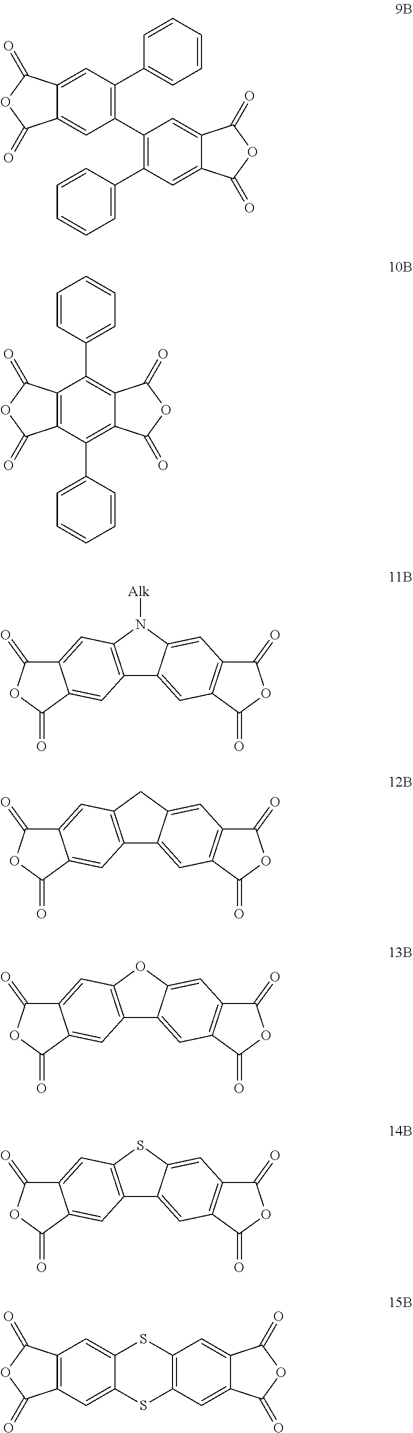

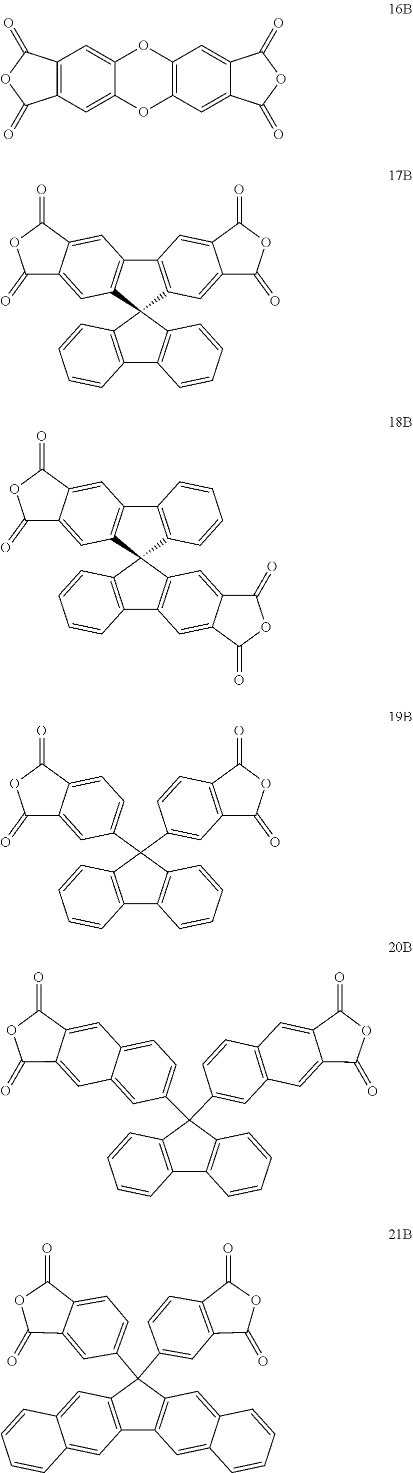

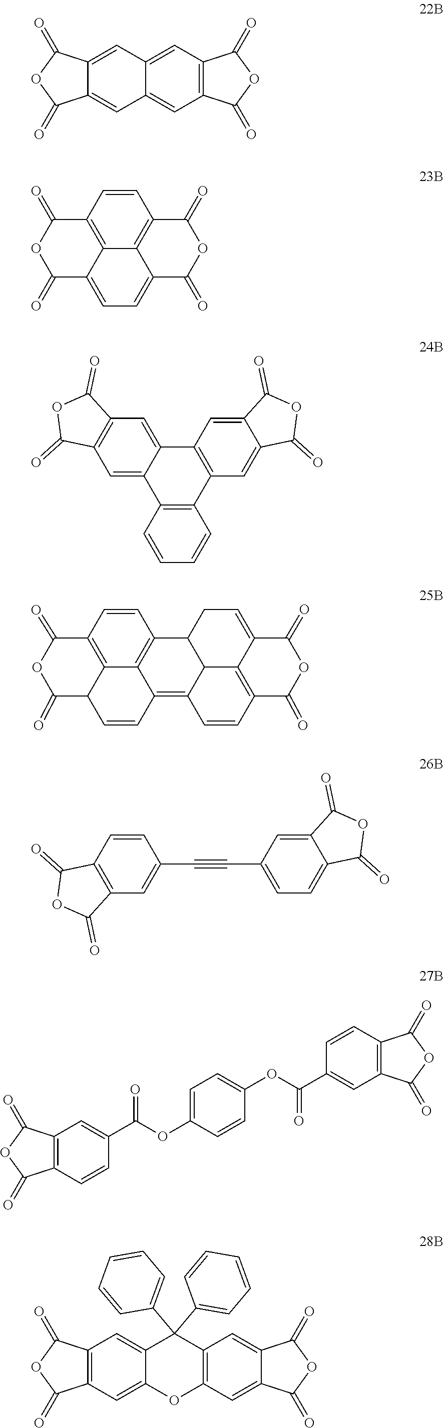

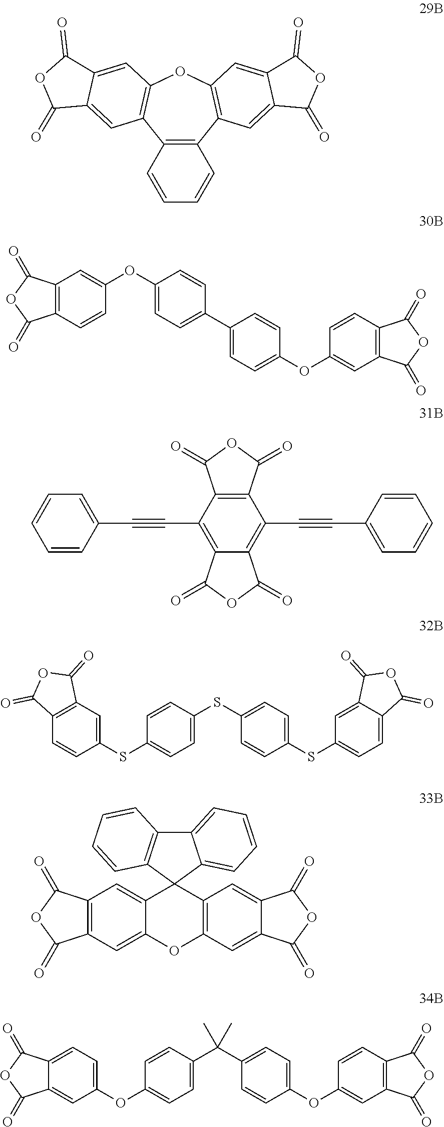 [SMILES: O=c1oc(=O)c2cc3c(cc12)oc1cc2c(=O)oc(=O)c2cc1c1ccccc31 ; O=C1OC(=O)c2cc(Oc3ccc(-c4ccc(Oc5ccc6c(c5)C(=O)OC6=O)cc4)cc3)ccc21 ; O=c1oc(=O)c2c(C#Cc3ccccc3)c3c(=O)oc(=O)c3c(C#Cc3ccccc3)c12 ; O=C1OC(=O)c2cc(Sc3ccc(Sc4ccc(Sc5ccc6c(c5)C(=O)OC6=O)cc4)cc3)ccc21 ; O=C1OC(=O)c2cc3c(cc21)Oc1cc2c(cc1C31c3ccccc3-c3ccccc31)C(=O)OC2=O ; CC(C)(c1ccc(Oc2ccc3c(c2)C(=O)OC3=O)cc1)c1ccc(Oc2ccc3c(c2)C(=O)OC3=O)cc1]

wherein Alk is a saturated linear or branched hydrocarbon group of 1 to 50 carbons that may or may not be substituted and may or may not include heteroatoms.

In some non-limiting embodiments, the second monomer having Formula (II) is selected from the group consisting of diphenylether; diphenylsulfane; diphenylsulfone; diphenylmethane; benzophenone; propane-22-diyldibenzene; phenylene; napthylene; anthracene; biphenylene; terphenylene; triphenylene; quaterphenylene; pyrene; perylene; tetrahydronapthylene; carbazole; thiocarbazole; dibenzodioxine; dibenzofuran; fluorene; spirobis(fluorene); 9,9′-diphenylfluorene; tetraphenylmethane; 12,12-diphenyldibenzofluorene; spiro[dibenzofluorene-12,9′-fluorene]; 9,9-di(naphthalene-2-yl)-fluorene; diphenylacetylene; 3,3′-oxybis(diphenylacetylene); 3,3′-thiobis(diphenylacetylene); 1,4-phenylene dibenzoate; 4,4′-diphenoxy-1,l′-biphenyl; 4,4′-(propane-2.2-diyl)bis(phenoxybenzene); tribenzooxepine; 9,9′-diphenylxanthene; spiro[fluorene-9,9-xanthene]; bisnapthalene; 1,1′-oxydinapthalene; 1,1′-thiodinapthalene; di(naphthalene-2-yl)sulfane; 1,4-bes(phenylethynyl)benzene; bis(4-(phenylthiol)phenyl)sulfane; thianthrene; phenothiazine; and phenazine.

Suitable solvents and cosolvents useful in the preparation of the copolymer compositions disclosed herein are generally those that will result in copolymer films prepared therefrom which exhibit uniform film quality when spin-coated, ink-jet printed, or slot-die coated at target thicknesses. The solvents and additional solvents are generally organic. Non-limiting embodiments of such solvents and additional solvents include ethers, ketones, esters, alcohols, and aromatic hydrocarbons. In some non-limiting embodiments, the solvent and/or cosolvent is selected from the group consisting of propylene glycol methyl ether, propylene glycol methyl ether acetate, diethylene glycol methyl ethyl ether, methyl isobutyl ketone, methyl ethyl ketone, methyl propyl ketone, methyl isoamyl ketone, dimethyl ketone, cyclopentanone, dibasicester-4, dibasicester-5, dibasicester-6, diphenyl ether, cyrene, methyl 3-methoxypropionate, ethyl 3-ethoxypropionate, benzyl benzoate, cyclohexanone, methyl 2-hydroxyl isobutyrate, ethyl acetate, ethyl lactate, butyl acetate, 2-butoxyethanol acetate, N-methylpyrrolidinone, dimethylacetamide, dimethylsulfoxide, dimethylformamide, anisole, γ-butyrolactone, isobutyl isobutyrate, n-heptane, and the like and combinations thereof. In some non-limiting embodiments, the solvent and/or cosolvent is selected from the group consisting of methyl isobutyl ketone, methyl isoamyl ketone, propylene glycol methyl ether acetate, methyl 3-methoxypropionate, ethyl 3-ethoxypropionate, benzyl benzoate, and the like and combinations thereof. In some non-limiting embodiments, the copolymer composition disclosed herein comprises one solvent. In some non-limiting embodiments, the copolymer composition disclosed herein comprises two or more solvents and/or additional solvents.

In some non-limiting embodiments of the copolymer composition disclosed herein, the one or more bifunctional high refractive index first monomers comprising a high refractive index aromatic core and further comprising one or more UV- or thermally reactive groups (A) given by Formula (I) is present at an amount of 1 equivalent. In some non-limiting embodiments of the copolymer composition disclosed herein, the one or more second monomers comprising a high refractive index core and further comprising one or more groups capable of reacting to increase the solubility of the copolymer in aqueous media (B) given by Formula (II) is present at an amount of 0.9-1 equivalent, in some non-limiting embodiments 0.8-1 equivalent, in some non-limiting embodiments 0.7-1 equivalent, in some non-limiting embodiments 0.6-1 equivalent, and in some non-limiting embodiments 0.5-1 equivalent.

In some non-limiting embodiments of the copolymer composition disclosed herein, the one or more solvents is present in a weight ratio of 5%-95% of the copolymer composition, in some non-limiting embodiments 10%-90%, in some non-limiting embodiments 20%-80%, in some non-limiting embodiments 30%-70%, in some non-limiting embodiments 40%-70%, and in some non-limiting embodiments 55%-65%.

In some non-limiting embodiments of the copolymer compositions disclosed herein, one or more ring-opening catalysts are present, having been used to prepare the monomer. The choice of an appropriate ring-opening catalyst is not particularly limited and can be determined in each case by one having skill in the art. In some non-limiting embodiments of the copolymer compositions disclosed herein, the ring-opening catalysts used to prepare the monomer are selected from Lewis acidic catalysts. In some non-limiting embodiments of the copolymer compositions disclosed herein, the ring-opening catalysts used to prepare the monomer are selected from the group consisting of tetra-substituted ammonium salts, tetra-substituted phosphonium salts, metal halides, and imidazolium salts. In some non-limiting embodiments of the copolymer compositions disclosed herein, ring-opening catalysts are selected from the group consisting of tetraethylammonium iodide, tetraethylammonium bromide, tetraethylammonium chloride, tetrabutylammonium iodide, tetrabutylammonium bromide, tetrabutylammonium chloride, tetraethylphosphonium iodide, tetraethylphosphonium bromide, tetraethylphosphonium chloride, tetrabutylphosphonium iodide, tetrabutylphosphonium bromide, tetrabutylphosphonium chloride, trimethylbenzylammonium chloride, trimethylbenzylammonium bromide, trimethylbenzylammonium iodide, methyltriphenylphosphonium iodide, methyltriphenylphosphonium bromide, methyltriphenylphosphonium chloride, tetraphenylphosphonium iodide, tetraphenylphosphonium bromide, tetraphenylphosphonium chloride, methyl imidazolium iodide, methyl imidazolium bromide, methyl imidazolium chloride, ethyl imidazolium iodide, ethyl imidazolium bromide, ethyl imidazolium chloride, zinc (II) dichloride, aluminum (III) trichloride, zinc (II) dibromide, and aluminum (III) tribromide.

In some non-limiting embodiments of the copolymer compositions disclosed herein, one or more ring-opening catalysts is present at a level of 0.5-20 mol % of the one or more bifunctional high refractive index first monomers comprising a high refractive index aromatic core and further comprising one or more UV- or thermally reactive groups (A) given by Formula (I). In some non-limiting embodiments 0.1-10 mol %, in some non-limiting embodiments 0.1-6 mol %, in some non-limiting embodiments 0.1-3 mol % and in some non-limiting embodiments 3-5 mol %.

In some non-limiting embodiments of the copolymer composition disclosed herein, the copolymer composition comprises one or more additional monomers comprising a high refractive index core (A′).

In some non-limiting embodiments, the one or more additional monomers comprising a high refractive index core (A′) has a refractive index measured at 550 nm that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more additional monomers comprising a high refractive index core (A′) has a refractive index measured at other wavelengths of the visible spectrum. In some non-limiting embodiments, the refractive index is measured between 380 nm and 780 nm. In some non-limiting embodiments, between 400 nm and 700 nm. In some non-limiting embodiments, between 450 nm and 650 nm. In some non-limiting embodiments, between 500 nm and 600 nm.

In some non-limiting embodiments, the one or more additional monomers comprising a high refractive index core (A′) has a refractive index measured at these other wavelengths of the visible spectrum that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more additional monomers comprising a high refractive index core (A′) is given by Formula (III):

Y-Q′-Y Formula (III)
wherein Q′ is a high refractive index aromatic core comprising one or more aryl or heteroaryl groups and Y is the same or different at each occurrence and is a nucleophilic reactive group. In some non-limiting embodiments, Q′ comprises two or more aryl or heteroaryl groups which are covalently linked by an alkyl, cycloalkyl, alkenyl, alkynyl, aryl, heteroaryl, aryloxy, arylthioxy, arylselenoxy, amino N(R′)(R″), arylcarbonyl, ketoxy, perfluoroalkyl, arylalkyl, silyl, siloxy, siloxane, sulfonyl, sulfonoaryl, or sulfonoheteroaryl or is linked by a phosphate, phosphine, urea, amide, imide, triazole, thioether, vinyl thioether, carbonate, thiocarbonate, or dithiocarbonate group or the like. In some non-limiting embodiments, Q′ comprises one or more aryl or heteroaryl groups comprising substituted or unsubstituted (C₃-C₆₀) mono- or polycyclic rings that may or may not contain deuterium and whose carbon atom(s) may be replaced with at least one hetero atom selected from N, O, S, and Se. In some non-limiting embodiments, Q′ additionally comprises one or more (C₃-C₃₀) alicyclic rings whose carbon atom(s) may be replaced with at least one hetero atom selected from N, O, S, and Se. Q′ may be further substituted with one or more alkyl, cycloalkyl, aryl, nitro, cyano, amino, halo, hydroxy, thioxy, selenoxy, carboxy, thiocarboxy, dithiocarboxy, alkenyl, alkynyl, cycloalkyl, heteroaryl, alkoxy, aryloxy, heteroaryloxy, alkoxycarbonyl, thioalkoxy, selenoalkoxy, ketoxy, perfluoroalkyl, perfluoroalkoxy, arylalkyl, silyl, siloxy, siloxane, sulfonyl, amido, amino, arylamido, arylamino, sulfonoaryl, sulfonoheteroaryl or may be substituted with a phosphate, phosphine, urea, amide, imide, triazole, thioether, vinyl thioether, carbonate, thiocarbonate, or dithiocarbonate group. Each R′ and R″ is independently an optionally substituted alkyl, cycloalkyl, or aryl group. R′ and R″, together with the nitrogen atom to which they are bound, can form a ring system in certain embodiments. Substituents on Q′ may also be cross-linking groups such as acrylate, methacrylate, alkene, alkyne, oxirane, thiirane, azide, carboxylic acid, alcohol, thiol, selenol, benzocyclobutene, and furan groups or the like.

In some non-limiting embodiments, Y is the same or different at each occurrence and is attached to Q′ via one or more carbons or heteroatoms such as S, N(R′), P, P(O)(O), O, B(R′), Si(R′)(R″), or Se and contains a primary or secondary nucleophilic end group such as hydroxyl, thiol, selenol, carboxylate, thiocarboxylate, dithiocarboxylate, amide, phosphate, or phosphine additionally comprising S, N, P, O, B, Si, or Se.

Some non-limiting examples of the one the compound having Formula (III) are:

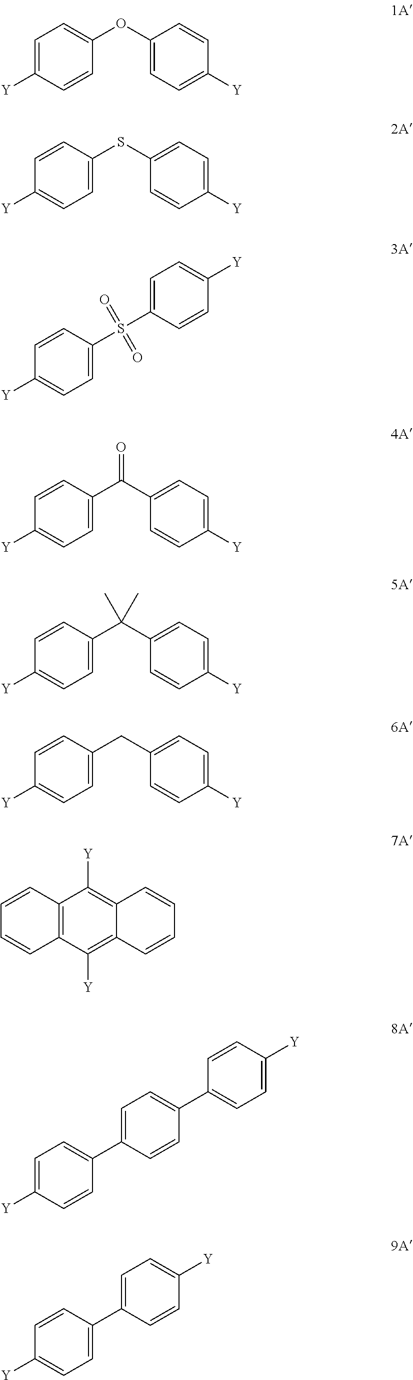

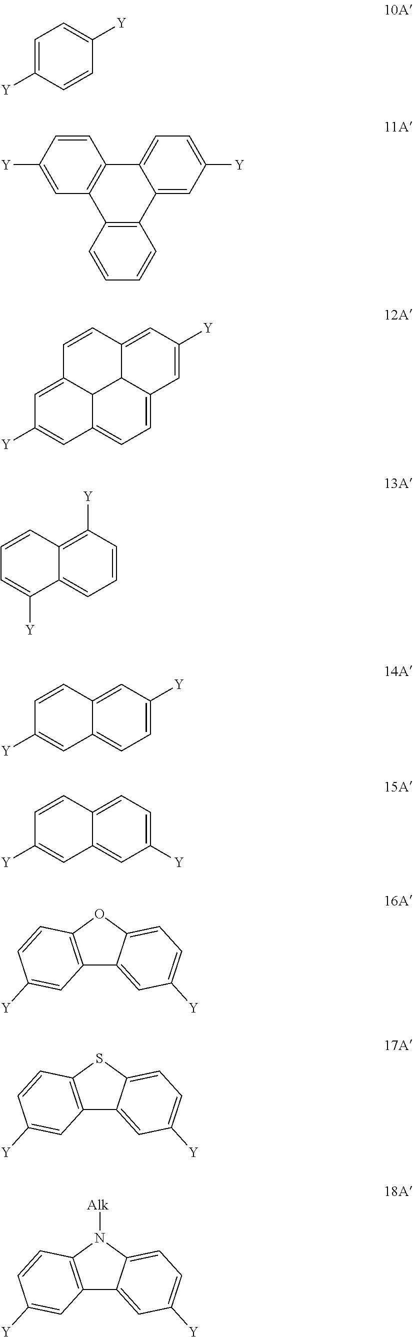

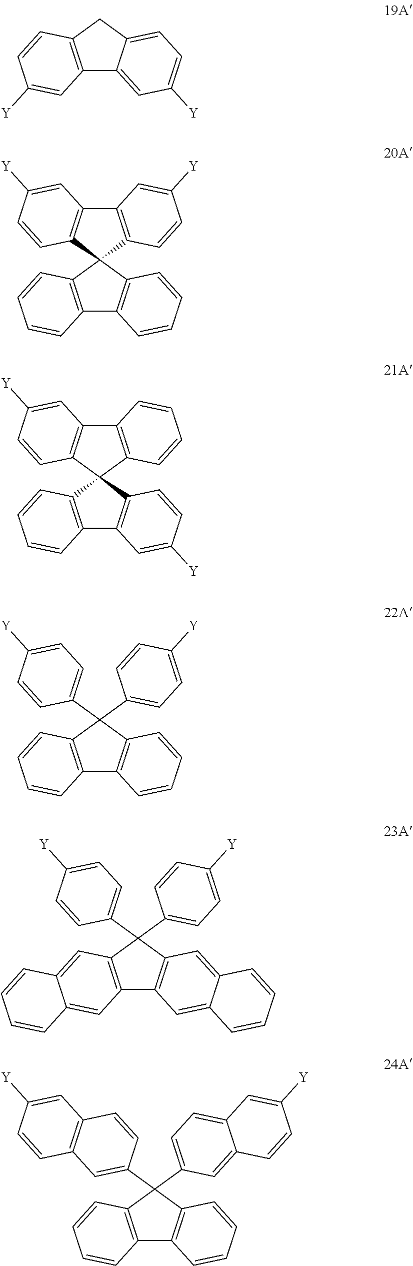

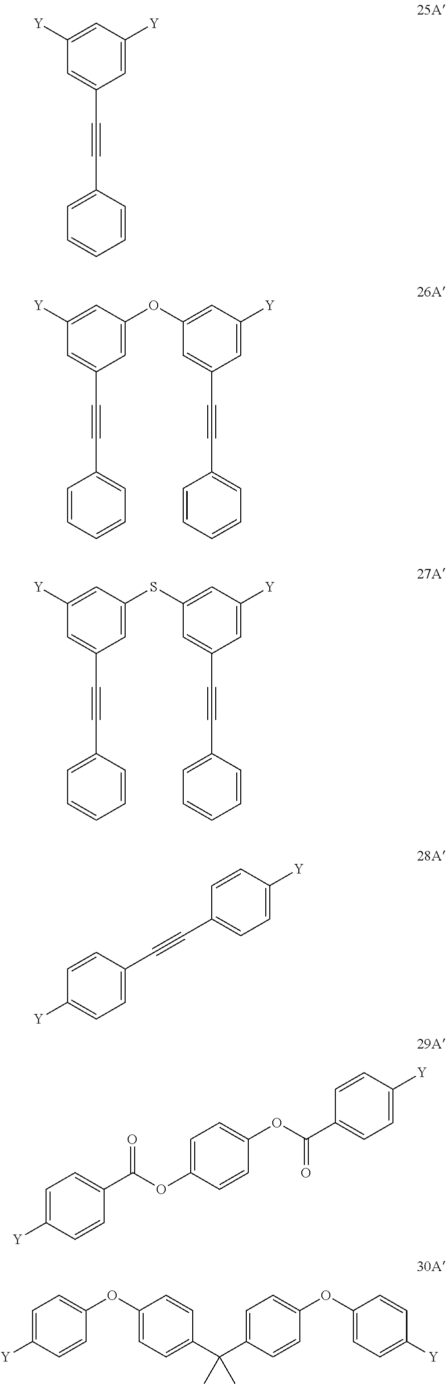

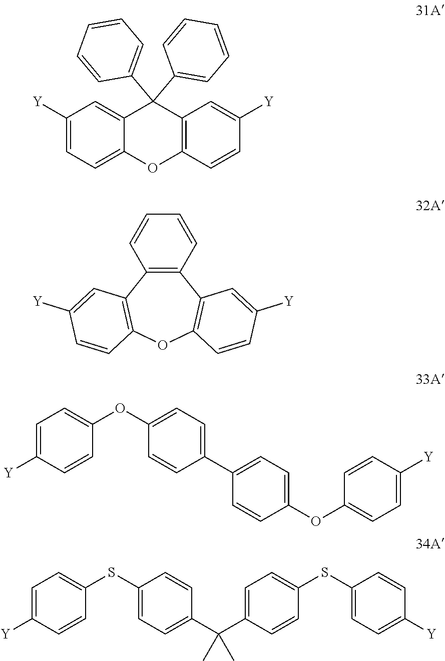

wherein Y is as defined above and Alk is a saturated linear or branched hydrocarbon group of 1 to 50 carbons that may or may not be substituted and may or may not include heteroatoms.

In some non-limiting embodiments, the one or more additional monomers comprising a high refractive index core (A ‘) having Formula (III) is selected from the group consisting of diphenylether; diphenylsulfane; diphenylsulfone; diphenylmethane; benzophenone; propane-22-diyldibenzene; phenylene; napthylene; anthracene; biphenylene; terphenylene; triphenylene; pyrene; carbazole; thiocarbazole; dibenzofuran; fluorene; spirobis(fluorene); 9,9’-diphenylfluorene; tetraphenylmethane; 12,12-diphenyldibenzofluorene; spiro[dibenzofluorene-12,9′-fluorene]; 9,9-di(naphthalene-2-yl)-fluorene; diphenylacetylene; 3,3′-oxybis(diphenylacetylene); 3,3′-thiobis(diphenylacetylene); 1,4-phenylene dibenzoate; 4,4′-diphenoxy-1,1′-biphenyl; 4,4′-(propane-2,2-diyl)bis(phenoxybenzene); tribenzooxepine; 9,9′-diphenylxanthene; bisnapthalene; 1,1′-oxydinapthalene; 1,1′-thiodinapthalene;

napthylbenzimidazolone; di(naphthalene-2-yl)sulfane; thianthrene; phenothiazine; and phenazine.

In some non-limiting embodiments of the copolymer composition disclosed herein, the one or more additional monomers comprising a high refractive index core (A′) given by Formula (III) are used in conjunction with the one or more bifunctional high refractive index first monomers comprising a high refractive index aromatic core and further comprising one or more UV- or thermally-reactive groups (A) as given by Formula (I) as a means to adjust the overall refractive index or cross-link density of the film or coating prepared from the copolymer composition. In some non-limiting embodiments of the copolymer composition disclosed herein, the one or more additional monomers comprising a high refractive index core (A′) given by Formula (III) is present at an amount relative to the one or more bifunctional high refractive index first monomers comprising a high refractive index aromatic core and further comprising one or more UV- or thermally-reactive groups (A) as given by Formula (I) of 0.01-0.99 equivalents, in some non-limiting embodiments 0.1-0.9 equivalents, in some non-limiting embodiments 0.2-0.8 equivalents, in some non-limiting embodiments 0.3-0.7 equivalents, in some non-limiting embodiments 0.4-0.6 equivalents, and in some non-limiting embodiments 0.5 equivalents.

In some non-limiting embodiments of the copolymer composition disclosed herein, the copolymer composition additionally comprises one or more monofunctional monomers (M) given by Formula (IV):

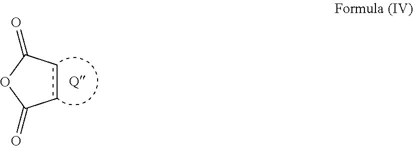

wherein Q″ comprises one or more alkyl, cycloalkyl, alkenyl, aryl, or heteroaryl groups.

In some non-limiting embodiments, the one or more monofunctional monomers given by Formula (IV) has a refractive index measured at 550 nm that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, the one or more monofunctional monomers given by Formula (IV) has a refractive index measured at other wavelengths of the visible spectrum. In some non-limiting embodiments, the refractive index is measured between 380 nm and 780 nm. In some non-limiting embodiments, between 400 nm and 700 nm. In some non-limiting embodiments, between 450 nm and 650 nm. In some non-limiting embodiments, between 500 nm and 600 nm.

In some non-limiting embodiments, the one or more monofunctional monomers given by Formula (IV) has a refractive index measured at these other wavelengths of the visible spectrum that is greater than 1.500. In some non-limiting embodiments, greater than 1.600. In some non-limiting embodiments, greater than 1.650. In some non-limiting embodiments, greater than 1.680. In some non-limiting embodiments, greater than 1.700. In some non-limiting embodiments, greater than 1.800.

In some non-limiting embodiments, Q″ comprises one or more aryl or heteroaryl groups comprising substituted or unsubstituted (C₃-C₆₀) mono- or polycyclic rings that may or may not contain deuterium and whose carbon atom(s) may be replaced with at least one hetero atom selected from N, O, S, and Se. In some non-limiting embodiments, Q″ additionally comprises one or more (C₃-C₃₀) alicyclic rings whose carbon atom(s) may be replaced with at least one hetero atom selected from N, O, S, and Se. Q″ may be further substituted with one or more alkyl, cycloalkyl, aryl, nitro, cyano, amino, halo, hydroxy, thioxy, selenoxy, carboxy, thiocarboxy, dithiocarboxy, alkenyl, alkynyl, cycloalkyl, heteroaryl, alkoxy, aryloxy, heteroaryloxy, alkoxycarbonyl, thioalkoxy, selenoalkoxy, ketoxy, perfluoroalkyl, perfluoroalkoxy, arylalkyl, silyl, siloxy, siloxane, sulfonyl, amido, amino, arylamido, arylamino, sulfonoaryl, sulfonoheteroaryl or may be substituted with a phosphate, phosphine, urea, amide, imide, triazole, thioether, vinyl thioether, carbonate, thiocarbonate, or dithiocarbonate group. Each R′ and R″ is independently an optionally substituted alkyl, cycloalkyl, or aryl group. R′ and R″, together with the nitrogen atom to which they are bound, can form a ring system in certain embodiments. Substituents on Q″ may also be cross-linking groups cross-linking substituents such as acrylate, methacrylate, alkene, alkyne, oxirane, thiirane, azide, carboxylic acid, alcohol, thiol, selenol, benzocyclobutene, and furan groups or the like.

Some non-limiting examples of the one or more monofunctional monomers having Formula (IV) are:

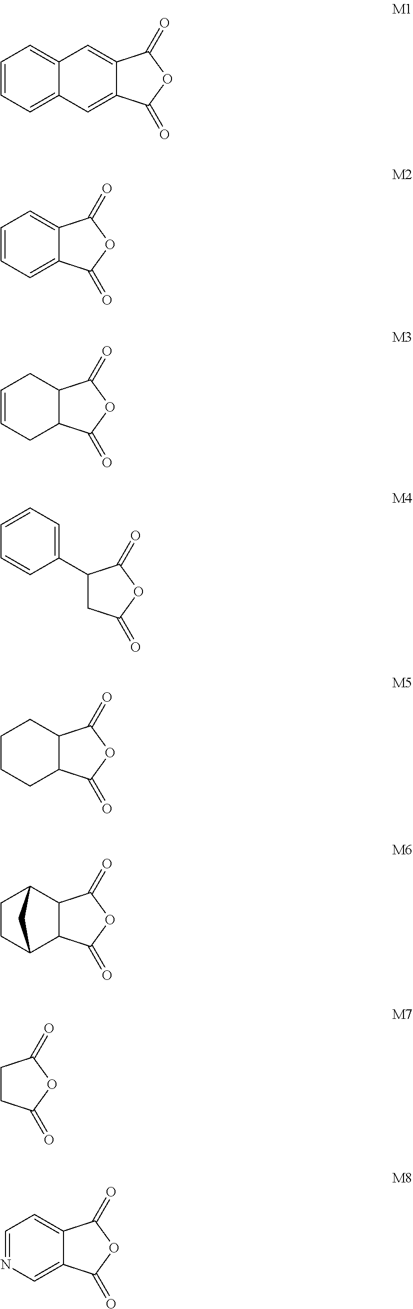

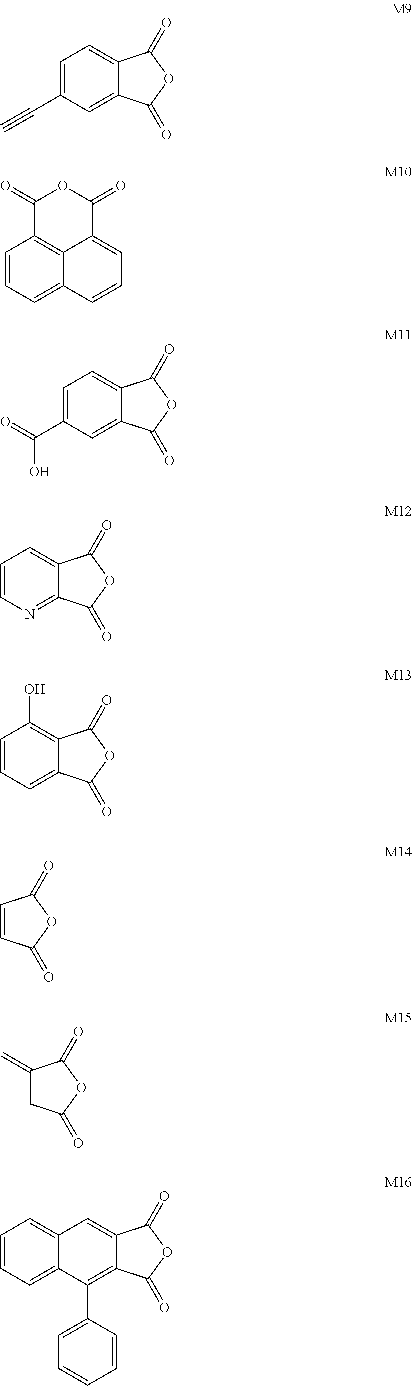

In some non-limiting embodiments, the one or more monofunctional monomers is selected from the group consisting of 1,2-napthalic anhydride, phathalic anhydride; 3,4,5,6-tetahydrophthalic anhydride; 1,2,3,6-tetahydrophthalic anhydride; phenylsuccinic anhydride; cyclohexanedicarboxylic anhydride; hexahydro-4,7-methanoisobenzofuran-1,3-dione; succinic anhydride; maleic anhydride; citraconic anhydride; cis-aconitic anhydride; S-acetylmercaptosuccinic anhydride; 2-acetoxysuccinic anhydride; 2,3-dimethylmaleic anhydride; 1,2,4-benzenetricarboxylic anhydride; 4-alkynylphthalicanhydride; 2,3-pyridinedicarboxylic anhydride;3,4-pyridinedicarboxylic anhydride; 1,8-napthalic anhydride; 4-hydroxyisobenzofuran-1,3-dione; itaconic anhydride; and 1-phenyl-2,3-napthalenedicarboxylic anhydride.

In some non-limiting embodiments of the copolymer composition disclosed herein, the one or more monofunctional monomers given by Formula (IV) are introduced as a means to adjust the molecular weight of one or more of the polymeric components of the copolymer composition. This can provide additional synthetic control of mechanical, optical, thermal, and other properties associated with the disclosed copolymer compositions. One having skill in the art would appreciate how this molecular weight control might benefit the overall performance of these disclosed compositions in targeted applications. In some non-limiting embodiments of the copolymer composition disclosed herein, the one or more monofunctional monomers given by Formula (IV) is present at an amount of 0.01-2.00 equivalent, in some non-limiting embodiments 0.10-1.00 equivalent, in some non-limiting embodiments 0.10-0.80 equivalents, in some non-limiting embodiments 0.10-0.60 equivalents, in some non-limiting embodiments about 0.1-0.4 equivalents, and in some non-limiting embodiments 0.2-0.4 equivalents.

In some non-limiting embodiments, the copolymer composition disclosed herein may be chemically modified after polymerization. Post-polymerization modifications may include azide-alkyne “click” reactions, thiol-ene “click” reactions, alkylation, esterification, acetylation, and silylation.

The copolymer composition as disclosed herein can be polymerized and cured to form the corresponding copolymer solid. It can be directly cast as a film, applied as a coating, or poured into one or more non-solvents to precipitate the polymer. Non-polar solvents such as hexanes, heptane, toluene, and the like or polar solvents such as water, methanol, and the like are typical non-solvents which can be used to precipitate the copolymer. Solid copolymer may be dissolved and processed from a suitable organic solvent described above, or from organic solvents typically used in the electronics industry; such as propylene glycol methyl ether (PGME), propylene glycol methyl ether acetate (PGMEA), methyl 3-methoxypropionate (MMP), ethyl 3-methoxypropionate (EEP), ethyl lactate, n-butyl acetate, anisole, N-methyl pyrrolidone (NMP), gamma-butyrolactone (GBL), ethoxybenzene, benzyl propionate, benzyl benzoate, propylene carbonate, and mixtures thereof. Mixtures of organic solvents may also be used, such as a mixture comprising one or more of anisole, ethoxybenzene, PGME, PGMEA, GBL, MMP, EEP, n-butyl acetate, benzyl propionate, and benzyl benzoate in combination with one or more additional organic solvents, and more preferably a mixture comprising two or more of anisole, ethoxybenzene, PGME, PGMEA, GBL, MMP, n-butyl acetate, benzyl propionate, and benzyl benzoate. When a mixture of solvents is used, the ratio of solvents is generally not critical and may vary from 99:1 to 1:99 w/w. It will be appreciated by those skilled in the art that the concentration of the copolymer in the organic reaction solvent may be adjusted by removing a portion of the organic solvent, or by adding more of the organic solvent, as may be desired.

In some non-limiting embodiments of the copolymer composition disclosed herein, the copolymer has a number-average molecular weight in Daltons between 500 and 100,000 as determined using gel permeation chromatography (GPC, using tetrahydrofuran or dimethylacetamide as an eluent and using polystyrene standards or light-scattering detection for calibration of the molecular weights as detected by refractive index measurements). In some non-limiting embodiments between 1,000 and 50,000; in some non-limiting embodiments between 1,000 and 25,000; in some non-limiting embodiments between 1,000 and 20,000; in some non-limiting embodiments between 1,000 and 15,000; in some non-limiting embodiments between 1,000 and 10,000; and in some non-liming embodiments between 1,000 and 5,000.

In some non-limiting embodiments of the copolymer composition disclosed herein,

the copolymer has a weight-average molecular weight in Daltons between 500 and 100,000 as determined using gel permeation chromatography (GPC, using tetrahydrofuran or dimethylacetamide as an eluent and using polystyrene standards or light-scattering detection for calibration of the molecular weights as detected by refractive index measurements). In some non-limiting embodiments between 2,000 and 100,000; in some non-limiting embodiments between 2,000 and 50,000; in some non-limiting embodiments between 2,000 and 40,000; in some non-limiting embodiments between 2,000 and 30,000; in some non-limiting embodiments between 2,000 and 20,000; and in some non-liming embodiments between 1,000 and 10,000.

For coating formation, the copolymer compositions disclosed herein can be applied by spin-coating, dipping, drop-casting, roller-coating, screen printing, ink-jet printing, gravure, slot-die coating, or other conventional coating techniques. In the electronics manufacturing industry, spin-coating and slot-die coating are preferred methods to take advantage of existing equipment and processes. In spin-coating, the solids content of the composition may be adjusted, along with the spin speed and time, to achieve a desired thickness of the composition on the surface it is applied to. Typically, the present compositions are spin-coated at a spin speed of 400 to 4000 rpm. The amount of the composition dispensed on the substrate depends on the total solids content in the composition, the desired thickness of the resulting coating layer, and other factors well-known to those skilled in the art.

Substrates onto which the materials may be coated are those generally used in the art. In some non-limiting embodiments, the substrates used are selected from the group consisting of silica, silicon, silicon nitride, silicon oxynitride, silicon carbide, silicon-germanium, gallium-arsenide, indium-phosphide, aluminum nitride, alumina, glass, and the like. In some non-limiting embodiments, the substrates used are selected from the group consisting of silica, silicon, silicon nitride, and silicon carbide. In some non-limiting embodiments, the substrate used is silicon. In some non-limiting embodiments, the substrate used is glass. In some non-limiting embodiments, the substrates used are cured polymeric films deposited on any of the aforementioned materials.

The thickness of the coating and/or optical thin film is not particularly limited and will depend, for example, on the particular application or use. In some non-limiting embodiments, the thickness of the coating and/or optical thin film is between 10 nm and 100 μm. In some non-limiting embodiments, the thickness of the coating and/or optical thin film is between 100 nm and 10 μm. In some non-limiting embodiments, the thickness of the coating and/or optical thin film is between 500 nm and 1 μm. In some non-limiting embodiments, the thickness of the coating and/or optical thin film is between 1 μm and 20 μm, in some non-limiting embodiments between 1 μm and 10 μm, in some non-limiting embodiments between 1 μm and 5 μm, and in some non-limiting embodiments between about 2 μm and 5 μm.

Generally, after being coated on a substrate surface, the copolymer composition is heated (soft-baked) to remove any organic solvent present. Typical baking temperatures are from 85 to 140° C., although other suitable temperatures may be used. Such baking to remove residual solvent is typically done for approximately 30 seconds to 2 minutes, although longer or shorter times may suitably be used. Following solvent removal, a layer, film, or coating of the copolymer on the substrate surface is obtained.

After the soft-bake step, the coating comprising the copolymer composition may be optionally further dried under vacuum to remove residual solvent. A vacuum level of 200 to 400 mTorr is typically applied for 20 to 100 seconds. Such vacuum drying to remove residual solvent is typically done at 200 mTorr for 1 to 10 seconds, although longer or shorter times may suitably be used. Drying under vacuum typically occurs at room temperature.

After the soft-bake step, the coating comprising the copolymer composition may optionally be exposed to light, causing a photo-chemical reaction. The light exposure may optionally be patterned to create features upon the substrate. Features are typically formed by exposing portions of the coating to light through a photo-mask, triggering a photochemical reaction in the exposed regions. The wavelength of light is selected based on the application and material composition. In some cases, the photochemical reaction decreases the solubility of the exposed area (negative photoresist design), and in other cases, the photochemical reaction increases the solubility of the exposed area (positive photoresist design). After the light exposure step, the soluble portions of the photopatterned coating are rinsed away with a developer solvent. Depending on the particular copolymer and components of the composition, the photopatterning may cause further change to the copolymer, for example, through one or more of polymerization, condensation, cross-linking, deprotection, or bond cleavage. The photopatterning step is typically conducted in a mask aligner. The wavelength, time, and intensity of the light exposure in the patterning step will depend on the particular copolymer composition and the layer thickness. In some non-limiting embodiments, the coated film was exposed, through a photo-mask having a pattern consisting of square holes 1-100 μm in size, to broad-band light (300 to 800 nm) at an exposure dosage of 10 to 200 mJ/cm² based on a wavelength of 365 nm for a time period of 0.5 to 80 seconds using an aligner, which emits light having a wavelength of 300 nm to 800 nm (10-35 mW/cm²). In some non-limiting embodiments, the developer used is an aqueous solution of 2.38 wt % tetramethylammonium hydroxide dispensed as a puddle to completely cover the film for 40 to 10 seconds, and then rinsed by distilled water for 30 seconds.

After the soft bake step and light exposure step, if applicable, the coating comprising the copolymer composition is typically cured at elevated temperature to remove substantially all of the solvent from the polymeric layer, thereby forming a tack-free coating, improving adhesion of the layer to the underlying structure, and/or removing any species that may off-gas at a later step. Depending on the particular copolymer and components of the composition, the cure may cause further change to the copolymer, for example, through one or more of oxidation, outgassing, polymerization, condensation, or cross-linking. The cure is typically conducted on a hotplate or in an oven. The cure can be conducted, for example, in an atmosphere of air or inert gas such as nitrogen, argon, or helium, or can be conducted under vacuum. In one non-limiting embodiment, the polymeric layer is cured in an inert gas atmosphere. In one non-limiting embodiment, the polymeric layer is cured under ambient atmospheric conditions. The temperature and time for the cure will depend, for example, on the particular copolymer and solvent of the composition, and the layer thickness. In some non-limiting embodiments, cure temperatures are from 100 to 450° C. In some non-limiting embodiments, cure temperatures are 300 to 400° C., or from 325 to 350° C. In coatings wherein the copolymer layer comprises a cross-linker and/or a photo or thermal acid generator (see below), lower cure temperatures can sometimes be used. In some non-limiting embodiments, these lower cure temperatures are from 50 to 250° C. In some non-limiting embodiments, these lower cure temperatures are from 100 to 250° C. In some non-limiting embodiments, these lower cure temperatures are from 150 to 250° C. In some non-limiting embodiments, these lower cure temperatures are from 200 to 250° C. In one non-limiting embodiment, wherein the copolymeric layer comprises a cross-linker, the cure temperature is 230° C. In some non-limiting embodiments, the cure time is from 30 seconds to two hours. In some non-limiting embodiments, the cure time is from 1 minute to 60 minutes. In one non-limiting embodiment, the cure time is 30 minutes. The cure can be conducted in a single step or in multiple steps. The cure can be conducted by heating the copolymer composition layer at constant temperature or with a varied temperature profile such as a ramped or terraced temperature profile.

Cured copolymer materials, thin films, and the like are generally characterized by compositions corresponding to those as disclosed herein by the embodiments for the copolymer formulations, generally without the solvent component, which is removed via the processes described herein.

The copolymer compositions disclosed herein may be used in formulations containing one or more additional species that contribute to their overall utility in delivering superior properties of interest in electronics and displays applications. Formulations may be prepared which optionally comprise any one or more of: (f) one or more additional polymers or copolymers; (g) one or more photo-initiators and/or thermal initiators; (h) one or more cross-linking agents; (i) one or more antioxidants; and (j) one or more surface leveling agents.

In some non-limiting embodiments, formulations may be prepared which comprise the copolymer compositions disclosed herein and one or more additional polymers or copolymers. These additional polymers or copolymers may include poly(acrylic acid), polyacrylates, polymethacrylates, polyacrylamides, polyacrylonitriles, polyvinyls, polystyrene, poly(hydroxystyrene), poly(vinyl ether)s, polyarylenes, polyimides, poly(amic acid)s, poly(ester acid)s, polyurethanes, polycarbonates, polyesters, polyamides, polysilanes, polysiloxanes, silicones, polymeric ionic liquids, and the like and combinations thereof. It should be noted that addition of the second, or subsequent, polymer or copolymer does not negatively impact the overall optical properties of the composition for the applications disclosed herein, and may possess high optical density, reactive side chains, or polar protic side chains, and the like and combinations thereof.

In some non-limiting embodiments, formulations may be prepared which comprise the copolymer compositions disclosed herein and a photochemically-activated catalyst. In some non-limiting embodiments, the photochemically-activated catalyst is selected from the group consisting of Cyracure™ UVI-6970, Cyracure™ UVI-6974, Cyracure™ UVI-6990, Cyracure™ UVI-950, Irgacure® 250, Irgacure® 261, Irgacure® 264, SP-150, SP-151, SP-170, Optmer SP-171, CG-24-61, DAICAT II, UVAC1590, UVAC1591, CI-2064, CI-2638, CI-2624, CI-2481 CI-2734, CI-2855, CI-2823, CI-2758, CIT-1682, PI-2074, FFC509, BBI-102, BBI-101, BBI-103, MPI-103, TPS-103, MDS-103, DTS-103, NAT-103, NDS-103, CD-1010, CD-1011, CD-1012, CPI-100P, CPI-101A, MIPHOTO TPA-517, MIPHOTO BCF-530D, and the like and combinations thereof.

The formulations of the present disclosure may contain one or more photoinitiators in order to render them photocurable, such light-activated photoinitiators being activated by the appropriate wavelength radiation. A wide variety of photoinitiators may be used. The photoinitiators can comprise acylphosphine oxides, aminoalkylphenones, hydroxylketones, benzil ketals, benzoin ethers, benzophenone, or thioxanthones.

Examples of the photoinitiators can include, but are not limited to, α-hydroxyketones such as 2-hydroxy-2-methyl-1-phenylpropanone (OMNIRAD™ 1173, commercially available from IGM Resins), 1-hydroxycyclohexyl phenyl ketone (OMNIRAD™ 184, commercially available from IGM Resins), 1-[4-(2-hydroxyethyoxyl)-phenyl]-2-hydroxy-2-methyl-1-propanone (OMNIRAD™ 2959, commercially available from IGM Resins); 2-ethylhexyl 2-([1,1′-biphenyl]-4-ylcarbonyl)benzoate (OMNIRAD™ 601, commercially available from IGM Resins); benzoin dimethyl ether; benzyldimethyl-ketal; α-aminoketone; monoacyl phosphines; bisacyl phosphines; phosphine oxides such as diphenyl(2.4,6-trimethylbenzoyl)phosphine oxide, 2, 4, 6-trimethylbenzoyl-diphenyl-phosphine oxide (OMNIRAD™ TPO, commercially available from IGM Resins), bis(2,4,6-trimethylbenzoyl)-phenylphosphineoxide (OMNIRAD™ 819, commercially available from IGM Resins), ethyl(3-benzoyl-2,4,6-trimethylbenzol)(phenyl) phosphinate (SPEEDCURE™ XKm, commercially available from Lambson Limited, Wetherby, United Kingdom); diethoxy-acetophenone (DEAP); 1-[4-(Phenylthio)phenyl]-1,2-octanedione 2-(O-benzoyloxime) (OXE-01, Naide Fine Chemicals); 1-[9-Ethyl-6-(2-methylbenzoyl)-9H-carbazol-3-yl]-ethanone-1-(O-acetyloxime) (OXE-02, Naide Fine Chemicals); Irgacure OXE-03 (BASF Corp); Irgacure OXE-04 (BASF Corp); 2-Methyl-4′-(methylthio)-2-morpholinopropiophenone (Irgacure 907, BASF Corp); SPI-02, SPI-03, SPI-04, SPI-05, SPI-06 (Samyang Corporation); PBG-304, PBG-305, PBG-314, PBG-3057, PBG-326, PBG-363 (Changzhou Tronly New Electric Materials Co. LTD); and mixtures thereof such as a blend of 2-hydroxy-2-methyl-1-phenylpropanone, bis(2,4,6-trimethylbenzoyl)phenylphosphine oxide and cthyl(2.4,6-trimethylbenzoyl)-phenyl phosphinate (OMNIRAD™ 2022, commercially available from IGM Resins); a blend of bis(2,4,6-trimethylbenzoyl)phenylphosphine oxide and ethyl(2,4,6-trimethylbenzoyl)-phenyl phosphinate (OMNIRAD™ 2100, commercially available from IGM Resins); a blend of oxy-phenyl-acetic acid 2-[2-oxo-2-phenyl-acetoxy-ethoxy]-ethyl ester and oxy-phenyl-acetic acid 2-[2-hydroxy-ethoxy]-ethyl ester (OMNIRAD™ 754, commercially available from IGM Resins); Esacure ONE (commercially available from IGM Resins); and a blend of diphenyl(2,4,6-trimethylbenzoyl)phosphine oxide and 2-hydroxy-2-methylpropiophenone (OMNIRAD™ 4265, commercially available from IGM Resins); NCI-730 (ADEKA Corp); and NCI-930 (ADEKA Corp). The selection of the particular UV wavelength to use for a given photoinitiator, as well as the length of exposure, is well-known to those skilled in the art.

Examples of the photoinitiators can include, but are not limited to oxime ester molecules described by the formula:

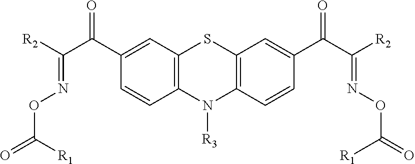

wherein R₁ to R₃ each are independently hydrogen, halogen, (C1-C20)alkyl, (C6-C20) aryl, (C1-C20)alkoxy, (C6-C20) aryl(C1-C20)alkyl, hydroxy (C1-C20)alkyl, hydroxy (C1-C20)alkoxy (C1-C20)alkyl, or (C3-C20)cycloalkyl. Such molecules include SPI-05, commercially available from Samyang Corporation.

The photoinitiator can be present in an amount of from 0 to 5 wt %, or from 0.001 to 3 wt %, or from 0.05 to 1.5 wt %, or from 0.1 to 1.25 wt %, or from 0.5 to 1.15 wt %.

In some non-limiting embodiments, formulations may be prepared which comprise the copolymer compositions disclosed herein and a thermally-activated catalyst. In some non-limiting embodiments, the thermally-activated catalyst is selected from the group consisting of San-Aid SI-45 (Sanshin Chemical Industry), San-Aid SI-47 (Sanshin Chemical Industry), San-Aid SI-60 (Sanshin Chemical Industry), San-Aid SI-60L (Sanshin Chemical Industry), San-Aid SI-80L (Sanshin Chemical Industry), San-Aid SI-80L (Sanshin Chemical Industry), San-Aid SI-100 (Sanshin Chemical Industry), San-Aid SI-100L (Sanshin Chemical Industry), San-Aid SI-110L (Sanshin Chemical Industry), San-Aid SI-145 (Sanshin Chemical Industry), San-Aid SI-150 (Sanshin Chemical Industry), San-Aid SI-160 (Sanshin Chemical Industry), San-Aid SI-110L (Sanshin Chemical Industry), San-Aid SI-180L (Sanshin Chemical Industry), diazonium salts, iodonium salts, sulfonium salts, phosphonium salts, selenium salts, oxonium salts, ammonium salts, and metal chelates.

In some non-limiting embodiments, formulations may be prepared which comprise the copolymer compositions disclosed herein and thermally- or photochemically-activated catalyst which are present in a mole ratio of 10,000:1 to 1:1, in some non-limiting embodiments from 5,000:1 to 1:1, in some non-limiting embodiments 1,000:1 to 1:1, in some non-limiting embodiments 500:1 to 1:1, in some non-limiting embodiments 100:1 to 1:1, in some non-limiting embodiments 75:1 to 10:1, in some non-limiting embodiments 60:1 to 10:1, in some non-limiting embodiments 50:1 to 25:1, in some non-limiting embodiments 40:1 to 30:1, in some non-limiting embodiments about 40:1, in some non-limiting embodiments about 30:1, in some non-limiting embodiments about 25:1, in some non-limiting embodiments about 20:1, and in some non-limiting embodiments about 10:1.

In some non-limiting embodiments, formulations may be prepared which comprise the copolymer compositions disclosed herein and a cross-linker. In some non-limiting embodiments, the cross-linker is referred to as a “cross-linking compound” or as another term that would be known to one of skill in the art. Depending on the particular copolymer in the formulation, it may be desirable to include a cross-linker in the formulation, for example, to provide improved mechanical properties such as strength or elasticity to the copolymer in the formulation. In some non-limiting embodiments of the formulation disclosed herein, the cross-linker is selected from the group consisting of diamine compounds, melamine compounds, hemiaminal compounds, guanamine compounds, benzo-guanamine compounds, glycoluril compounds, urea compounds, epoxy compounds, oxetane compounds, isocyanate compounds, azide compounds, hydroxide-containing compounds, thiol-containing compounds, acrylate compounds, aryl acrylate compounds, heteroaryl acrylate compounds, methacrylate compounds, alkenyl compounds, benzocyclobutenyl compounds, 1,3-diene compounds, furan compounds, and alkynyl compounds.

Suitable cross-linkers will depend on the copolymer in the formulation and may be chosen, for example, from: melamine compounds such as hexamethylol melamine, hexamethoxymethyl melamine, hexamethylol melamine compounds having 1 to 6 methylol groups, methoxymethylated, hexamethoxyethyl melamine, hexacyloxymethyl melamine, and hexamethylol melamine compounds having 1 to 6 methylol groups acyloxymethylated;

hemiaminal compounds such as 1,3,4,6-Tetrakis(methoxymethyl)glycoluril and hexa-(methoxymethyl)melamine, 1,3-bis(methoxymethyl)-2-imidazolidinone ; guanamine compounds such as tetramethylol guanamine, tetramethoxymethyl guanamine, tetramethylol guanamine compounds having 1 to 4 methylol groups methoxymethylated, tetramethoxyethyl guanamine, tetraacyloxyguanamine, tetramethylol guanamine compounds having 1 to 4 methylol groups acyloxymethylated, and benzoquanamine compounds; glycoluril compounds having substituted thereon at least one group chosen from methylol, alkoxymethyl and acyloxymethyl groups such as tetramethylol glycoluril, tetramethoxyglycoluril, tetramethoxymethyl glycoluril, tetramethylol glycoluril compounds having 1 to 4 methylol groups methoxymethylated, and tetramethylol glycoluril compounds having 1 to 4 methylol groups acyloxymethylated; urca compounds having substituted thereon at least one group chosen from methylol, alkoxymethyl and acyloxymethyl groups such as tetramethylol urca, tetramethoxymethyl urca, tetramethylol urea compounds having 1 to 4 methylol groups methoxymethylated, and tetramethoxyethyl urea; epoxy compounds such as such as tris(2,3-epoxypropyl)isocyanurate, trimethylolmethane triglycidyl ether, trimethylolpropane triglycidyl ether, bisphenol A diglycidyl ether, bisphenol S diglycidyl ether, 3,4-epoxycyclohexylmethyl 3 4-epoxycyclohexanecarboxylate, tris(4-hydroxyphenyl)methane tryglycidyl ether, trimethylolpropane triglycidyl ether, 4,4′-methylenebis(N,N-diglycidylaniline), 2,4,6,8-Tetramethyl-2,4,6,8-tetrakis(propyl glycidyl ether)cyclotetrasiloxane, KR-470 (Shin-Etsu), X-12-981S (Shin-Etsu), RA2101S (Miwon Commercial Co., Ltd), GHP01P (Miwon Commercial Co., Ltd), GHP20P (Miwon Commercial Co., Ltd), GHP21P (Miwon Commercial Co., Ltd), GHP03P (Miwon Commercial Co., Ltd), HP-4032 (DIC Corp.), HP-4700 (DIC Corp.), HP-4770 (DIC Corp), jEF YX8800 (DIC Corp), 4,4′-methylenebis(N,N-diglycidalaniline), tris(4 hydroxy-phenyl)methane triglycidal ether, 3,4-epoxycyclohexylmethyl-3,4-epoxycyclo-hexanecarboxylate, TEPIC-UC (Nissan Chemical), TEPIC-L (Nissan Chemical), TG-G (Shikoku), tetrakis[(epoxycyclohexyl) ethyl]tetramethylcyclotetrasiloxane and triethylolethane triglycidyl ether; isocyanate compounds such as the blocked isocyanate Desmodur BL 3475 SA/SN; azide compounds; hydroxy-containing compounds; diamine-containing compounds such as 4,4′-diaminodiphenyl sulfone; or compounds having a double bond such as an alkenyl ether group.

Non-limiting embodiments of these cross-linking compounds are chosen to react with nucleophilic side chains of the copolymer under appropriate conditions. Such cross-linking compounds will have an electrophilically reactive cross-linking group. Examples of such cross-linkers are:

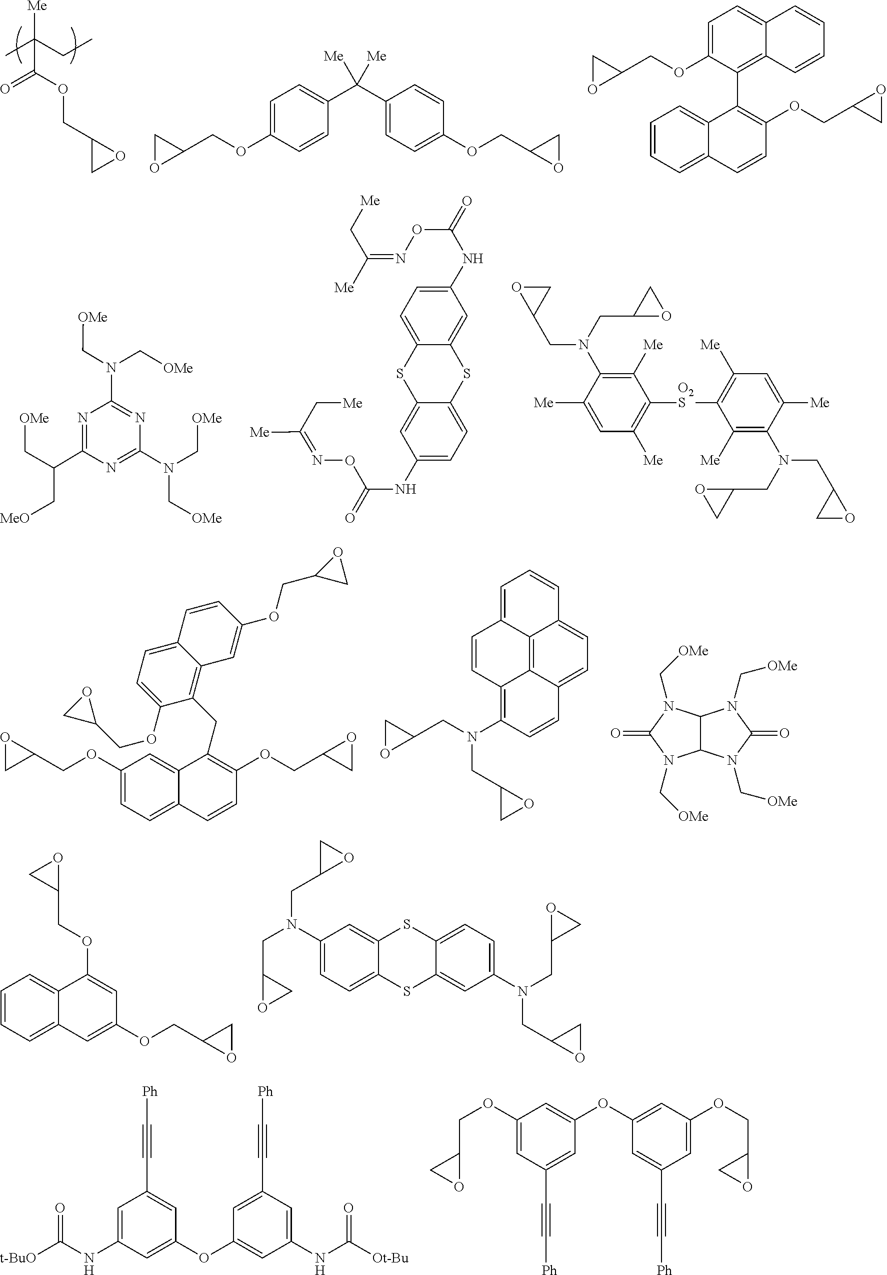

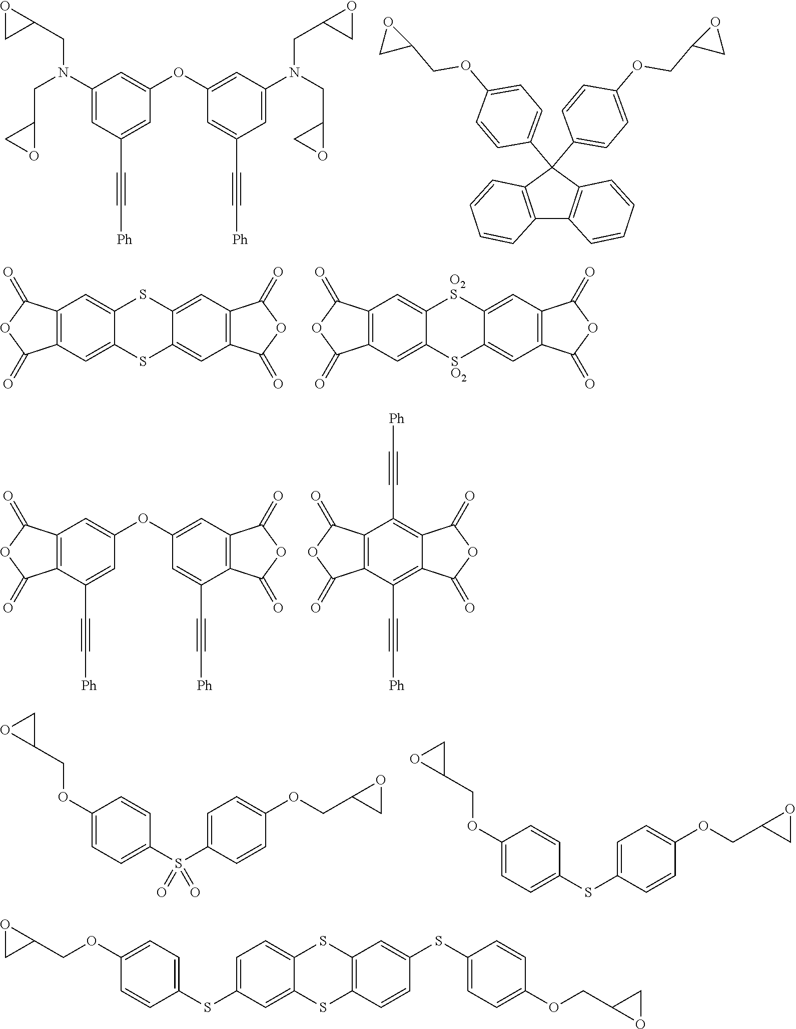

Other non-limiting embodiments of these cross-linking compounds contain metallic oxides, or metal-oxide oligomeric compositions. Such cross-linking compounds will have reactive cross-linking groups as functional side chains. Their composition can be generally expressed as:

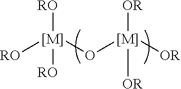

where R is an alkyl or aryl functional group, and M is one of the following metals: Ti, Zn, Zr, V, Hf, Sn, La, Rh, Ce, U, Cu, La, Cr. Examples of such cross-linkers are:

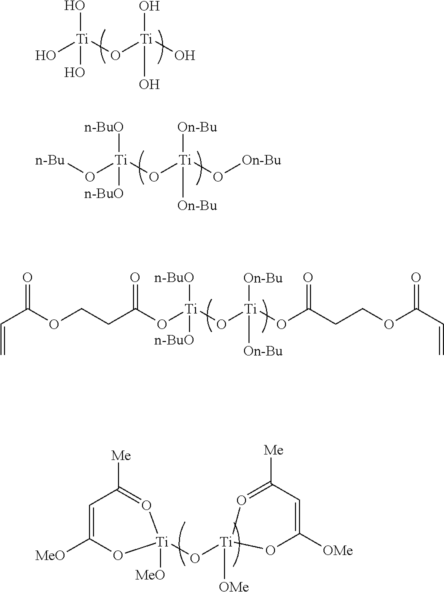

Other non-limiting embodiments of these cross-linking compounds are selected to react with radically-reactive side chains of the copolymer under appropriate conditions. Such cross-linking compounds will have a radically-reactive cross-linking group, including dipentaerythritol hexaacrylate, glycerol 1,3-diglycerolate diacrylate, MIRAMER HR-6042 (available from Miwon Specialty Chemical Company), RP-1040 (available from Nippon Kayaku); DPCA-60 (Nippon Kayaku), HX-220 (Nippon Kayaku), R551 (Nippon Kayaku), Trimethylolpropane triacrylate (Nippon Kayaku), PET-30 (Nippon Kayaku), KAYARAD T-1420(T) (Nippon Kayaku), DPHA-40H (Nippon Kayaku), Viscoat#802 (Nippon Kayaku), Aronix M-520 (Toagosei Co., Ltd.), 2,4,6,8-Tetramethyl-2,4,6,8-tetravinylcyclotetrasiloxane (Tokyo Chemical Industry Co., Ltd.), Bis(4-methacryloylthiophenyl) Sulfide (Tokyo Chemical Industry Co., Ltd.), X-12-2475 (Shin-Etsu); SR295, SR35 H, SR349, SR355, SR399, SR601, SR602, SR833 S (available from Sartomer), (((9H-fluorene-9,9-diyl)bis(4,1-phenylene))bis(sulfanediyl))bis(ethane-2,1-diyl) diacrylate (XL1).

Other non-limiting embodiments of these cross-linking compounds are selected to react

with alkene or alkyne side chains of the copolymer under appropriate conditions. Such cross-linking compounds will have an alkene-reactive cross-linking group. Examples of such cross-linkers are:

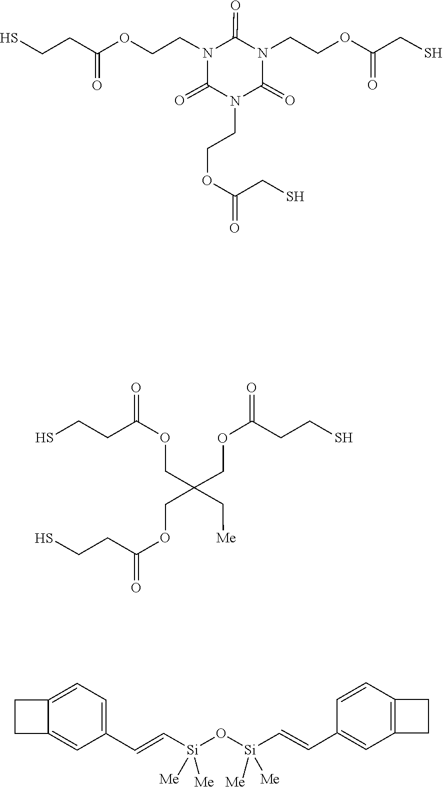 [SMILES: O=C(CS)OCCn1c(=O)n(CCOC(=O)CS)c(=O)n(CCOC(=O)CCS)c1=O ; CCC(COC(=O)CCS)(COC(=O)CCS)COC(=O)CCS ; C[Si](C)(/C=C/c1ccc2c(c1)CC2)O[Si](C)(C)/C=C/c1ccc2c(c1)CC2]

Other non-limiting embodiments of these cross-linking compounds are selected to react with electrophilic side chains of the copolymer under appropriate conditions. Such cross-linking compounds will have a nucleophilic cross-linking group. Examples of such cross-linkers are:

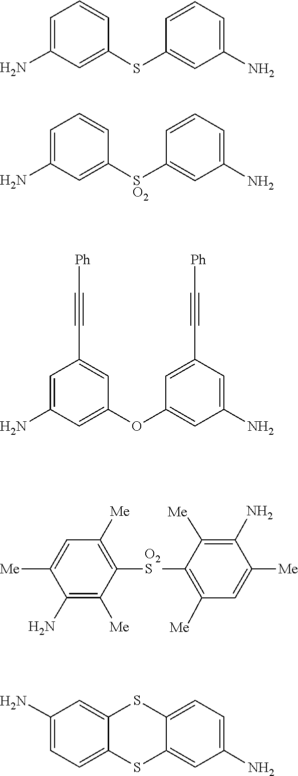

These compounds may be used as an additive or introduced into a copolymer side chain as a pendant group. A cross-linker, if used, is typically present in the formulation in an amount from 0.5 to 50 wt % or from 0.5 to 25 wt % based on total solids of the formulation. In some non-limiting embodiments, the cross-linker is present in the formulation in an amount from 5 to 35 wt % based on total solids.

Depending on the particular components in the formulation, it may be desirable to include an antioxidant in the formulation, for example, to enhance the durability of the formulation or film through the reduction of potential oxidative reactions and their potential to initiate undesired radical reactions. Suitable antioxidants will depend on the components in the formulation and may be chosen, for example, from 3,4-di-tert-butylhydroxytoluene, 4-methoxyphenol, pentaerythritol tetrakis(3-(3,5-di-tert-butyl-4-hydroxyphenyl)propionate) [available from BASF under the tradename IRGANOX® 1010], dilauryl thiodipropionate [available from BASF under the tradename IRGANOX® PS800], tris(2,4-di-tert-butylphenyl) phosphite [available from BASF under the tradename IRGAPHOS® 168], poly-(N-Beta-hydroxyethyl-2,2,6,6-tetramethyl-4-hydroxy-piperidyl succinate) thiodipropionate [available from BASF under the tradename Tinuvin® 622], bis(2.4-di-t-butylphenyl) pentaerythritol diphosphate thiodipropionate [available from Brenntag under the tradename ULTRANOX® 626], 40% tricthylene glycol bis(3-tert-butyl-4-hydroxy-5-methylphenyl), polyvinyl alcohol and deionized water [available from BASF under the tradename IRGANOX®) 245 DW], Weston®) 705T, 4-hydroxy-2,2,6,6-tetramethylpiperidin-1-oxyl [also known as 4-hydroxy-TEMPO], tris (tri-methylsilyl)silane, trimethylcyclohexyl salicylate, trioctylphosphine, trimethylolpropane tris(3-mercaptopropionate), trimethylolpropane tris(3-mercaptopropionate), triphenylphosphine, and 3,9-bis(octadecyloxy) 2,4,8,10-tetraoxa-3,9-diphosphaspiro[5,5]undecane and pentaerythritol tetrakis(3-mercaptopropionate).

An antioxidant, if used, is typically present in the formulation in an amount from

0.1 to 25 wt % or from 0.25 to 15 wt % based on total solids of the formulation. In some non-limiting embodiments, the antioxidant is present in the formulation in an amount from 0.5 to 2.5 wt %.

The present formulations may optionally contain a surface leveling agent, or a “leveling agent,” for example, to reduce the surface tension of the formulation. Suitable surface leveling agents will depend on the components in the formulation and may be chosen, for example, from fluorinated and non-fluorinated surface leveling agents, and may be ionic or non-ionic. The leveling agent may contain a majority of silicone units derived from the polymerization of the following monomers Si(R¹)(R²)(OR³)₂ wherein R¹, R² or R³ is each independently chosen from a C₁-C₂₀ alkyl or a C₅-C₂₀ aliphatic group or a C₁-C₂₀ aryl group. In one non-limiting embodiment, the leveling agent is non-ionic and may contain at least two functional groups that can chemically react with functional groups contained in the silicone and non-silicone resins under a cationic photo curing process or thermal curing condition. A leveling agent containing non-reactive groups is present in some non-limiting embodiments. In addition to silicone-derived units the leveling agent may comprise units derived from the polymerization of an C₃-C₂₀ aliphatic molecule comprising an oxirane ring. In addition, the leveling agent may comprise units derived from an C₁-C₅₀ aliphatic molecule comprising a hydroxyl group. In some non-limiting embodiments, the leveling agent is free of halogen substituents. In some non-limiting embodiments, the molecular structure of the leveling agent is predominantly linear, branched, or hyperbranched, or it may be a graft structure.

A mixture of leveling agents may be used wherein one or more of the leveling agents comprise silicone-units and one or more leveling agents are free of silicone-units. In some non-limiting embodiments, the leveling agent free of silicone-units may comprise polyether groups or perfluorinated polyether groups.

In one non-limiting embodiment, the leveling agent is as described, for example, in Thin Solid Films 2015, vol. 597, p.212-219. It is commercially available from BYK Additives and Instruments, and has structure:

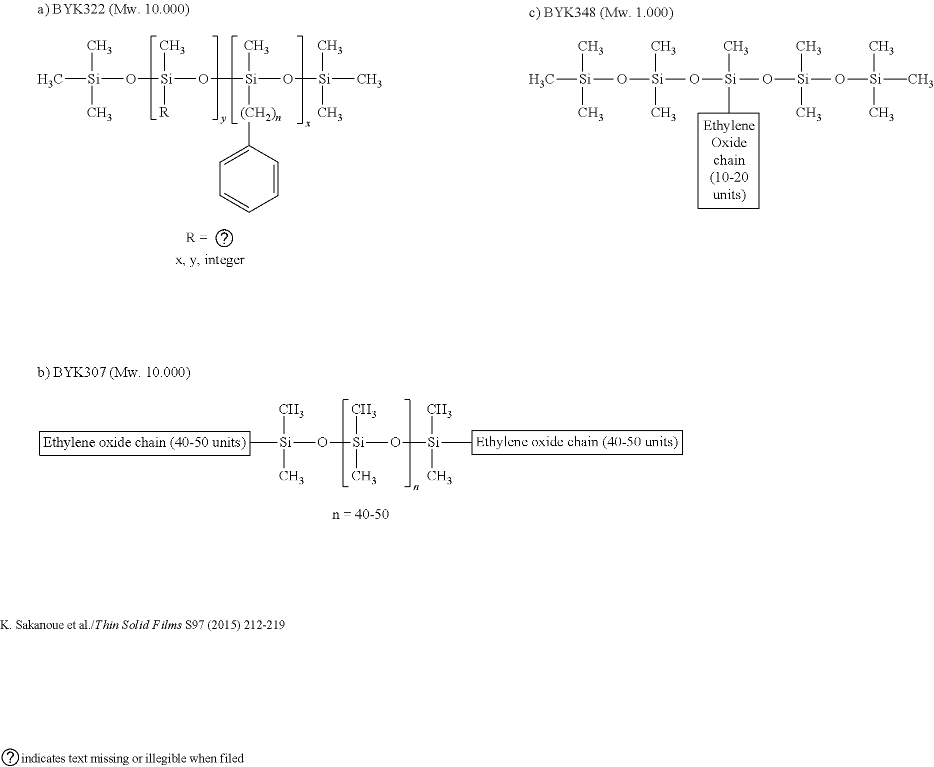

In some non-limiting embodiments; the leveling agent is selected from the group consisting of AD1700, MD700; Megaface F-114, F-251, F-253, F-281, F-410, F-430, F-477, F-510, F-551, F-552, F-553, F-554, F-555, F-556, F-557, F-558, F-559, F-560, F-561, F-562, F-563, F-565, F-568, F-569, F-570, F-574, F-575, F-576, R-40, R-40-LM, R-41, R-94, RS-56, RS-72-K, RS-75, RS-76-E, RS-76-NS, RS-78, RS-90, DS-21 (DIC Sun Chemical); KY-164, KY-108, KY-1200, KY-1203 (Shin Etsu); DOWSIL™ 14, DOWSIL™ 11, DOWSIL™ 54, DOWSIL™ 57, DOWSIL™ FZ-2110, DOWSIL™ FZ-2122, DOWSIL™ FZ-2123 [available from Dow, Inc.] .; Xiameter OFX-0077; ECOSURF EH-3, EH-6, EH-9, EH-14, SA-4, SA-7, SA-9, SA-15; Tergitol 15-S-3, 15-S-5, 15-S-7, 15-S-9, 15-S-12, 15-S-15, 15-S-20, 15-S-30, 15-S-40, L61, L-62, L-64, L-81, L-101, XD, XDLW, XH, XJ, TMN-3, TMN-6, TMN-10, TMN-100X, NP-4, NP-6, NP-7, NP-8, NP-9, NP-9.5, NP-10, NP-11, NP-12, NP-13, NP-15, NP-30, NP-40, NP-50, NP-70; Triton CF-10, CF-21, CF-32, CF76, CF87, DF-12, DF-16, DF-20, GR-7M, BG-10, CG-50, CG-110, CG-425, CG-600, CG-650, CA, N-57, X-207, HW 1000, RW-20, RW-50, RW-150, X-15, X-35, X-45, X-114, X-100. X-102, X-165, X-305, X-405, X-705; PT250, PT700, PT3000, P425, P1000TB, P1200, P2000, P4000, 15-200 (Dow Chemical); DC ADDITIVE 3, 7, 11, 14, 28, 29, 54, 56, 57, 62, 65, 67, 71, 74, 76, 163 (DowCorning); TEGO Flow 425, Flow 370, Glide 100, Glide 410, Glide 415, Glide 435, Glide 432, Glide 440, Glide 450, Flow 425, Wet 270, Wet 500, Rad 2010, Rad 2200 N, Rad 2011, Rad 2250, Rad 2500, Rad 2700, Dispers 670, Dispers 653, Dispers 656, Airex 962, Airex 990, Airex 936, Airex 910 (Evonik); BYK-300, BYK-301/302, BYK-306, BYK-307. BYK-310. BYK-315, BYK-313, BYK-320, BYK-322, BYK-323, BYK-325, BYK-330, BYK-331, BYK-333, BYK-337, BYK-341, BYK-342, BYK-344, BYK-345/346, BYK-347, BYK-348, BYK-349, BYK-370, BYK-375, BYK-377, BYK-378, BYK-UV3500, BYK-UV3510, BYK-UV3570, BYK-3550, BYK-SILCLEAN 3700, Modaflow 9200, Modaflow 2100, Modaflow Lambda, Modaflow Epsilon, Modaflow Resin, Efka FL, Additiol XL 480, Additol XW 6580, and BYK-SILCLEAN 3720.

In some non-limiting embodiments, the leveling agent is chosen from the group consisting of perfluoro-C₄ surface leveling agents such as FC-4430 and FC-4432 (available from 3M Corporation) and fluorodiols such as POLYFOX PF-535, PF-636, PF-6320, PF-656, and PF-6520 (available from Omnova).

The leveling agent can be present in an amount of from 0 to 1 wt %, or from 0.001 to 0.9 wt %, or from 0.01 to 0.5 wt %, or from 0.01 to 0.25 wt %, or from 0.01 to 0.2 wt %, or from 0.01 to 0.1 wt %.

In some non-limiting embodiments, the formulation disclosed herein additionally comprises one or more components selected from the group consisting of thermal acid generators, photoacid generators, oxygen scavengers, UV blockers, and hindered-amine light stabilizers.

Depending on the particular copolymer in the formulation, it may be desirable to include a thermal acid generator in the formulation, for example, to allow the curing step to be performed at a lower temperature. Suitable thermal acid generators will depend on the copolymer in the formulation and may be chosen, for example, from

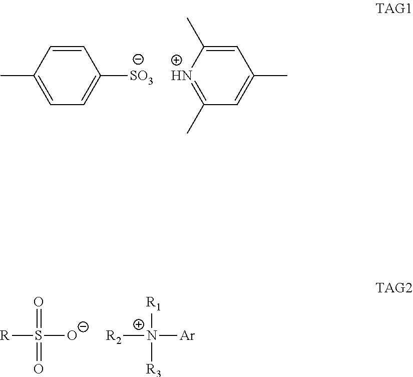

where TAG2 is commercially available, for example, from King Industries under the trade name “K-Pure TAG.” In some non-limiting embodiments, the thermal acid generator may be selected from the group consisting of amine blocked acids, covalently blocked acids, or quaternary blocked acids. In some non-limiting embodiments, the thermal acid generator may be selected from the group consisting of trimethylpyridinium p-toluenesulfonate, triethylammonium p-toluenesulfonate, CXC-1821 (King Industries Specialty Chemicals), CXC-2689 (King Industries Specialty Chemicals), CXC-2678 (King Industries Specialty Chemicals), CXC-1614 (King Industries Specialty Chemicals), CXC-1615 (King Industries Specialty Chemicals), CXC-1767 (King Industries Specialty Chemicals), CXC-2172 (King Industries Specialty Chemicals), CXC-2179 (King Industries Specialty Chemicals), ammonium triflate, and N-benzyl-N.N-dimethylbenzeneaminium triflate, and the like and combinations thereof.

A thermal acid generator, if used, is typically present in the formulation in an amount from 0.001 to 25 wt % or from 0.25 to 15 wt % based on total solids of the formulation. In some non-limiting embodiments, the thermal acid generator is present in the formulation in an amount from 0.25 to 2.5 wt %.

The formulations of the present disclosure may further comprise a photoacid generator (PAG). Suitable PAGs can generate an acid that, during post-exposure bake, causes cleavage of acid-labile groups present on a polymer of the photoresist composition. Suitable PAG compounds are known in the art of chemically amplified photoresists and may be ionic or nonionic. Suitable PAG compounds include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325.

In some non-limiting embodiments, suitable PAGs have formula G⁺A⁻, wherein G⁺ is an organic cation and A⁻ is an organic anion. Organic cations include, for example, iodonium cations substituted with two alkyl groups, aryl groups, or a combination of alkyl and aryl groups; and sulfonium cations substituted with three alkyl groups, aryl groups, or a combination of alkyl and aryl groups. In some embodiments, G⁺ is an iodonium cation substituted with two alkyl groups, aryl groups, or a combination of alkyl and aryl groups; or a sulfonium cation substituted with three alkyl groups, aryl groups, or a combination of alkyl and aryl groups. In some embodiments, G⁺ may be one or more of a substituted sulfonium cation having the Formula (V) or an iodonium cation having the Formula (VI):

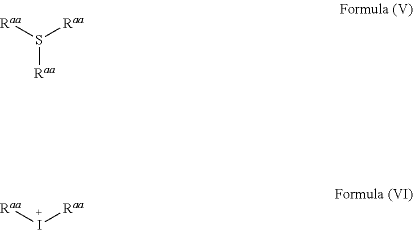

wherein, each R^{aa} is independently a C₁₋₂₀ alkyl group, a C₁₋₂₀ fluoroalkyl group, a C₃₋₂₀ cycloalkyl group, a C₃₋₂₀ fluorocycloalkyl group, a C₂₋₂₀ alkenyl group, a C₂₋₂₀ fluoroalkenyl group, a C₆₋₃₀ aryl group, a C₆₋₃₀ fluoroaryl group, C₆₋₃₀ iodoaryl group, a C₄₋₃₀ heteroaryl group, a C₇₋₂₀ arylalkyl group, a C₇₋₂₀ fluoroarylalkyl group, a C₅₋₃₀ heteroarylalkyl group, or a C₅₋₃₀ fluoroheteroarylalkyl group, each of which is substituted or unsubstituted, wherein each R^{aa} is either separate or connected to another group R^{aa} via a single bond or a divalent linking group to form a ring. Each R^{aa} optionally may include as part of its structure one or more groups selected from —O—, —C(O)—, —C(O)—O—, -C₁₋₁₂ hydrocarbylene-, —O-(C₁₋₁₂ hydrocarbylene)-, —C(O)—O-(C₁₋₁₂ hydrocarbylene)-, and —C(O)—O-(C₁₋₁₂ hydrocarbylene)-O—. Each R^{aa} independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups. Suitable divalent linking groups for connection of R^{aa} groups include, for example, —O—, —S—, —Te—, —Se—, —C(O)—, —C(S)—, —C(Te)—, or —C(Se)—, substituted or unsubstituted C₁₋₅ alkylene, and combinations thereof.

Exemplary sulfonium cations of Formula (V) include the following:

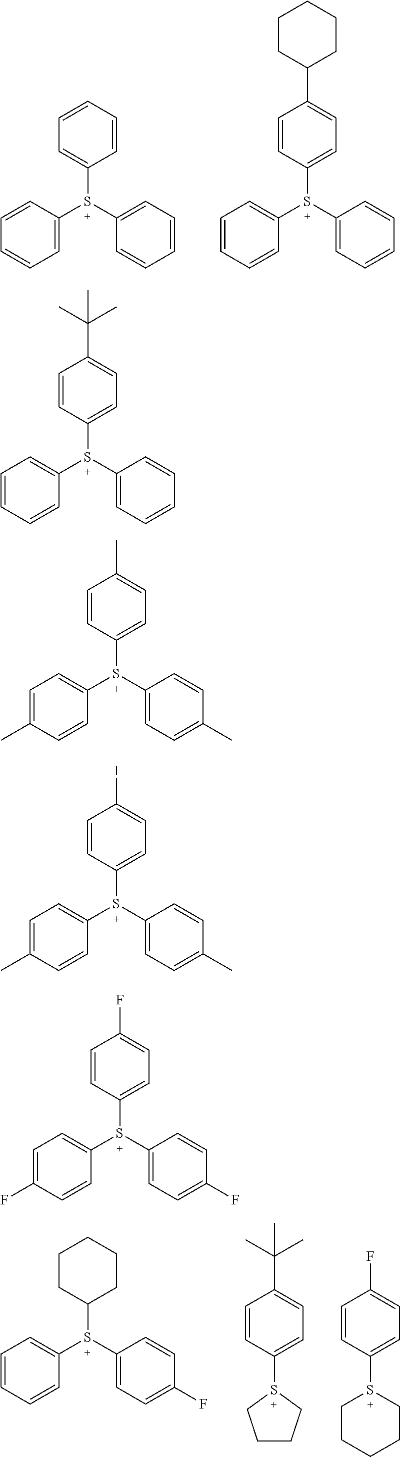

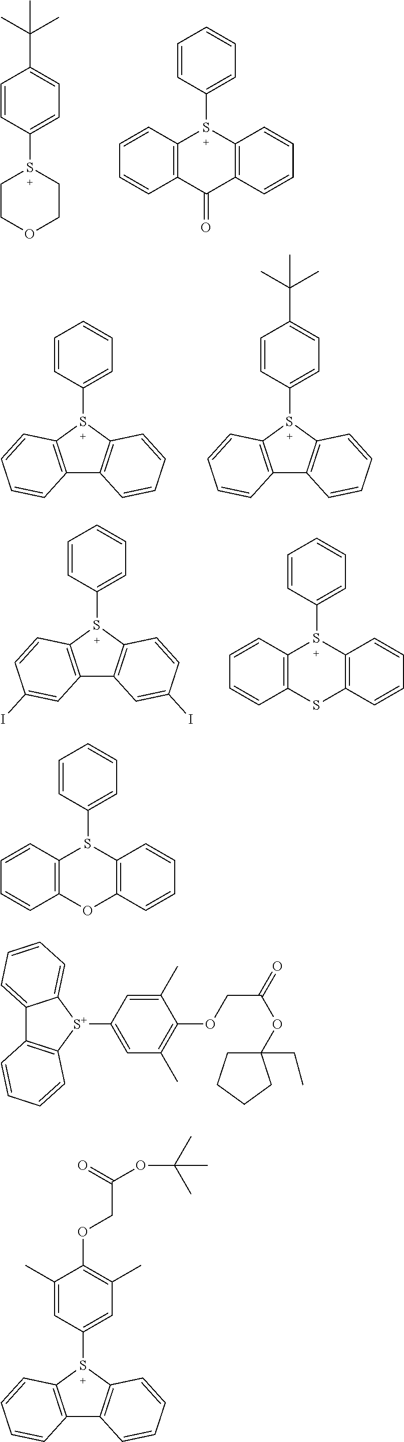

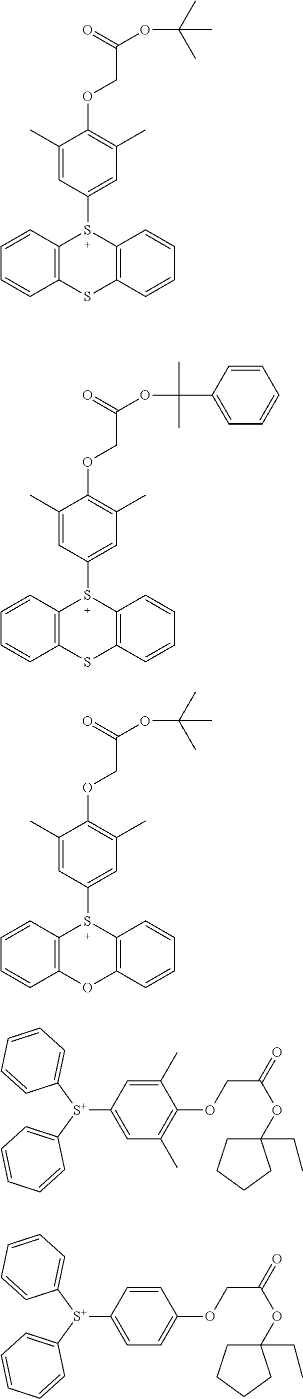

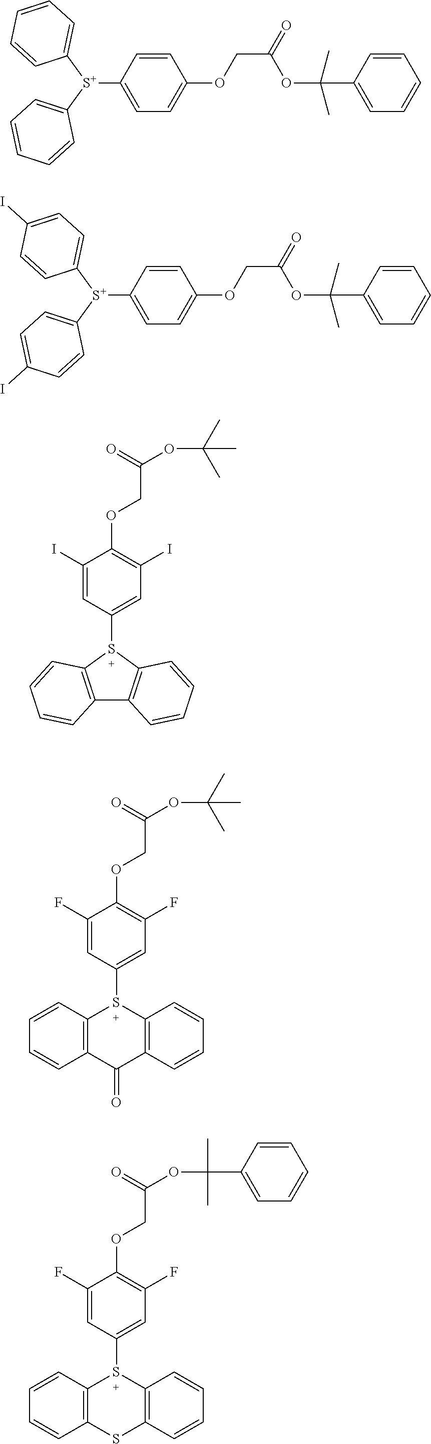

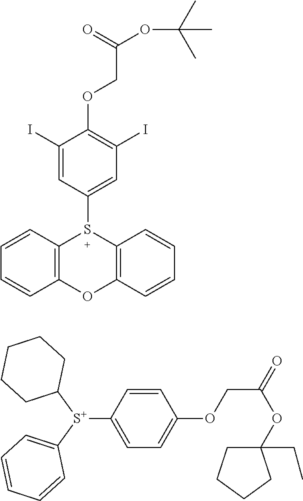

Exemplary iodonium cations of Formula (VI) include the following:

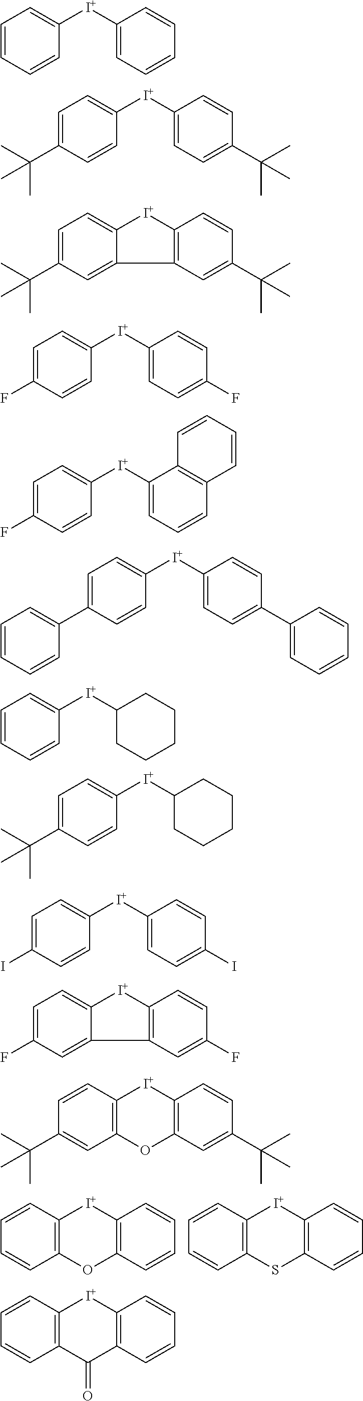

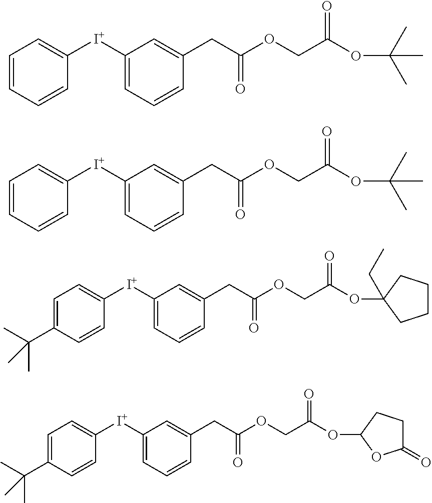

PAGs that are onium salts typically comprise an anion having a sulfonate group or a non-sulfonate type group, such as a sulfonamidate group, a sulfonimidate group, a methide group, or a borate group. Exemplary suitable anions having a sulfonate group include the following:

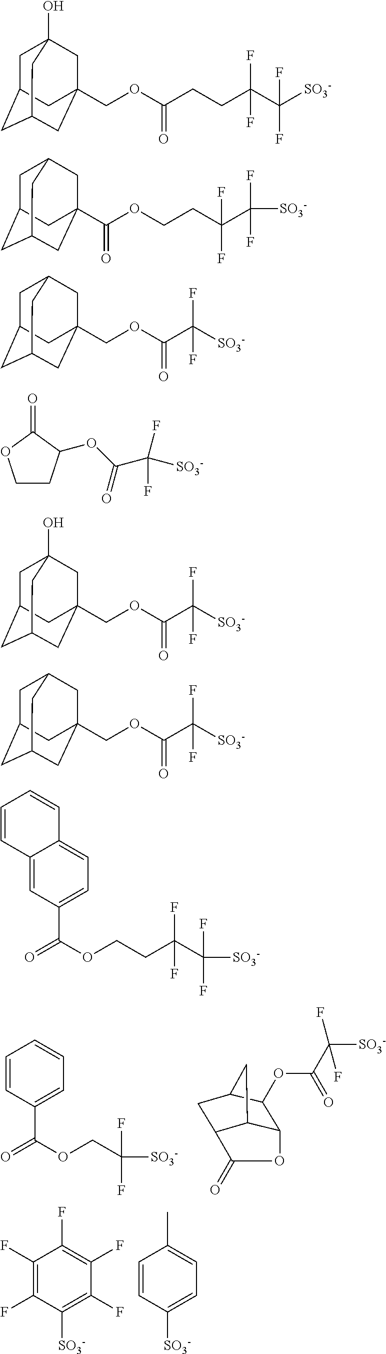

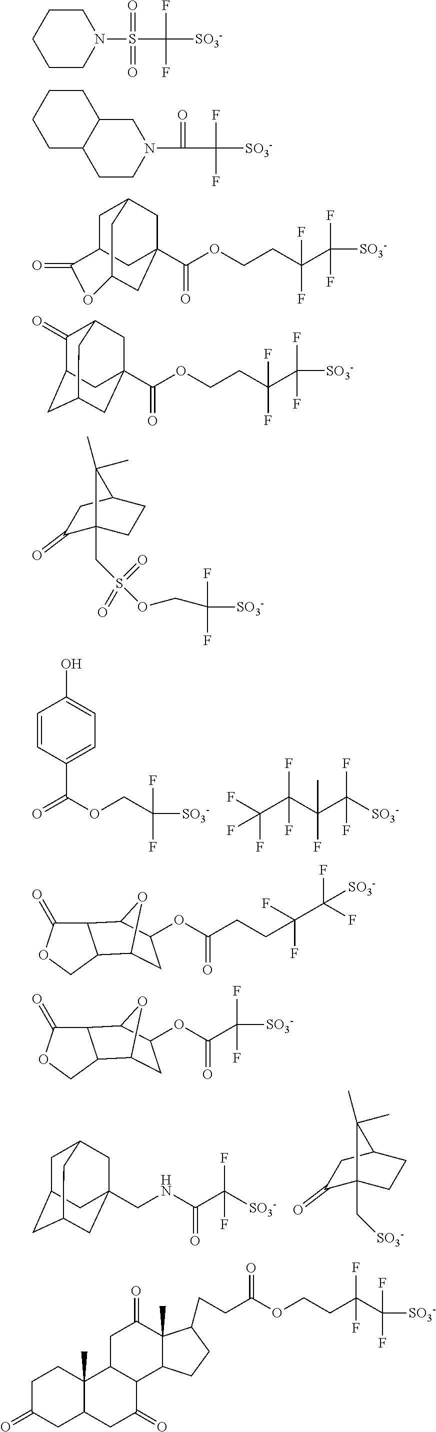

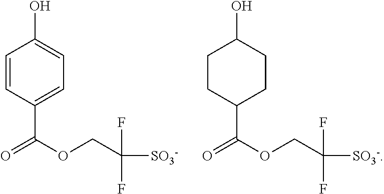

Exemplary suitable non-sulfonated anions include the following:

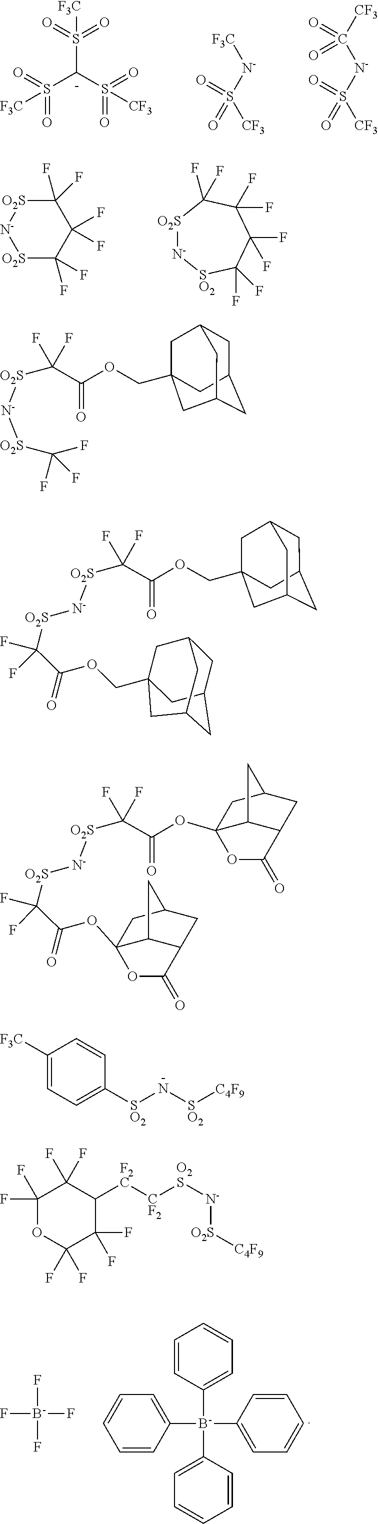

A PAG, if used, is typically present in the formulation in an amount from 0.001 to 25 wt % or from 0.25 to 15 wt % based on total solids of the formulation. In some non-limiting embodiments, the thermal acid generator is present in the formulation in an amount from 0.25 to 2.5 wt %.

The formulations of the present disclosure may optionally contain one or more oxygen scavengers in sufficient amounts to maintain oxygen content of the formulation at 1000 ppb or less. In some non-limiting embodiments, the oxygen content of the formulation is 1000 ppb to 0 ppb, in some non-limiting embodiments 500 ppb to 0 ppb, in some non-limiting embodiments 200 ppb to 0 ppb.

Oxygen scavengers include, but are not limited to, hydroxyl amine compounds having a formula:

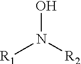

wherein R₁ and R₂ may be the same or different and are hydrogen, substituted or unsubstituted (C₁-C₁₀)alkyl, substituted or unsubstituted (C₅-C₁₀)cycloalkyl or substituted or unsubstituted (C₆-C₁₀)aryl, with the proviso that R₁ and R₂ are not hydrogen at the same time. Non-limiting examples of such alkyl groups include methyl, ethyl, propyl, isopropyl, hydroxymethyl, 2-hydroxyethyl, pentyl, t-butyl and octyl. Non-limiting examples of cycloalkyl groups include cyclopentyl, cyclophexyl, 4-methy-lcyclohexyl and cyclooctyl. Non-limiting examples of aryl groups include phenyl, naphthayl, xylyl, 4-hydroxyphenyl and tolyl. Non-limiting examples of specific oxygen scavengers include N-methylhydroxylamine, N-isopropylhydroxylamine, N-cyclohexylhydroxylamine and N,N-diethylhydroxylamine.

Oxygen scavengers may also include, but are not limited to, organic acids such as aliphatic, aromatic, and amino carboxylic acids and salts thereof. Non-limiting examples of carboxylic acids include acetic acid, propionic acid, butyric acid, pentanoic acid, 3-methylbutanoic acid, gallic acid, citric acid, lactic acid, ascorbic acid, tartronic acid, and 2,4-dihydroxybenzoic acid. Non-limiting examples of amino carboxylic acids include glycine, dihydroxy ethyl glycine, alanine, valine, leucine, asparagines, glutamine, and lysine.

Additional oxygen scavengers may also include hydrazine, carbohydrazide, erythorbate, methylethylketoxime, hydroquinone, hydroquinone sulfonate, sodium salt, ethoxyquin, methyltetrazone, tetramethylphenylenediamine, DEAE 2-ketogluconate Tinuvin® 123 and 292 (BASF), and hydroxyacetone. In some non-limiting embodiments, oxygen scavengers are selected from the group consisting of hydroquinone and hydroquinone sulfonate, sodium salt.

In general, when present, oxygen scavengers are included in the formulations in amounts of 0.001 wt % to 1 wt %. In some non-limiting embodiments the oxygen scavengers are included in the solutions in amounts of 0.005 wt % to 0.1 wt % to provide the desired oxygen content of the formulation.

The formulations of the present disclosure may optionally contain one or more UV blockers. Non-limiting examples of UV blockers include anthraquinone, substituted anthraquinones such as alkyl and halogen substituted anthraquinones such as 2-tertiary butyl anthraquinone, 1-chloroanthraquinone, p-chloroanthraquinone, 2-methylanthraquinone, 2-ethylanthraquinone, octamethyl anthraquinone and 2-amylanthraquinone, optionally substituted polynuclear quinones such as 1,4-naphthaquinone, 9,10-phenanthraquinone, 1,2-benzanthraquinone, 2,3-benzanthraquinone, 2-methyl-1,4-napththoquinone, 2,3-dichloronaphthaquinone, 1.4-dimethylanthraquinone, 2,3-dimethylanthraquinone, 2-phenylanthraquinone, 2,3-diphenylanthraquinone, 3-chloro-2-methylanthraquinone, retenequinone, 7,8,9,10-tetrahydronaphthaanthraquinone, 1,2,3,4-tetrahydrobenzanthracene-7,2-dione, acetophenones such as acetaphenone, 2,2-dimethoxy-2-phenyl acetophenone, 2,2-diethoxy-2-phenyl acetophenone, 1,1-dichloro acetophenone, 1-hydroxy cyclohexyl phenylketone and 2-methyl-1-(4-methylthio)phenyl-2-morpholin-propan-1-one; thioxanthones such as 2-methylthioxanthone, 2-decylthioxanthone, 2-dodecylthioxanthone, 2-isopropylthioxanthone, 2.4-dimethylthioxanthone, 2,4-diethylthioxanthone, 2-chlorothioxanthone, and 2,4-diisopropylthioxanthone; ketals such as acetophenone dimethylketal and dibenzylketal; benzoins and benzoin alkyl ethers such as benzoin, benzylbenzoin methyl ether, benzoin isopropyl ether, and benzoin isobutyl ether; azo compounds such as azobisisovaleronitrile; Michler's Ketone, Ethyl Michler's Ketone, and xanthone, and mixtures thereof.

Organic pigments may also be used as UV blockers. Such organic pigments include, but are not limited to: carbon black, indigo, phthalocyanine, para red, flavanoids such as red, yellow, blue, orange and ivory colors. Specific organic pigments having Color Index (C.I.) numbers include C.I. Pigment Yellow 12, C.I. Pigment Yellow 13, C.I. Pigment yellow 14, C.I. Pigment Yellow 17, C.I. Pigment Yellow 20, C.I. Pigment Yellow 24, C.I. Pigment Yellow 31, C.I. Pigment Yellow 55, C.I. Pigment Yellow 83, C.I. Pigment Yellow 93, C.I. Pigment yellow 109, C.I. Pigment Yellow 110, C.I. Pigment Yellow 139, C.I. Pigment Yellow 153. C.I. Pigment Yellow 154, C.I. Pigment Yellow 166, C.I. Pigment Yellow 168, C.I. Pigment Orange 36, C.I. Pigment Orange 43, C.I. Pigment Orange 51, C.I. Pigment Red 9. C.I. Pigment Red 97, C.I. Pigment Red 122, C.I. Pigment Red 123, C.I. Pigment Red 149, C.I. Pigment Red 176, C.I. Pigment Red 177, C.I. Pigment Red 180, C.I. Pigment Red 215,

C.I. Pigment Violet 19, C.I. Pigment Violet 23, C.I. Pigment Violet 29, C.I. Pigment Blue 15, C.I. Pigment Blue 15:3, C.I. Pigment Blue 15:6, C.I. Pigment Green 7, C.I. Pigment Green 36, C.I. Pigment Brown 23, C.I. Pigment Brown 25, C.I. Pigment Black 1 and C.I. Pigment Black 7. Other suitable pigments include, but are not limited to: titanium dioxide, Prussian blue, cadmium sulfide, iron oxides, vermillion, ultramarine and the chrome pigments, including chromates, molybdates and mixed chromates and sulfates of lead, zinc, barium, calcium and mixtures and modifications thereof which are commercially available as greenish-yellow to red pigments under the names primrose, lemon, middle orange, scarlet, and red chromes.

Organic dyes also may be used as UV blockers. Such dyes include, but are not limited to: azo dyes, anthraquinone, benzodifuranone, indigold, polymethine, and related dyes, styryl, di- and triaryl carbonium dyes and related dyes, quinophthalones, sulfurbased dyes, nitro and nitroso dyes, stilbenes, formazans, dioxazines, perylenes, quinacridones, pyrrolo-pyrroles, isoindolines, and isoindolinones. Other suitable dyes include, but are not limited to: azo dyes, metal complex dyes, naphthol dyes, indigo dyes, carbonium dyes, quinoncimine dyes, xanthene dyes, cyanine dyes, quinoline dyes, nitro dyes, nitroso dyes, benzoquinone dyes, naphthoquinone dyes, penoline dyes, pthalicyanine dyes, leuco dyes, and fluorescent dyes. Examples of fluorescent dyes are xanthenes such as rhodamine and fluorescein, bimanes, coumarins such as umbelliferone, aromatic amines such as dansyl, squarate dyes, benzofurans, cyanines, merocyanines, rare earth chelates, and carbozoles.

Commercially-available UV blockers include, but are not limited to: CYASORB™ UV 24 available from Spectrum laboratories Inc .; LOWILITE™ 27, LOWILITE™ 22, LOWILITE™ 55, LOWILITE™ 26 available from Addivant LLC, BLS 531, BLS 5411, BLS 1326 available from Mayzo, Inc.; Speedcure™ ITX, EHA and 3040, Irgacure™ 184, 369, 907 and 1850, Daracure™ 1173 Uvinul® 3027, 3028, 3029, 3030, 3033, and 3035, as well as Tinuvin® 460, 479, and 1600 available from BASF. Speedcure™, Irgacure™ and Daracure™ are registered trademarks of Lambson Plc and Ciba GmbH, respectively.

In general, when present, UV blockers are included in the formulations in amounts of 0.001 wt % to 1 wt %. In some non-limiting embodiments the UV blockers are included in the solutions in amounts of 0.005 wt % to 0.5 wt % to provide the desired level of UV protection.

The formulations of the present disclosure may optionally contain one or more

hindered-amine light stabilizers. The hindered amine or hindered amine derivative is a generic term for a compound that has at least one organic or inorganic bulky substituent directly attached to the nitrogen atom of an amine structure. More specifically, the structure of the secondary or tertiary amine known as a hindered amine light stabilizer (HALS) is well known to includes, for example, a structure wherein one position of the nitrogen atom is substituted with an oxy radical (such as TEMPO, 4-hydroxy-TEMPO).

In general, when present, hindered-amine light stabilizers are included in the formulations in amounts of 0.001 wt % to 1 wt %. In some non-limiting embodiments the hindered-amine light stabilizers are included in the solutions in amounts of 0.005 wt % to 0.5 wt % to provide the desired level of stability.

In some non-limiting embodiments of the formulation disclosed herein, the weight percentage of the copolymer composition comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B) is between 5% and 95%, in some non-limiting embodiments between 10% and 80%, in some non-limiting embodiments between 10% and 60%, and in some non-limiting embodiments between 10% and 40%.

In some non-limiting embodiments of the formulation disclosed herein, the composition optionally comprises the copolymer composition comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B) and one or more additional polymers or copolymers. In such formulations, the mass ratio of the first copolymer and any additional second polymers or copolymers is between 99:1 and 1:99. in some non-limiting embodiments between 80:20 and 20:80, in some non-limiting embodiments between 60:40 and 40:60.

In some non-limiting embodiments of the formulation disclosed herein, the composition optionally comprises one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B) and one or more additional polymers or copolymers. In such formulations, the weight percentage of the combined polymers and copolymers is between 5% and 95%, in some non-limiting embodiments between 10% and 80%, in some non-limiting embodiments between 10% and 60%, in some non-limiting embodiments between 10% and 40%, and in some non-limiting embodiments between 10% and 25%.

In some non-limiting embodiments of the formulation disclosed herein, the weight percentage of the solvent is between 10% and 90%, in some non-limiting embodiments between 50% and 90%, in some non-limiting embodiments between 55% and 90%, in some non-limiting embodiments between 60% and 90%, and in some non-limiting embodiments between 65% and 85%.

In some non-limiting embodiments the copolymers and formulations disclosed herein can be used to produce thin films that exhibit: (1) a refractive index >1.620 at a wavelength of 550 nm; (2) a % T >80% at wavelengths ≥410 nm for a 2 μm film; and (3) photopatternability afforded by a light-induced reaction that imparts partial solubility in developing solutions used in the electronics industry such as aqueous tetramethyl ammonium hydroxide solutions or the like.

The present disclosure is further directed to a method for forming an optical thin film comprising a copolymer composition comprising: (a) one or more bifunctional high refractive index first monomers comprising a high refractive index aromatic core and further comprising one or more UV- or thermally-reactive groups (A) and (b) one or more second monomers comprising a high refractive index core and further comprising one or more groups capable of reacting to increase the solubility of the copolymer in aqueous media (B); wherein the method comprises the following steps in order: spin coating a formulation comprising (a) a copolymer comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B); (b) optionally one or more additional polymers or copolymers; (c) optionally one or more photoinitiators and/or thermal initiators; (d) optionally one or more cross-linking agents; (e) optionally one or more antioxidants; (f) optionally one or more surface leveling agents; and (g) one or more solvents onto a substrate; soft-baking the coated substrate; optionally drying the coated substrate in vacuum; optionally photopatterning and developing the coated substrate; and treating the soft-baked coated substrate at one or more pre-selected temperatures for one or more pre-selected time intervals.

Non-limiting, specific method embodiments for the copolymer comprising (a) one or more bifunctional high refractive index first monomers comprising a high refractive index aromatic core and further comprising one or more UV- or thermally-reactive groups (A) and (b) one or more second monomers comprising a high refractive index core and further comprising one or more groups capable of reacting to increase the solubility of the copolymer in aqueous media (B), and the formulation comprising (a) a copolymer comprising one or more bifunctional high refractive index first monomers comprising a high refractive index aromatic core and further comprising one or more UV- or thermally-reactive groups (A) and (b) one or more second monomers comprising a high refractive index core and further comprising one or more groups capable of reacting to increase the solubility of the copolymer in aqueous media (B); (c) one or more additional polymers or copolymers; (d) one or more photoinitiators and/or thermal initiators; (e) one or more cross-linking agents; (f) one or more antioxidants; (g) one or more surface leveling agents; and (h) one or more solvents are the same as those disclosed herein in the context of the copolymer composition and the formulation above herein.

The formulation may be coated to form an optical thin film. Spin coating is a non-limiting example of coating processes known to those with skill in the art. Other non-limiting processes include dip-coating, drop-casting, roller-coating, screen printing, ink-jet printing, gravure, slot-die coating, or other conventional coating techniques. In the electronics manufacturing industry, spin-coating and slot-die coating are preferred methods to take advantage of existing equipment and processes. In spin-coating, the solids content of the composition may be adjusted, along with the spin speed, to achieve a desired thickness of the formulation on the surface to which it is applied. Typically, the present formulations are spin-coated at a spin speed of 400 to 4000 rpm. The amount of the formulation dispensed on the substrate depends on the total solids content in the composition, the desired thickness of the resulting coating layer, and other factors well-known to those skilled in the art.

Substrates onto which the formulations may be coated are those generally used in the art. In some non-limiting embodiments, the substrates used are selected from the group consisting of silica, Si wafers, silicon nitride, silicon oxynitride, silicon carbide, silicon-germanium, gallium-arsenide, indium-phosphide, indium-tin-oxide, aluminum nitride, alumina, glass, and the like. In some non-limiting embodiments, the substrates used are selected from the group consisting of silica, Si wafers, silicon nitride, and silicon carbide. In some non-limiting embodiments, the substrate used is Si wafers. In some non-limiting embodiments, the substrate used is glass. In some non-limiting embodiments, the substrate used comprises a polymer film or a polymer composite film akin to those generally used in the art. In some non-limiting embodiments, the substrate used comprises multiple materials, including those specified above, disposed in layers or patterns that vary in composition.

The thickness of the formulation and/or optical thin film is not particularly limited and will depend, for example, on the particular application or use. In some non-limiting embodiments, the thickness of the coating and/or optical thin film is between 50 nm and 100 μm. In some non-limiting embodiments, the thickness of the coating and/or optical thin film is between 100 nm and 50 μm. In some non-limiting embodiments, the thickness of the coating and/or optical thin film is between 500 nm and 20 μm. In some non-limiting embodiments, the thickness of the coating and/or optical thin film is between 1 μm and 10 μm. In some non-limiting embodiments, the thickness of the coating and/or optical thin film is 1 μm, in some non-limiting embodiments 2 μm, in some non-limiting embodiments 3 μm, in some non-limiting embodiments 4 μm, in some non-limiting embodiments 5 μm, in some non-limiting embodiments 6 μm, in some non-limiting embodiments 7 μm, in some non-limiting embodiments 8 μm, in some non-limiting embodiments 9 μm, and in some non-limiting embodiments 10 μm.

In some non-limiting embodiments, after being coated on a substrate surface, the formulation is soft-baked (heated) to remove any organic solvent present. Typical soft-baking temperatures are from 90° C. to 140° C., although other suitable temperatures may be used. In some non-limiting embodiments of the present disclosure, the soft-baking is performed at temperatures between 90° C. and 130° C., in some non-limiting embodiments between 90° C. and 120° C., in some non-limiting embodiments between 90° C. and 110° C., and in some non-limiting embodiments between 90° C. and 100° C. In some non-limiting embodiments; the soft-baking is performed at 90° C., in some non-limiting embodiments 100° C., in some non-limiting embodiments 110° C., in some non-limiting embodiments 120° C., in some non-limiting embodiments 130° C., and in some non-limiting embodiments 140° C. Soft-baking is generally done for approximately 30 sec. to 2 min., although longer or shorter times may suitably be used. In some non-limiting embodiments, soft-baking is done for 30 sec., in some non-limiting embodiments 45 sec., in some non-limiting embodiments 1 min., in some non-limiting embodiments 1 min. 15 sec., in some non-limiting embodiments 1 min. 30 sec., in some non-limiting embodiments 1 min. 45 sec., and in some non-limiting embodiments 2 min. In some non-limiting embodiments, soft-baking is done for 15 sec., and in some non-limiting embodiments soft-baking may be done for 3 minutes or more. Following solvent removal, a film of the copolymer on the substrate surface is obtained.

After the soft-bake step, the coating layer, film, or coating may be optionally further dried under vacuum to remove residual solvent. A vacuum level of 200 to 400 mTorr is typically applied for 20 to 100 seconds. Such vacuum drying to remove residual solvent is typically done at 200 mTorr for 1 to 10 seconds, although longer or shorter times may suitably be used. Drying under vacuum typically occurs at room temperature.

After the soft-bake step, the coating layer, film, or coating may optionally be patterned to create features upon the substrate. Features are typically formed by exposing portions of the coating to light through a mask, triggering a photochemical reaction in the exposed regions. The wavelength of light is selected based on the application and material design. In some cases, the photochemical reaction decreases the solubility of the exposed area (negative photoresist design), and in other cases, the photochemical reaction increases the solubility of the exposed area (positive photoresist design). After the light exposure step, the soluble portions of the photopatterned coating are rinsed away with a developer solvent. Depending on the particular copolymer and components of the composition, the photopatterning may cause further change to the copolymer, for example, through one or more of polymerization, condensation, cross-linking, deprotection, or bond cleavage. The photopatterning step is typically conducted in a mask aligner. The wavelength, time, and intensity of the light exposure in the patterning step will depend on the particular copolymer composition and the layer thickness. In some non-limiting embodiments, the coated film was exposed, through a photo-mask having a pattern consisting of square holes 1-100 μm in size, to broad-band light (300 to 800 nm) at an exposure dosage of 10 to 200 mJ/cm² based on a wavelength of 365 nm for a time period of 0.5 to 80 seconds using an aligner, which emits light having a wavelength of 300 nm to 800 nm (10-35 mW/cm²). In some non-limiting embodiments, the developer used is an aqueous solution of 2.38 wt % tetramethylammonium hydroxide dispensed as a puddle to completely cover the film for 40 to 10 seconds, and then rinsed by distilled water for 30 seconds.

After the soft-bake step, the coating layer, film, or coating is typically cured at elevated temperature to remove substantially all of the solvent from the polymeric layer, thereby forming a tack-free coating and improving adhesion of the layer to the underlying structure. Depending on the particular copolymer and components of the composition, the cure may cause further change to the polymer, for example, through one or more of oxidation, outgassing, polymerization, condensation, or cross-linking. The cure is typically conducted on a hotplate or in an oven. The cure can be conducted, for example, in an atmosphere of air or inert gas such as nitrogen, argon or helium, or can be conducted under vacuum. In one non-limiting embodiment, the polymeric layer is cured in an inert gas atmosphere. In one non-limiting embodiment, the polymeric layer is cured under ambient atmospheric conditions. The temperature and time for the cure will depend, for example, on the particular copolymer and solvent of the formulation, and the layer thickness. In some non-limiting embodiments, cure temperatures are from 100° C. to 450° C. In some non-limiting embodiments, cure temperatures are 300° C. to 400° C., or from 325° C. to 350° C. In coatings wherein the polymeric layer comprises a cross-linker and/or a thermal acid generator, lower cure temperatures can sometimes be used. In some non-limiting embodiments, these lower cure temperatures are from 50° C. to 250° C. In some non-limiting embodiments, these lower cure temperatures are from 150° C. to 200° C. In one non-limiting embodiment, wherein the copolymeric layer comprises a cross-linker, the cure temperature is 230° C. In some non-limiting embodiments, the cure time is from 30 seconds to two hours. In some non-limiting embodiments, the cure time is from 1 minute to 60 minutes. In one non-limiting embodiment, the cure time is 30 minutes. The cure can be conducted in a single step or in multiple steps. The cure can be conducted by heating the copolymer composition layer at constant temperature or with a varied temperature profile such as a ramped or terraced temperature profile. The temperatures and times associated with the ramped or terraced temperature profile are generally preselected based on the specific formulation composition and intended end use of the associated layer, film, or coating that results from the method.

The present disclosure is further directed to an optical thin film comprising a copolymer comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B). In some non-limiting embodiments, the optical thin film has a thickness between 10 nm and 100 μm. In some non-limiting embodiments, the optical thin film as a thickness between 100 nm and 50 μm, in some non-limiting embodiments between 500 nm and 25 μm, in some non-limiting embodiments between 750 nm and 15 μm, in some non-limiting embodiments between 0.01 μm and 12 μm, in some non-limiting embodiments between 0.1 μm and 10 μm, and in some non-limiting embodiments between 1 μm and 5 μm.

In some non-limiting embodiments, the optical thin films of the present disclosure have a refractive index measured at 550 nm that is greater than 1.500 and in some non-limiting embodiments greater than 1.550. In some non-limiting embodiments, the optical thin films of the present disclosure have a refractive index measured at 550 nm that is greater than 1.600, in some non-limiting embodiments greater than 1.650, in some non-limiting embodiments greater than 1.660, in some non-limiting embodiments greater than 1.670, in some non-limiting embodiments greater than 1.680, in some non-limiting embodiments greater than 1.690, in some non-limiting embodiments greater than 1.700, in some non-limiting embodiments greater than 1.710, in some non-limiting embodiments greater than 1.720, in some non-limiting embodiments greater than 1.730, in some non-limiting embodiments greater than 1.740, in some non-limiting embodiments greater than 1.750, in some non-limiting embodiments greater than 1.760, in some non-limiting embodiments greater than 1.770, in some non-limiting embodiments greater than 1.780, and in some non-limiting embodiments greater than 1.790. In some non-limiting embodiments, the coatings and/or optical thin films of the present disclosure have a refractive index measured at 550 nm that is greater than 1.800.

In some non-limiting embodiments, the optical thin films of the present disclosure have a refractive index measured at other wavelengths of the visible spectrum. In some non-limiting embodiments, the optical thin films of the present disclosure have a refractive index measured between 380 nm and 1400 nm. In some non-limiting embodiments, the optical thin films of the present disclosure have a refractive index measured between 400 nm and 700 nm. In some non-limiting embodiments, the optical thin films of the present disclosure have a refractive index measured between 450 nm and 650 nm. In some non-limiting embodiments, the optical thin films of the present disclosure have a refractive index measured between 500 nm and 600 nm.

In some non-limiting embodiments, the optical thin films of the present disclosure have a refractive index measured at these other wavelengths of the visible spectrum that is greater than 1.500. In some non-limiting embodiments, the optical thin films of the present disclosure have a refractive index measured at these other wavelengths of the visible spectrum that is greater than 1.600. In some non-limiting embodiments, the optical thin films of the present disclosure have a refractive index measured at these other wavelengths of the visible spectrum that is greater than 1.650. In some non-limiting embodiments, the optical thin films of the present disclosure have a refractive index measured at these other wavelengths of the visible spectrum that is greater than 1.670. In some non-limiting embodiments, the optical thin films of the present disclosure have a refractive index measured at these other wavelengths of the visible spectrum that is greater than 1.700. In some non-limiting embodiments, the optical thin films of the present disclosure have a refractive index measured at these other wavelengths of the visible spectrum that is greater than 1.800.

In some non-limiting embodiments, the optical thin films of the present disclosure have a percent transmittance at a film thickness of 2 μm greater than or equal to 80% at wavelengths between 400 nm and 1000 nm, in some non-limiting embodiments greater than or equal to 85% at wavelengths between 400 nm and 1000 nm, in some non-limiting embodiments greater than or equal to 90% at wavelengths between 400 nm and 1000 nm, in some non-limiting embodiments greater than or equal to 95% at wavelengths between 400 nm and 1000 nm, and in some non-limiting embodiments greater than or equal to 99% at wavelengths between 400 nm and 1000 nm.

In some non-limiting embodiments, the optical thin films of the present disclosure are soluble in aqueous developer solutions used in the electronics industry. In one non-limiting embodiment, a soft-baked film is submerged in aqueous tetramethyl ammonium hydroxide (TMAH) solution (2.38%) for 2 minutes, and the film thicknesses before and after exposure are compared to calculate a percent film loss. In another non-limiting embodiment, a soft-baked film is exposed to aqueous tetramethyl ammonium hydroxide (TMAH) solution (2.38%) in a Thin Film Analyzer TFA-11CT (Luzchem), and the film thickness is measured over time using single or multi-wavelength analysis across 400 nm to 850 nm in order to determine the dissolution rate. Other developing solutions typical in the electronics industry are aqueous tetramethyl ammonium hydroxide (TMAH) solutions of varying concentrations, aqueous tetrabutyl ammonium hydroxide (TBAH) solutions, buffered or unbuffered aqueous potassium hydroxide solutions, and buffered or unbuffered aqueous sodium hydroxide solutions. In other non-limiting embodiments, the developer can be an organic solvent or a blend of organic solvent and cosolvents. In some non-limiting embodiments, the solvent and/or cosolvent is selected from the group consisting of propylene glycol methyl ether, propylene glycol methyl ether acetate, diethylene glycol methyl ethyl ether, methyl isobutyl ketone, methyl ethyl ketone, methyl propyl ketone, ethyl ethoxypropionate, methyl isoamyl ketone, dimethyl ketone, cyclopentanone, benzyl benzoate, cyclohexanone, methyl 2-hydroxyl isobutyrate, ethyl acetate, ethyl lactate, butyl acetate, methanol, butanol, isopropyl alcohol, N-methylpyrrolidinone, dimethylacetamide, dimethylsulfoxide, anisole, γ-butyrolactone, isobutyl isobutyrate, n-heptane, and the like and combinations thereof.

There are a number of reliability parameters associated with the optical thin films disclosed herein which make them useful in a variety of optical and electronic applications.

The reliability-in-use is generally assessed by the stability of the optical thin film refractive index and/or percent transmission at wavelengths between 400 nm and 1000 nm when the optical thin films are exposed to a variety of environmental stressors. In some non-limiting embodiments of the optical thin films disclosed herein, the refractive index of the optical thin film at 550 nm changes by less than or equal to 15% when exposed to one or more environmental stressors, in some non-limiting embodiments the refractive index of the optical thin film at 550 nm changes by less than or equal to 10% when exposed to one or more environmental stressors, in some non-limiting embodiments the refractive index of the optical thin film at 550 nm changes by less than or equal to 5% when exposed to one or more environmental stressors, in some non-limiting embodiments the refractive index of the optical thin film at 550 nm changes by less than or equal to 4% when exposed to one or more environmental stressors, in some non-limiting embodiments the refractive index of the optical thin film at 550 nm changes by less than or equal to 3% when exposed to one or more environmental stressors, in some non-limiting embodiments the refractive index of the optical thin film at 550 nm changes by less than or equal to 2% when exposed to one or more environmental stressors, and in some non-limiting embodiments the refractive index of the optical thin film at 550 nm changes by less than or equal to 1% when exposed to one or more environmental stressors.

In some non-limiting embodiments of the optical thin films disclosed herein, the percent transmission at wavelengths between 400 nm and 1000 nm of the optical thin film at 550 nm changes by less than or equal to 15% when exposed to one or more environmental stressors, in some non-limiting embodiments the percent transmission at wavelengths between 400 nm and 1000 nm of the optical thin film at 550 nm changes by less than or equal to 10% when exposed to one or more environmental stressors, in some non-limiting embodiments the percent transmission at wavelengths between 400 nm and 1000 nm of the optical thin film at 550 nm changes by less than or equal to 5% when exposed to one or more environmental stressors, in some non-limiting embodiments the percent transmission at wavelengths between 400 nm and 1000 nm of the optical thin film at 550 nm changes by less than or equal to 4% when exposed to one or more environmental stressors, in some non-limiting embodiments the percent transmission at wavelengths between 400 nm and 1000 nm of the optical thin film at 550 nm changes by less than or equal to 3% when exposed to one or more environmental stressors, in some non-limiting embodiments the percent transmission at wavelengths between 400 nm and 1000 nm of the optical thin film at 550 nm changes by less than or equal to 2% when exposed to one or more environmental stressors, and in some non-limiting embodiments the percent transmission at wavelengths between 400 nm and 1000 nm of the optical thin film at 550 nm changes by less than or equal to 1% when exposed to one or more environmental stressors.

The optical thin films disclosed herein exhibit excellent reliability-in-use when exposed and/or repeatedly exposed to high temperatures. In some non-limiting embodiments of the optical thin films disclosed herein, the percent transmission at wavelengths between 400 nm and 1000 nm of the optical thin film at 550 nm changes by less than or equal to 20% when exposed to thermal stress of 230° C. for 30 minutes. This test can be repeated or extended to longer thermal stress exposures up to 2 hours, and less than 15% further change in transmittance is observed.

The optical thin films disclosed herein exhibit excellent reliability-in-use when exposed and/or repeatedly exposed to high-temperature/high-humidity conditions. In some non-limiting embodiments of the optical thin films disclosed herein, the percent transmission at wavelengths between 400 nm and 1000 nm of the optical thin film at 550 nm changes by less than or equal to 15% when exposed for periods less than or equal to 21 days to thermal and moisture stress in a chamber with 85% relative humidity, heated to 85° C. or in a chamber with 65% relative humidity, heated to 95° C.

The optical thin films disclosed herein exhibit excellent reliability-in-use when exposed and/or repeatedly exposed to UV light. In some non-limiting embodiments of the optical thin films disclosed herein, the percent transmission at wavelengths between 400 nm and 1000 nm of the optical thin film at 550 nm changes by less than or equal to 15% when exposed to the full solar spectrum to a dose less than or equal to 2 MLux hr. In some non-limiting embodiments of the optical thin films disclosed herein, the percent transmission at wavelengths between 400 nm and 1000 nm of the optical thin film at 550 nm changes by less than or equal to 30% when exposed to the full solar spectrum to a dose less than or equal to 5 MLux hr.

The optical thin films disclosed herein exhibit excellent reliability-in-use when exposed and/or repeatedly exposed to visible light. In some non-limiting embodiments of the optical thin films disclosed herein, the percent transmission at wavelengths between 400 nm and 1000 nm of the optical thin film changes by less than or equal to 15% when exposed to a full solar spectrum with >50% of the intensity at wavelengths less than 390 nm attenuated to a dose less than or equal to 2 MLux hr. In some non-limiting embodiments of the optical thin films disclosed herein, the percent transmission at wavelengths between 400 nm and 1000 nm of the optical thin film changes by less than or equal to 30% when exposed to the full solar spectrum with >50% of the intensity at wavelengths less than 390 nm attenuated to a dose less than or equal to 5 MLux hr.

The present disclosure is further directed to an optical device comprising an optical thin film comprising a copolymer comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B) wherein the optical device is a display device. Non-limiting examples of optical devices include standard light emitting diodes (LEDs), mini LEDs, microLEDs, nanoLEDs, quantum dot LEDs (QD-LEDs), organic LEDs (OLEDS), quantum dot organic LEDs (QD-OLEDs), optical waveguides, CMOS image sensors, and others generally known to those having skill in the art. Specific embodiments of these display devices are generally known to those having skill in the particular art in which they are applied.

Electronic devices that may benefit from having one or more layers comprising the optical materials disclosed herein include, but are not limited to, (1) devices that convert electrical energy into radiation (e.g., a light-emitting diode, light emitting diode display, diode laser, or lighting panel), (2) devices that detect an optical signal using an electronic process (e.g., a photodiode, a photodetector, a photoconductive cell, a photoresistor, a photoswitch, a phototransistor, a phototube, an infrared (“IR”) detector, or a biosensor), (3) devices that convert radiation into electrical energy (e.g., a photovoltaic device or solar cell), (4) devices that convert light of one wavelength to light of a different wavelength, (e.g., a down-converting phosphor device or a frequency doubling element), (5) devices that include one or more electronic components that include one or more organic semiconductor layers (e.g., a transistor or diode), (6) devices that collect or focus incident light in optical devices (e.g., a microlens in a CMOS image sensor), or any combination of devices in items (1) through (6). In some non-limiting examples, the devices are display devices.

In these electronic devices, the optical materials disclosed herein can be utilized in several different forms, including but not limited to thin films, thick films, and individual optical features of a form to perform the necessary aforementioned functions. Moreover, these films can be modified to include complex topography necessary to perform the necessary aforementioned functions.

In some embodiments, the device is a display. In these cases, the display is comprised of the optical material along with several additional functional layers that serve to emit and guide light to the surface of the panel, generating an image useful for a user-interface in applications including but not limited to televisions, computers, mobile phones, game consoles, automotive, and user-controlled “smart” devices such as home appliances and public information kiosks. The optical material and several additional functional layers form a stack of materials through which the light must travel, and the mismatch of refractive indices between adjacent layers can greatly reduce the overall brightness and efficiency of these devices. Light generated in the emissive layer is lost via scattering and internal reflection. The coatings and optical thin films disclosed herein can be used to dampen the refractive index gradient through a device and disrupt losses amplified by undesired waveguiding modes. In some non-limiting embodiments, the coatings and optical thin films disclosed herein can be used as relatively-high-refractive index light-extraction layer between an OLED encapsulant layer and polarizer layer to greatly increase number of photons emitted from a top-display device. In some non-limiting embodiments, the coatings and optical thin films disclosed herein can be used in the formation of relatively low-refractive-index banks between pixels in the emissive layer of an OLED to improve display power efficiency. Importantly, the refractive indices of the coatings and optical thin films can be tuned via curing processes within a particular composition to accommodate the material changes made elsewhere in the device stack as optimum performance is sought.

In some embodiments, the device is a CMOS image sensor. In these cases, the sensor is comprised of the optical material along with several additional functional layers that serve to guide filtered ambient light to the surface of a single CMOS photodetector, generating an electrical response to a photonic stimulus that can be electronically amplified and processed to create digital information. Most frequently, these functional material layers are patterned and disposed to create an array of many individual wavelength-sensitive photodetectors, frequently called active pixel sensors. By combining and processing active pixel sensor signal information from the multitude of active pixel sensors in the array, a digital image is created.

In these electronic devices that may benefit from having one or more layers comprising the optical materials disclosed herein, the optical material may form a planar layer. In some embodiments, the optical material may form a conformal layer that follows the contours of the underlying substrate. In some embodiments, the optical material may form a particular lens structure or array of lenses.

In the display device design, the optical material can serve as a simple lens element, focusing emitted light to a desired viewing angle. When functioning as a lens element, the optical material is typically disposed upon a multilayer substrate. In some embodiments, the display device is a bottom emission design, in which the multilayer substrate comprises a color filter array, thin-film transistor backplane, and a transparent substrate. In bottom emission displays, the emitting materials may be deposited after the optical material discussed herein. In some embodiments, the display device is a top emission design, in which the multilayer substrate comprises an encapsulant, electrodes, emitting materials, charge transport materials, thin film transistor backplane, and substrate material. In top emission displays, the emitting materials are deposited before the optical material discussed herein. The presence or lack of emitting materials at the time of optical material deposition significantly impacts the available processing conditions, as the emitting materials can be unstable under particular conditions.

In the CMOS image sensor design, the optical material can serve as a simple lens element, focusing ambient light upon an individual active pixel sensor. When functioning as a lens element, the optical material is typically disposed upon a multi-layer photodiode component. In still other embodiments of the CMOS image sensor design, the lens element layer is further coated with additional material layers that are also penetrated by light en route to the image sensor. These materials may serve one or more of several functional roles to drive improved sensor performance by adjusting component properties, including but not limited to antireflective properties, mechanical properties, optical properties, surface roughness, thermal stability, and photostability.

In any device that utilizes the optical material as a lens element, the focal length (f) of the lens element comprised of the optical material can vary depending on the refractive index (n) of the optical material and the design of the device. The device design can influence the thickness of the lens element layer (d) and its radii of curvature (R₁, R₂), guaranteeing that the majority of light directed by the lens component is delivered to a specific location. The relationship between these design and performance elements is generally expressed in the lensmaker's equation:

$$\\ \frac{1}{f} = ( n - 1 ) [ \frac{1}{{R}_{1}} - \frac{1}{{R}_{2}} + \frac{( n - 1 ) d}{{nR}_{1} {R}_{2}} ]$$

The device layers can be formed by any deposition technique, or combinations of techniques. including vapor deposition, liquid deposition, and thermal transfer.

In some embodiments of the optical device, the optical material comprising the lens element layer must be deposited first into a planar film layer, and then further processed to form the lens in accordance with the device design. The manner of forming the lens shape can vary. In some cases, the lens is formed by lithographic patterning and selective removal of a photoactive optical material comprising the lens, followed by thermal processing above the material's glass transition temperature to reflow the material into a hemispherical shape. In other cases, the lens is formed by coating the optical material comprising the lens with a photoresist that is coated, patterned, and reflowed as described previously, forming a hemispherical lens shape comprised of photoresist resting atop the optical material comprising the lens. In a second step of this process, the lens shape is transferred to the optical material comprising the lens by exposing the film to a reactive ion etch of fluoride or oxygen, among others, leaving behind a lens shape in the optical material comprising the lens. In still other cases, a photoactive optical material comprising the lens is patterned in a low-contrast process using a greyscale or half-tone photomask, which leaves a lens shape after the exposed portion of the material is removed during a developer step. In still other cases, the optical material comprising the lens is coated as a leveling material to fill an inverted lens cavity produced in a previous step. In some cases, the inverted lens cavity is patterned in a low-contrast process using a greyscale or half-tone photomask and optionally further etched. In other cases, the inverted lens cavity is produced by etching through a subsequent photopatterned sacrificial layer to transfer the pattern. In still other cases, the lens shape is formed through direct contact pattern transfer methods, such as nanoimprinting.

The coatings and optical thin films, and their associated properties, according to the present disclosure may be prepared and used according to the examples set out below. The examples are presented herein for purposes of illustration of the present disclosure and are not intended to limit the scope of the invention described in the claims.

### EXAMPLES

### Copolymer P32 Synthesis

In a 1 L reaction vessel, 9,9-Bis(4-glycidyloxyphenyl)fluorene (50.0 g, 1.0 equiv) was dissolved in propylene glycol methyl ether acetate (PGMEA, 102.475 g. 40 wt % solids). Then, methyl hydroquinone (MEHQ, 0.01 equiv, 0.13 g), acrylic acid (2.2 equiv, 17.1 g), and catalytic tetrabutylammonium bromide (3 mol %, 1.0 g) were added to the reactor. The reaction mixture was heated to 120° C. and stirred at 150 rpm with a mechanical stirrer for 6 h. After cooling, s-bisphenyl dianhydride (BPDA, 0.5 equiv, 23.9 g) and PGMEA (35.8 g) were added to the reaction mixture. The reaction was kept at 120° C. for 9 h while stirring with a mechanical stirrer at 150 rpm. The homogenous reaction mixture was then cooled to room temperature. In the third step, the monofunctional monomer tetrahydrophathlic anhydride (THPA, 2.9 g, 0.4 equiv) and PGMEA (4.3 g) were added to achieve a 40 wt % solids reaction. The reaction was heated to 120° C. while stirring at 150 rpm with a mechanical stirrer for 6 h. The reaction was then cooled to 25° C.

This general procedure was also used to prepare the copolymers reported in Table 1, where the total scale of the polymerization may be optionally chosen from 5 g to 1000 g and the reaction times may be varied from 1 hour to 24 hours.

TABLE 1
Copolymer compositions

| | | | | | | | Equiv. | Reactive | | Equiv. | | |
|---|---|---|---|---|---|---|---|---|---|---|---|---|
| Polymer | Monomer | | | Monomer | | Monomer | Monomer | Group | Monomer | Monomer | Solids | |
| # | A | X1 | X2 | A′ | Y | B | B | R | M | M | % | Solvent |
| P1 | 22A | O | O | None | — | 3B | 0.8 | R1 | None | 0 | 40% | PGMEA |
| P2 | 22A | O | O | None | — | 32B | 0.8 | R1 | None | 0 | 40% | PGMEA |
| P3 | 16A | O | O | None | — | 8B | 0.8 | R1 | None | 0 | 40% | PGMEA |
| P4 | 22A | O | O | None | — | 15B | 0.8 | R1 | None | 0 | 40% | PGMEA |
| P5 | 22A | O | O | None | — | 17B | 0.8 | R1 | None | 0 | 40% | PGMEA |
| P6 | 22A | O | O | None | — | 18B | 0.8 | R1 | None | 0 | 40% | PGMEA |
| P7 | 22A | O | O | None | — | 10B | 0.8 | R1 | None | 0 | 40% | PGMEA |
| P8 | 22A | O | O | None | — | 1B | 0.8 | R1 | None | 0 | 40% | PGMEA |
| P9 | 22A | O | O | None | — | 28B | 0.8 | R1 | None | 0 | 40% | PGMEA |
| P10 | 22A | O | S | None | — | 32B | 0.8 | R1 | None | 0 | 40% | DMF |
| P11 | 22A | O | O | None | — | 18B | 0.85 | R1 | None | 0 | 40% | DMF |
| P12 | 22A | O | O | None | — | 29B | 0.8 | R1 | None | 0 | 25% | PGMEA/ |
| | | | | | | | | | | | | DMF |
| | | | | | | | | | | | | (3:4 wt:wt) |
| P13 | None | O | O | 22A′ | EtOH | 18B | 0.8 | None | None | 0 | 25% | PGMEA/ |
| | | | | | | | | | | | | DMF |
| | | | | | | | | | | | | (2:3 wt:wt) |
| P14 | None | O | O | 22A′ | OH | 32B | 0.8 | None | None | 0 | 40% | DMF |
| P15 | 22A | O | O | None | — | 8B | 0.8 | R2 | None | 0 | 40% | PGMEA |
| P16 | 22A | O | O | None | — | 8B | 0.8 | R1 | M11 | 0.4 | 40% | PGMEA |
| P17 | 22A | O | O | None | — | 8B | 0.8 | R1 | M10 | 0.4 | 25% | PGMEA/ |
| | | | | | | | | | | | | DMF |
| P18 | 22A | O | O | None | — | 8B | 0.8 | R1 | M14 | 0.4 | 40% | PGMEA |
| P19 | 22A | O | O | None | — | 8B | 0.8 | R1 | None | 0 | 40% | PGMEA |
| P20 | None | O | O | 22A′ | EtOH | 8B | None | None | None | 0 | 40% | TMU |
| P21 | 22A | O | O | None | — | 8B | 0.8 | R1 | None | 0 | 40% | TMU |
| P22 | 22A | O | O | None | — | 10B | 0.8 | R1 | None | 0 | 40% | TMU |
| P23 | 22A | O | O | None | — | 26B | 0.8 | R1 | None | 0 | 40% | TMU |
| P24 | 18A | O | O | None | — | 8B | 0.8 | R1 | None | 0 | 40% | PGMEA |
| | (Alk = Et) | | | | | | | | | | | |
| P25 | 26A | O | O | None | — | 8B | 0.8 | R1 | None | 0 | 40% | PGMEA |
| P26 | 22A | O | O | None | — | 8B | 0.8 | R7 | None | 0 | 40% | PGMEA |
| P27 | 11A | O | O | None | — | 8B | 0.8 | R1 | None | 0 | 40% | PGMEA |
| P28 | 22A | O | S | None | — | 19B | 0.8 | R1 | None | 0 | 40% | DMF |
| P29 | 22A | O | O | None | — | 8B | 0.8 | R8 | None | 0 | 40% | PGMEA |
| P30 | 22A | O | O | None | — | 8B | 0.8 | R9 | None | 0 | 40% | PGMEA |
| P31 | 22A | O | O | None | — | 8B | 0.8 | R1 | M3 | 0.4 | 40% | PGMEA |
| P32 | 2A | S | O | None | — | 8B | 0.8 | R1 | M1 | 0.4 | 40% | PGMEA |
| P33 | 2A | S | O | None | — | 19B | 0.8 | R1 | M1 | 0.4 | 40% | PGMEA |
| P34 | 22A | S | O | None | — | 8B | 0.9 | R1 | M1 | 0.4 | 40% | PGMEA |
| P35 (Compar- | 44A | O | O | None | — | 19B | 0.9 | R1 | M1 | 0.4 | 40% | PGMEA |
| ative) | | | | | | | | | | | | |

Note:
Solvent abbreviations are as follows: propylene glycol methyl ether acetate (PGMEA), dimethylformamide (DMF), trimethyl urea (TMU).

### Copolymer Film Characterization

Several polymers from Table 1 were cast as films, in some cases with the addition of a surface leveling agent and characterized as reported in Table 2. For film thickness and refractive index measurement, a coated and cured film on silicon was placed on an alpha-SE ellipsometer (J. A. Woollam). A Cauchy film model was used to fit: refractive index, attenuation coefficient, surface roughness, native silica thickness, angle offset, and film thickness. Alternatively, a coated and cured film on glass was measured in a Metricon Model 2010/M Prism Coupler.

For film transmittance measurement, a coated and cured film on Eagle XG glass of approximately 2 μm thickness was measured via transmission UV-Vis. An uncoated Eagle XG coupon of the same thickness as the sample substrate was measured as a blank. The film thickness of coated and cured films on Eagle XG glass were measured using a Filmetrics thickness measurement instrument with refractive index as a fixed input or a 3D profiler. In some cases, three measurements across the sample were recorded and averaged and a Fourier filter was applied to remove interference fringes from the data. All data were normalized to a 2.0 μm standard thickness. The % Transmittance was then read out from the resulting normalized curve.

TABLE 2
Copolymer film properties

| | | Surface leveling | | | Refractive Index | | % Transmittance | | |
|---|---|---|---|---|---|---|---|---|---|
| Film | Based on | agent | | Curing | Film Thickness | RI @ | Film Thickness | % T @ | % T @ 410 nm |
| # | Polymer # | Component | Wt % | Conditions | (nm) | 550 nm | (nm) | 410 nm | after 230 C./60 min |
| FL1 | P3 | Polyfox-656 | 0.05% | Low Temp | 301 | 1.639 | 2014 | 87.6 | 81.7 |
| FL2 | P4 | Polyfox-656 | 0.05% | Low Temp | 303 | 1.630 | 1708 | 99.2 | 95.6 |
| FL3 | P9 | — | — | Low Temp | 3258 | 1.622* | 3258 | 98.5 | 97.3 |
| FL4 | P10 | — | — | Low Temp | 3356 | 1.627* | 3356 | 96.9 | 63.3 |
| FL5 | P11 | — | — | Low Temp | 2225 | 1.641* | 2225 | 97.3 | 96.1 |
| FL6 | P12 | — | — | Low Temp | 1808 | 1.635* | 1808 | 96.5 | 96.1 |
| FL7 | P13 | — | — | Low Temp | 1822 | 1.668* | 1822 | 97.8 | N.D. |
| FL8 | P16 | — | — | High Temp | 1707 | 1.624* | 1707 | 96.1 | 96.0 |
| FL9 | P18 | — | — | High Temp | 1761 | 1.627* | 2106 | 96.6 | 97.1 |
| FL10 | P26 | FZ-2122 | 0.05% | High Temp | 2121 | 1.651* | 2121 | 96.7 | 97.6 |
| FL11 | P27 | FZ-2122 | 0.05% | High Temp | 2498 | 1.657* | 2498 | 90.2 | 88.7 |
| FL12 | P28 | FZ-2122 | 0.05% | Low Temp | 1265 | 1.669* | 1265 | 94.1 | 50.5 |
| FL13 | P29 | FZ-2122 | 0.05% | High Temp | 2844 | 1.680* | 2844 | 94.7 | 92.9 |
| FL14 | P30 | FZ-2122 | 0.05% | High Temp | 2227 | 1.675* | 2227 | 92.9 | 93.1 |
| FL15 | P33 | FZ-2122 | 0.05% | Low Temp | 455 | 1.655 | 1900 | 93.4 | N.D. |
| FL16 | P34 | FZ-2122 | 0.05% | Low Temp | 481 | 1.660 | 2000 | 94.0 | N.D. |
| FL17 | P35 (Compar- | FZ-2122 | 0.05% | High Temp | 327 | 1.611 | 1730 | 93.1 | 92.8 |
| | ative) | | | | | | | | |

| Formulation | | | | | | | Surface leveling | | | |
|---|---|---|---|---|---|---|---|---|---|---|
| # | Polymer | | Cross-linker | | Photoinitiator | | agent | | Solvent | |
| — | Component | Wt % | Component | Wt % | Component | Wt % | Component | Wt % | Component | Wt % |
| F1 | P31 | 12.74% | HR-6042 | 6% | OXE-01 | 0.76% | FZ-2122 | 0.05% | PGMEA | 80.5% |
| F2 | P31 | 12.74% | RP-1040 | 6% | SPI-03 | 0.76% | FZ-2122 | 0.05% | PGMEA | 80.5% |
| F3 | P31 | 12.74% | XL1 | 6% | SPI-05 | 0.76% | FZ-2122 | 0.05% | PGMEA | 80.5% |
| F4 | P31 | 12.74% | SR349 | 6% | SPI-03 | 0.76% | FZ-2122 | 0.05% | PGMEA | 80.5% |
| F5 | P33 | 12.74% | HR-6042 | 6% | OXE-01 | 0.76% | FZ-2122 | 0.05% | PGMEA | 80.5% |
| F6 | P34 | 12.74% | SR349 | 6% | OXE-01 | 0.76% | FZ-2122 | 0.05% | PGMEA | 80.5% |
| F7 | P34 | 12.74% | HR-6042 | 6% | SPI-03 | 0.76% | FZ-2122 | 0.05% | PGMEA | 80.5% |

Note:
The Low Temp process utilized in Table 2 consists of: soft-bake at 100° C. for 100 seconds and cure at 85° C. for 40 minutes. The High Temp. process utilized in Table 2 consists of: soft-bake at 105° C. for 90 seconds and cure at 230° C. for 30 minutes. A thermal stress was applied at 230° C. for an additional 60 minutes as a measure of film reliability. Refractive indices marked with an asterisk (*) were measured at 543 nm. All reported % Transmittances are normalized to a 2.0 μm film thickness.

### Formulation Preparation

To a vial or bottle are added the following order: first, powder materials (SPI-03 and Irganox1010) and PGMEA are added placed on a shaker to fully dissolve the powers, generally at 100 to 300 rpm for 5 to 10 minutes. Polymers, cross-linkers, surface leveling agent, and other additives can be added after powders are dissolved without recommended order. The formulation is then filtered by polyvinylidene fluoride or polytetrafluoroethylene syringe filters with a 1 to 5 um pore size. This procedure was used to prepare the formulations reported in Table 3. The sample formulation scale is typically 20 g to 50 g but may be prepared up to 1000 g or more. Table 3. Formulation compositions
Note: Solvent abbreviations are as follows: propylene glycol methyl ether acetate (PGMEA)

### Formulation Film Characterization

Several formulations from Table 3 were cast as films and characterized as reported in Table 4. For film thickness and refractive index measurement, a coated and cured (at low or high temperature) film on silicon was placed on an alpha-SE or M-2000D ellipsometer (J. A. Woollam) or Elli-SE ellipsometer (Ellipsotechnology) for film thickness and refractive index measurement. A Cauchy film model (alpha-SE), B-spline model (M-2000D), or Tauc-Lorentz equation (Elli-SE) was used to fit: refractive index, attenuation coefficient, surface roughness, native silica thickness, angle offset, and film thickness. Coated and cured films on Eagle XG glass were measured using a Filmetrics or SIS-2000 (SNU precision) thickness measurement instrument.

For film transmittance measurement, a coated and cured film on Eagle XG glass of approximately 2 μm thickness was measured via transmission UV-Vis. An uncoated Eagle XG coupon of the same thickness as the sample substrate was measured as a blank. Three measurements across the sample were then recorded and averaged. A Fourier filter was applied to remove interference fringes from the data, and the data were normalized to a 2.0 μm standard thickness. The % Transmittance was read out from the resulting smoothed and normalized curve.

TABLE 4
Formulation film properties

| | | | % Transmittance | | |
|---|---|---|---|---|---|
| | Based on | | | % T @ 410 nm | TMAH |
| Film | Formula- | RI @ | % T @ | after 230 C./ | Solubility |
| # | tion # | 550 nm | 410 nm | 60 min | (2 min; 2.38%) |
| FL18 | F1 | 1.629 | 90.8 | 91.0 | 100% |
| FL19 | F2 | 1.599 | 93.6 | 94.5 | 100% |
| FL20 | F3 | 1.670 | 82.2 | 81.4 | 100% |
| FL21 | F4 | 1.622 | 88.1 | 88.6 | 100% |
| FL22 | F5 | 1.660 | 91.3 | 91.9 | 100% |
| FL23 | F6 | 1.646 | 82.9 | 81.9 | 100% |
| FL24 | F7 | 1.653 | 92.4 | 92.4 | 100% |
| FL16 | Copolymer | 1.660 | 94.0 | N.D. | 0% |
| | Only | | | | |

Note:
All reported % Transmittances are normalized to a 2.0 μm film thickness. The critical dimension (CD) of patterning is measured via microscope. The TMAH solubility was measured by submerging a <1 μm thick film in TMAH for 2 min and rinsing with DI water for 5 sec. and drying on a hot plate at 110° C. for 60 sec. Film thickness was measured before and after submersion in TMAH and film loss (%) is reported.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention. Also, embodiments associated with a particular species or property may be combined with those associated with another species or property, so long as they are not mutually exclusive. The skilled person would understand which embodiments were mutually exclusive and would thus readily be able to determine the combinations of embodiments that are contemplated by the present application.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment.

Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

1. A copolymer composition comprising: (a) one or more bifunctional high refractive index first monomers comprising a high refractive index aromatic core and further comprising one or more UV- or thermally-reactive groups (A); (b) one or more second monomers comprising a high refractive index core and further comprising one or more groups capable of reacting to increase the solubility of the copolymer in aqueous media (B); and (c) one or more solvents.

2. The copolymer composition of claim 1, wherein the one or more bifunctional high refractive index first monomers comprising a high refractive index aromatic core and further comprising one or more UV- or thermally-reactive groups (A) is given by Formula (I): 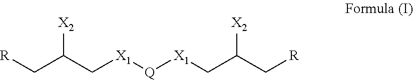
wherein Q is a high refractive index aromatic core comprising one or more aryl or heteroaryl groups; X1 and X2 are heteroatoms; and R is the same or different at each occurrence and is a UV- or thermally-active functional group.

3. The copolymer composition of claim 2, wherein Q comprises one or more aryl or heteroaryl groups comprising substituted or unsubstituted (C₃-C₆₀) mono-or polycyclic rings that may or may not contain deuterium and whose carbon atom(s) may be replaced with at least one hetero atom selected from N, O, S, and Se; wherein
Q optionally comprises two or more aryl or heteroaryl groups which are covalently linked by an alkyl, cycloalkyl, alkenyl, alkynyl, aryl, heteroaryl, aryloxy, arylthioxy, arylselenoxy, amino N(R′)(R″), arylcarbonyl, ketoxy, perfluoroalkyl, arylalkyl, silyl, siloxy, siloxane, sulfonyl, sulfonoaryl, or sulfonoheteroaryl or is linked by a phosphate, phosphine, urea, amide, imide, triazole, thioether, vinyl thioether, carbonate, thiocarbonate, or dithiocarbonate group or the like; wherein
Q optionally comprises one or more (C₃-C₃₀) alicyclic rings; wherein
Q may be further substituted with alkyl, cycloalkyl, aryl, nitro, cyano, amino, halo, hydroxy, thioxy, selenoxy, carboxy, thiocarboxy, dithiocarboxy, alkenyl, alkynyl, cycloalkyl, heteroaryl, alkoxy, aryloxy, heteroaryloxy, alkoxycarbonyl, thioalkoxy, selenoalkoxy, ketoxy, perfluoroalkyl, perfluoroalkoxy, arylalkyl, silyl, siloxy, siloxane, sulfonyl, amido, amino, arylamido, arylamino, sulfonoaryl, sulfonoheteroaryl or may be substituted with a phosphate, phosphine, urea, amide, imide, triazole, thioether, vinyl thioether, carbonate, thiocarbonate, or dithiocarbonate group; wherein
R′ and R″ is independently an optionally substituted alkyl, cycloalkyl, or aryl group; wherein
R′ and R″, together with the nitrogen atom to which they are bound, can optionally form a ring system; and wherein
s=0-2.

4. The copolymer composition of claim 1, wherein the one or more second monomers comprising a high refractive index core and further comprising one or more groups capable of reacting to increase the solubility of the copolymer in aqueous media (B) is given by Formula (II): 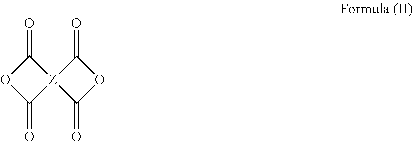
wherein Z is a tetravalent high refractive index core comprising one or more aryl or heteroaryl groups.

5. The copolymer composition of claim 1, wherein the copolymer composition comprises one or more additional monomers (A′) comprising a high refractive index core given by Formula (III):
Y-Q′-Y Formula (III)
wherein Q′ is a high refractive index aromatic core comprising one or more aryl or heteroaryl groups and Y is the same or different at each occurrence and is a nucleophilic reactive group.

6. The copolymer composition of claim 1, wherein the copolymer composition comprises one or more monofunctional monomers given by Formula (IV): 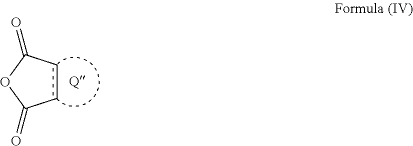
wherein Q″ is a high refractive index aromatic core comprising one or more aryl or heteroaryl groups.

7. A formulation comprising the copolymer composition of claim 1 and additionally comprising any one or more of: (f) one or more additional polymers or copolymers; (g) one or more photo-initiators and/or thermal initiators; (h) one or more cross-linking agents; (i) one or more antioxidants; (j) one or more surface leveling agents; (k) one or more adhesion promotors; and (I) one or more solvents.

8. The formulation of claim 7, wherein the formulation additionally comprises any one or more of: thermal acid generators, photoacid generators, oxygen scavengers, UV blockers, and hindered-amine light stabilizers.

9. An optical thin film comprising a copolymer comprising one or more bifunctional high refractive index first monomers comprising a high refractive index aromatic core and further comprising one or more UV- or thermally-reactive groups (A) and one or more second monomers comprising a high refractive index core and further comprising one or more groups capable of reacting to increase the solubility of the copolymer in aqueous media (B).

10. The optical thin film according to claim 9, wherein the optical thin film exhibits: (1) a refractive index >1.62 at a wavelength of 550 nm; (2) a % T >80% at wavelengths ≥410 nm for a 2 μm film; and (3) photo-patternability afforded by a light-induced reaction that imparts partial solubility in developing solutions used in the electronics industry such as aqueous tetramethyl ammonium hydroxide solutions or the like.

11. An optical device comprising the optical thin film of claim 9 wherein the optical device is a display device.
